(19) United States
(12) Patent Application Publication
(10) Pub. No.: US 2026/0118757 A1
(43) Pub. Date: Apr. 30, 2026

(54) RADIATION-SENSITIVE RESIST COMPOSITION AND PATTERN FORMATION METHOD USING THE SAME

(71) Applicant: Samsung Electronics Co., Ltd., Suwon-si (KR)

(72) Inventors: Taro MIYOSHI, Yokohama (JP); Nobuji SAKAI, Yokohama (JP); Yoshinobu KAMAKURA, Yokohama (JP); Hideomi YAMAGA, Yokohama (JP); Mitsumasa HAMANO, Yokohama (JP); Sayaka UCHIDA, Tokyo (JP); Naoki OGIWARA, Tokyo (JP)

(73) Assignees: Samsung Electronics Co., Ltd., Suwon-si (KR); THE UNIVERSITY OF TOKYO, Tokyo (JP)

(21) Appl. No.: 19/373,056

(22) Filed: Oct. 29, 2025

(30) Foreign Application Priority Data
Oct. 30, 2024 (JP) 2024-190672
Aug. 18, 2025 (KR) 10-2025-0114426

(51) Int. Cl. G03F 7/004; G03F 7/00

(52) U.S. Cl. CPC G03F 7/0043; G03F 7/70033

(57) ABSTRACT

Provided are a radiation-sensitive resist composition and a pattern formation method using the same, wherein the radiation-sensitive resist composition includes an ionic salt (A) including an organic cation (b) and an anion (a) which has a metal chalcogenide cluster structure, and a solvent (B), and a content of the ionic salt (A) in a total solid content of the radiation-sensitive resist composition is in a range of about 20 mass % to about 100 mass %.

### CROSS-REFERENCE TO RELATED APPLICATION

This application claims the benefit of Japanese Patent Application No. 2024-190672, filed on Oct. 30, 2024, in the Japanese Patent Office, and Korean Patent Application No. 10-2025-0114426, filed on Aug. 18, 2025, in the Korean Intellectual Property Office, the disclosures of which are incorporated herein in their entireties by reference.

### BACKGROUND

### 1. Field

The disclosure relates to a radiation-sensitive resist composition and a pattern formation method using the same.

### 2. Description of the Related Art

There is constant demand for the miniaturization of semiconductor processing, which may enable higher speeds and lower power consumption of semiconductor chips; therefore research and development of lithography technology, which is technology applied thereof, is underway. Recently, light sources for lithography have shifted to include extreme ultraviolet (EUV) sources, which makes it possible to obtain resist patterns with a line width of 20 nm or less. Chemically amplified resists used to obtain these resist patterns may have superior sensitivity and resolution as compared to materials for comparative light sources, e.g., excimer lasers.

### SUMMARY

In order to meet the demand for further miniaturization, research in improving both the sensitivity and resolution of chemically amplified resists is being conducted in order to obtain resist patterns with smaller critical dimensions (CDs) (e.g. a line width of 10 nm or less), which will be required in the future. Specifically, to address the low EUV absorption rate of organic materials included in chemically amplified resists, the energy of photons emitted by EUV rays should be efficiently converted into chemical reactions.

Provided are a radiation-sensitive resist composition having improved absorption properties of radiation (particularly, extreme ultraviolet (EUV) rays) and absorption properties such as improved sensitivity, improved developability, and/or improved resolution, and a pattern formation method using the same.

Additional aspects will be set forth in part in the description which follows and, in part, will be apparent from the description, or may be learned by practice of the presented embodiments of the disclosure.

According to an aspect of the disclosure, a radiation-sensitive resist composition includes an ionic salt (A) including an organic cation (b) and an anion (a) which has a metal chalcogenide cluster structure, and a solvent (B), wherein the anion (a) includes at least one of V, Nb, Ta, Mo, or W, the organic cation (b) is at least one of a secondary ammonium cation having 2 to 30 carbon atoms, a tertiary ammonium cation having 2 to 30 carbon atoms, a quaternary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, or a hydrazinium cation having 1 to 30 carbon atoms, and a content of the ionic salt (A) in the radiation-sensitive resist composition is in a range of about 20 mass % to about 100 mass % of a total solid content of the radiation-sensitive resist composition.

According to another aspect of the disclosure, a pattern formation method includes applying the radiation-sensitive resist composition onto a substrate to form a resist film, exposing at least a portion of the resist film to radiation, and developing the exposed resist film by using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a graph showing a Fourier transform infrared (FT-IR) spectrum of compound 1 obtained in Synthesis Example 1;

FIG. 2 is a graph showing an FT-IR spectrum of compound 2 obtained in Synthesis Example 2;

FIG. 3 is a graph showing an FT-IR spectrum of compound 3 obtained in Synthesis Example 3;

FIG. 4 is a graph showing an FT-IR spectrum of compound 4 obtained in Synthesis Example 4;

FIG. 5 is a graph showing an FT-IR spectrum of compound 5 obtained in Synthesis Example 5;

FIG. 6 is a graph showing an FT-IR spectrum of compound 6 obtained in Synthesis Example 6;

FIG. 7 is a graph showing an FT-IR spectrum of compound 7 obtained in Synthesis Example 7;

FIG. 8 is a graph showing an FT-IR spectrum of compound 8 obtained in Synthesis Example 8;

FIG. 9 is a graph showing an FT-IR spectrum of compound 9 obtained in Synthesis Example 9;

FIG. 10 is a graph showing an FT-IR spectrum of compound 10 obtained in Synthesis Example 10;

FIG. 11 is a graph showing an FT-IR spectrum of compound 11 obtained in Synthesis Example 11;

FIG. 12 is a graph showing an FT-IR spectrum of compound 12 obtained in Synthesis Example 12;

FIG. 13 is a graph showing an FT-IR spectrum of compound 13 obtained in Synthesis Example 13;

FIG. 14 is a graph showing an FT-IR spectrum of compound 14 obtained in Synthesis Example 14;

FIG. 15 is a graph showing an FT-IR spectrum of compound 15 obtained in Synthesis Example 15;

FIG. 16 is a graph showing an FT-IR spectrum of compound 16 obtained in Synthesis Example 16;

FIG. 17 is a graph showing an FT-IR spectrum of compound 17 obtained in Synthesis Example 17;

FIG. 18 is a graph showing an FT-IR spectrum of compound 18 obtained in Synthesis Example 18;

FIG. 19 is a graph showing an FT-IR spectrum of compound 19 obtained in Synthesis Example 19;

FIG. 20 is a graph showing an FT-IR spectrum of compound 20 obtained in Synthesis Example 20;

FIG. 21 is a graph showing an FT-IR spectrum of compound 21 obtained in Synthesis Example 21;

FIG. 22 is a graph showing an FT-IR spectrum of compound 22 obtained in Synthesis Example 22;

FIG. 23 is a graph showing an FT-IR spectrum of compound 23 obtained in Synthesis Example 23;

FIG. 24 is a graph showing an FT-IR spectrum of compound 24 obtained in Synthesis Example 24;

FIG. 25 is a graph showing an FT-IR spectrum of compound 25 obtained in Synthesis Example 25;

FIG. 26 is a graph showing an FT-IR spectrum of compound 26 obtained in Synthesis Example 26;

FIG. 27 is a graph showing an FT-IR spectrum of compound 27 obtained in Synthesis Example 27;

FIG. 28 is a graph showing an FT-IR spectrum of compound 28 obtained in Synthesis Example 28;

FIG. 29 is a graph showing an FT-IR spectrum of compound 29 obtained in Synthesis Example 29;

FIG. 30 is a graph showing an FT-IR spectrum of compound 30 obtained in Synthesis Example 30;

FIG. 31 is a graph showing an FT-IR spectrum of compound 31 obtained in Synthesis Example 31;

FIG. 32 is a graph showing an FT-IR spectrum of compound 32 obtained in Synthesis Example 32;

FIG. 33 is a graph showing an FT-IR spectrum of compound 33 obtained in Synthesis Example 33;

FIG. 34 is a graph showing an FT-IR spectrum of compound 34 obtained in Synthesis Example 34;

FIG. 35 is a graph showing an FT-IR spectrum of compound 35 obtained in Synthesis Example 35;

FIG. 36 is a graph showing an FT-IR spectrum of compound 36 obtained in Synthesis Example 36;

FIG. 37 is a graph showing an FT-IR spectrum of compound 37 obtained in Synthesis Example 37;

FIG. 38 is a graph showing an FT-IR spectrum of compound 38 obtained in Synthesis Example 38;

FIG. 39 is a graph showing an FT-IR spectrum of compound 39 obtained in Synthesis Example 39;

FIG. 40 is a graph showing an FT-IR spectrum of compound 40 obtained in Synthesis Example 40;

FIG. 41 is a graph showing an FT-IR spectrum of compound 41 obtained in Synthesis Example 41;

FIG. 42 is a graph showing an FT-IR spectrum of compound 42 obtained in Synthesis Example 42;

FIG. 43 is a graph showing an FT-IR spectrum of compound 43 obtained in Synthesis Example 43;

FIG. 44 is a graph showing an FT-IR spectrum of compound 44 obtained in Synthesis Example 44;

FIG. 45 is a graph showing an FT-IR spectrum of compound 45 obtained in Synthesis Example 45;

FIG. 46 is a graph showing an FT-IR spectrum of compound 46 obtained in Synthesis Example 46;

FIG. 47 is a graph showing an FT-IR spectrum of compound 47 obtained in Synthesis Example 47;

FIG. 48 is a flowchart illustrating a pattern formation method according to at least one example embodiment;

FIGS. 49A to 49C are side cross-sectional views illustrating a pattern formation method according to at least one example embodiment;

FIGS. 50A to 50E are side cross-sectional views illustrating a method of forming a patterning structure, according to at least one example embodiment; and

FIGS. 51A to 51E are side cross-sectional views illustrating a method of forming a semiconductor device, according to at least one example embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the FIGS., to explain aspects. As used herein, the term “and/or” includes any and all combinations of one or more of the associated listed items. Expressions such as “at least one of,” when preceding a list of elements, modify the entire list of elements and do not modify the individual elements of the list.

Since the present disclosure can apply various transformations and have various embodiments, specific embodiments will be illustrated in the drawings and described in detail in the detailed description. However, it should be understood that this is not intended to limit the disclosure to specific embodiments, and includes all transformations, equivalents, and substitutes included in the spirit and scope of the disclosure. In describing the disclosure, when it is determined that the specific description of the known related art unnecessarily obscures the gist of the disclosure, the detailed description thereof will be omitted.

It will be understood that, although the terms “first,” “second,” and “third” may be used herein to describe various elements, these elements should not be limited by these terms. These terms are only used to distinguish one element from another element and not used to limit order or types of elements.

In the present specification, when a portion of a layer, film, region, plate, or the like is described as being “on” or “above” another portion, it may include not only the meaning of “immediately on/under/to the left/to the right in a contact manner,” but also the meaning of “on/under/to the left/to the right in a non-contact manner.”

An expression used in the singular encompasses the expression of the plural, unless it has a clearly different meaning in the context. Hereinafter, unless explicitly described to the contrary, it is to be understood that the terms such as “including,” “having,” and “comprising” are intended to indicate the existence of the features, numbers, steps, actions, components, parts, ingredients, materials, or combinations thereof disclosed in the specification and are not intended to preclude the possibility that one or more other features, numbers, steps, actions, components, parts, ingredients, materials, or combinations thereof may exist or may be added.

Whenever a range of values is recited, the range includes all values that fall within the range as if expressly written, and the range further includes the boundaries of the range. Thus, a range of “X to Y” includes all values between X and Y and also includes X and Y.

Unless otherwise stated, operations and measurements of physical properties and/or the like are performed under conditions of room temperature (20° C. to 25° C.) and relative humidity of 40% RH to 50% RH.

In the description with reference to the drawings, substantially identical (and/or substantially similar) or corresponding components are given the same reference numerals, and thus a redundant description thereof may be omitted. In the drawings, the thicknesses of layers and regions may be exaggerated for clarity. Also, in the drawings, the thicknesses of some layers and regions may be exaggerated for convenience of description. Meanwhile, embodiments set forth herein are merely examples and various changes may be made therein.

### [Radiation-Sensitive Resist Composition]

A radiation-sensitive resist composition according to at least one example embodiment may be a radiation-sensitive resist composition which includes an ionic salt (A) including an organic cation (b) and an anion (a) which has a metal chalcogenide cluster structure, and a solvent (B), wherein the anion (a) includes at least one metal atom selected from V, Nb, Ta, Mo, and W, the organic cation (b) is at least one selected from a secondary ammonium cation having 2 to 30 carbon atoms, a tertiary ammonium cation having 2 to 30 carbon atoms, a quaternary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, and/or a hydrazinium cation having 1 to 30 carbon atoms, and a content of the ionic salt (A) in a total solid content of the radiation-sensitive resist composition is in a range of about 20 mass % to about 100 mass % of the total solid content.

The radiation-sensitive resist composition according to at least one example embodiment having the above-described configuration may have properties such as improved absorption of radiation (particularly, extreme ultraviolet (EUV) rays), improved sensitivity, improved developability, and improved resolution.

Although not limited to a specific theory, when radiation is irradiated onto the radiation-sensitive resist composition, the anion (a) of the ionic salt (A) changes into a reductant of a metal chalcogenide, and the organic cation (b) of the ionic salt (A) decomposes. The reductant of the metal chalcogenide is stabilized by proton donation from the solvent (B) and/or the decomposed organic cation (b). Accordingly, a reverse reaction in which a reductant reverts to the original metal chalcogenide is suppressed, and in addition, the solubility of an ionic salt including the reductant in a developer is significantly different from the solubility of an ionic salt including the original metal chalcogenide in a developer. Therefore, the radiation-sensitive resist composition according to at least one example embodiment may have improved dissolution contrast in addition to improved radiation absorption properties and may have improved properties such as sensitivity, developability, and resolution.

In addition, since the organic cation (b) allows for a wide range of structural design, improvements to sensitivity, developability, resolution, or the like may be easier.

As such, the radiation-sensitive resist composition according to at least one example embodiment may include the ionic salt (A) and the solvent (B). The radiation-sensitive resist composition according to at least one example embodiment may have properties such as improved absorption of radiation (particularly, EUV rays), improved sensitivity, improved developability, and improved resolution.

The radiation-sensitive resist composition of the disclosure may undergo a change in solubility (e.g., in a developer) upon exposure to radiation. The radiation-sensitive resist composition may be a positive resist composition in which an exposed portion is dissolved and removed to form a positive resist pattern or may be a negative resist composition in which an unexposed portion is dissolved and removed to form a negative resist pattern. In at least one example embodiment, the radiation-sensitive resist composition may be a positive resist composition.

In addition, the radiation-sensitive resist composition according to at least one example embodiment may be for a water development process using a water based developer when a resist pattern is formed, may be for an alkaline development process using an alkaline developer, and/or may be for a solvent development process using a developer including an organic solvent (hereinafter also referred to as an organic developer).

One type of the ionic salt (A) included in the radiation-sensitive resist composition may be used alone, or two or more types thereof may be used in combination.

### [Ionic Salt (A)]

The radiation-sensitive resist composition according to at least one example embodiment may include the ionic salt (A) including an organic cation (b) and an anion (a) having the metal chalcogenide cluster structure. The anion (a) and the organic cation (b) may combine through an ionic bond to form a salt.

<Anion (a)>

The ionic salt (A) may have the anion (a) having the metal chalcogenide cluster structure. Here, the term “metal chalcogenide cluster” is a group of atoms or molecules, or an aggregate of atoms or molecules, which is formed by bonding a plurality of types of atoms or molecules that constitute a metal chalcogenide. By having such a cluster structure, the anion (a) may become smaller in size, and when the anion (a) is used in a radiation-sensitive resist composition, the resolution of the radiation-sensitive resist composition may be improved.

The anion (a) may include at least one metal atom selected from vanadium (V), niobium (Nb), tantalum (Ta), molybdenum (Mo), and/or tungsten (W). From the viewpoint of ease of generation of a reductant, the anion (a) may include at least one metal atom selected from vanadium (V), molybdenum (Mo), and/or tungsten (W).

The total number of metal atoms in the chalcogenide cluster structure of the anion (a) may be in a range of 4 to 50, specifically, 4 to 30. When the above range is satisfied, the size of the anion (a) may be decreased, and resolution may be further improved.

A content of at least one metal atom selected from V, Nb, Ta, Mo, and W may be 20 at % or more with respect to 100 at % of the total number of metal atoms in the anion (a). When the above range is satisfied, sensitivity may be further improved due to there being many metal atoms with a relatively high absorption coefficient for radiation (particularly, EUV rays). The content of at least one metal atom selected from V, Nb, Ta, Mo, and W may be 45 at % or more, specifically, may be 70 at % or more, and more specifically, may be 80 at % or more with respect to 100 at % of the total number of metal atoms in the anion (a). In addition, an upper limit of the content of at least one metal atom selected from V, Nb, Ta, Mo, and W may be 100 at % with respect to 100 at % of the total number of metal atoms in the anion (a).

A molecular weight of the anion (a) may be in a range of about 600 to about 9,000, specifically, about 1,000 to 6,000. When the above range is satisfied, the size of the anion (a) may be decreased, and resolution may be further improved. As used herein, the term “molecular weight” is the sum of atomic weights of atoms constituting an ion or compound.

An average diameter of the anion (a) may be in a range of about 0.5 nm to about 10 nm, specifically, about 0.5 nm to about 3 nm, from the viewpoint of further improving resolution. An average diameter may be determined through a method such as single crystal X-ray structural analysis or dynamic light scattering analysis of solutions.

One type of the anion (a) constituting the ionic salt (A) according to at least one example embodiment may be used alone, or two or more types thereof may be used in combination.

The anion (a) may be at least one selected from anions represented by Formulas a-1 to a-6 below:

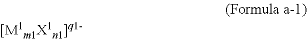

wherein, in Formula a-1,
M¹ may be at least one metal atom selected from V, Nb, Ta, Mo, and W,
m1 may be an integer from 4 to 60, a plurality of M¹ may be identical to or different from each other,
X¹ may be at least one selected from O, OH, S, and Se,
n1 may be an integer from 10 to 200, a plurality of X¹ may be identical to or different from each other, and
q1 may be an integer from 2 to 40,

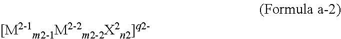

wherein, in Formula a-2,
M²⁻¹ may be at least one metal atom selected from V, Nb, Ta, Mo, and W,
m2-1 may be an integer from 4 to 60, a plurality of M²⁻¹ may be identical to or different from each other,
M²⁻² may be at least one atom selected from P, As, Si, Ge, Sn, B, Al, Ga, In, Fe, Zn, Co, Te, Cu, Ag, and Mn,
m2-2 may be an integer from 1 to 10, when m2-2 is greater than or equal to 2, a plurality of M²⁻² may be identical to or different from each other,
X² may be at least one selected from O, OH, S, and Se,
n2 may be an integer from 10 to 200, a plurality of X² may be identical to or different from each other, and
q2 may be an integer from 2 to 40,

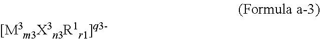

wherein, in Formula a-3,
M³ may be at least one metal atom selected from V, Nb, Ta, Mo, and W,
m3 may be an integer from 4 to 60, a plurality of M³ may be identical to or different from each other,
X³ may be at least one selected from O, OH, S, and Se,
n3 may be an integer from 10 to 200, a plurality of X³ may be identical to or different from each other,
R¹ may be an organic group having 1 to 20 carbon atoms,
r1 may be an integer from 1 to 10, when r1 is greater than or equal to 2, a plurality of R¹ may be identical to or different from each other, and
q3 may be an integer from 2 to 40,

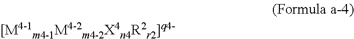

wherein, in Formula a-4,
M⁴⁻¹ may be at least one metal atom selected from V, Nb, Ta, Mo, and W,
m4-1 may be an integer from 4 to 60, a plurality of M⁴⁻¹ may be identical to or different from each other,
M⁴⁻² may be at least one atom selected from P, As, Si, Ge, Sn, B, Al, Ga, In, Fe, Zn, Co, Te, Cu, Ag, and Mn,
m4-2 may be an integer from 1 to 10, when m4-2 is greater than or equal to 2, a plurality of M⁴⁻² may be identical to or different from each other,
X⁴ may be at least one selected from O, OH, S, and Se,
n4 may be an integer from 10 to 200, a plurality of X⁴ may be identical to or different from each other,
R² may be an organic group having 1 to 20 carbon atoms,
r2 may be an integer from 1 to 10, when r2 is greater than or equal to 2, a plurality of R² may be identical to or different from each other, and
q4 may be an integer from 2 to 40,

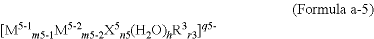

wherein, in Formula a-5,
M⁵⁻¹ may be at least one metal atom selected from V, Nb, Ta, Mo, and W,
m5-1 may be an integer from 4 to 60, a plurality of M⁵⁻¹ may be identical to or different from each other,
M⁵⁻² may be at least one atom selected from P, As, Si, Ge, Sn, B, Al, Ga, In, Fe, Zn, Co, Te, Cu, Ag, and Mn,
m5-2 may be an integer from 1 to 10, when m5-2 is greater than or equal to 2, a plurality of M⁵⁻² may be identical to or different from each other,
X⁵ may be at least one selected from O, OH, S, and Se,
n5 may be an integer from 10 to 200, a plurality of X⁵ may be identical to or different from each other,
h may be an integer from 1 to 10,
R³ may be an organic group having 1 to 20 carbon atoms,
r3 may be an integer from 1 to 10, when r3 is greater than or equal to 2, a plurality of R³ may be identical to or different from each other, and
q5 may be an integer from 2 to 40, and

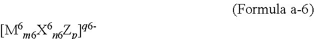

wherein, in Formula a-6,
M⁶ may be at least one metal atom selected from V, Nb, Ta, Mo, and W,
m6 may be an integer from 4 to 60, a plurality of M⁶ may be identical to or different from each other,
X⁶ may be at least one selected from O, OH, S, and Se,
n6 may be an integer from 10 to 200, a plurality of X⁶ may be identical to or different from each other,
Z may be an inorganic functional group including an oxygen atom and at least one atom selected from a nitrogen atom, a phosphorus atom, and a sulfur atom,
p may be an integer from 1 to 10, when p is greater than or equal to 2, a plurality of Z may be identical to or different from each other, and
q6 may be integer from 2 to 40.
X¹ in Formula a-1, X² in Formula a-2, X³ in Formula a-3, X⁴ in Formula a-4, X⁵ in Formula a-5, and X⁶ in Formula a-6 may each be a chalcogen element or a group including a chalcogen element. X¹ in Formula a-1, X² in Formula a-2, X³ in Formula a-3, X⁴ in Formula a-4, X⁵ in Formula a-5, and X⁶ in Formula a-6 may be directly bonded to at least one metal atom selected from V, Nb, Ta, Mo, and W, and may contribute to the stabilization of a cluster structure.
M²⁻² in Formula a-2, M⁴⁻² in Formula a-4, and M⁵⁻² in Formula a-5 may also be referred to as modifying elements and may not be directly bond to at least one metal atom selected from V, Nb, Ta, Mo, and W, but may contribute to the stabilization of a cluster structure. In addition, S included in a chalcogen element may also be used as a modifying element.
R¹ in Formula a-3, R² in Formula a-4, and R³ in Formula a-5 may each be an organic group having 1 to 20 carbon atoms. Specific examples of the organic group may include, for example: chain hydrocarbon groups such as a methyl group and an ethyl group; cyclic hydrocarbon groups such as a cyclohexyl group and a phenyl group; chain heteroatom-containing groups such as a trimethylolethane group, an ethylene carbonyloxy group, a methylphosphonic acid group, and an ethylphosphonic acid group; heterocyclic groups such as a pyridinyl group and a 1,10-phenanthrolinyl group; and/or the like.
Z in Formula a-6 may be an inorganic functional group including an oxygen atom and at least one atom selected from a nitrogen atom, a phosphorus atom, and a sulfur atom, Examples of the inorganic functional group may include a nitroso group (NO), a PO₄ group, a HPO₄ group, a SO₃ group, etc.

From the viewpoint that the size of the ionic salt (A) is further decreased and resolution is improved, q1 in Formula a-1, q2 in Formula a-2, q3 in Formula a-3, q4 in Formula a-4, q5 in Formula a-5, and q6 in Formula a-6 may each independently be an integer from 3 to 15.

More specific examples of the anion (a) represented by Formula a-1 may include, for example, [Nb₆O₁₉]⁸⁻, [Nb₇O₂₂]⁹⁻, [Nb₁₀O₂₈]⁶⁻, [Ta₆O₁₉]⁸⁻, [Ta₁₀O₂₈]⁶⁻, [Mo₆O₁₉]²⁻, [W₆O₁₉]²⁻, [W₇O₂₄]⁶⁻, [W₁₀O₃₂]⁴⁻, [W₁₀O₃₄]⁸⁻, [Mo₇O₂₄]⁶⁻, [Mo₈O₂₆]⁴⁻, [Mo₁₀O₃₄]⁸⁻, [W₁₂O₄₀(OH)₂]¹⁰⁻, [W₁₂O₃₈(OH)₂]⁶⁻, [V₄O₁₂]⁴⁻, [V₁₀O₂₈]⁶⁻, [V₁₂O₃₂]⁴⁻, [V₁₃O₃₄]⁴⁻, [V₁₈O₄₂]¹²⁻, [NbW₅O₁₉]³⁻, [Nb₄W₂O₁₉]⁶⁻, [V₂W₄O₁₉]⁴⁻, [NbVW₄O₁₉]⁴⁻, [V₅Mo₈O₄₀]⁷⁻, [W₆O₁₈S]²⁻, [W₃OS₈]²⁻, [W₄S₁₂]²⁻, and/or the like.

More specific examples of the anion (a) represented by Formula a-2 may include, for example, [TeMo₆O₂₄]⁶⁻, [CoW₆As₆O₃₀]⁴⁻, [SW₁₂O₄₀]²⁻, [PW₁₂O₄₀]³⁻, [AsW₁₂O₄₀]³⁻, [SiW₁₂O₄₀]⁴⁻, [GeW₁₂O₄₀]⁴⁻, [BW₁₂O₄₀]⁵⁻, [AlW₁₂O₄₀]⁵⁻, [GaW₁₂O₄₀]⁵⁻, [FeW₁₂O₄₀]⁵⁻, [ZnW₁₂O₄₀]⁶, [CoW₁₂O₄₀]⁶⁻, [SMo₁₂O₄₀]²⁻, [PMo₁₂O₄₀]³⁻, [AsMo₁₂O₄₀]³⁻, [SiMo₁₂O₄₀]⁴⁻, [GeMo₁₂O₄₀]⁴⁻, [SiMo₂W₁₀O₄₀]⁴⁻, [SiVW₁₁O₄₀]⁵⁻, [SiMo₂VW₉O₄₀]⁵⁻, [SiW₁₁O₃₉]⁸⁻, [PW₁₁O₃₉]⁸⁻, [B₃W₃₉O₁₃₂]²¹⁻, [AsW₉O₃₃]⁹⁻, [P₂W₁₈O₆₂]⁶⁻, [As₂W₁₈O₆₂]⁶⁻, [S₂W₁₈O₆₂]⁴⁻, [P₂MO₁₈O₆₂]⁶⁻, [As₂Mo₁₈O₆₂]⁶⁻, [S₂Mo₁₈O₆₂]⁴⁻, [AgP₅W₃₀O₁₁₀]¹⁴⁻, [Sn₈W₁₈O₆₆]⁸⁻, [Sn₃W₁₈Si₂O₆₈]¹⁴⁻, [Sn₃W₁₈P₂O₆₈]¹²⁻, [SnW₁₂O₄₂]¹⁰⁻, [Te₁₀W₂₈O₁₁₈]²⁸⁻, [Te₂W₁₈Cu₃O₆₉]¹⁶⁻, [Te₄W₂₀O₈₀]²⁴⁻, [Te₉W₂₈O₁₁₂]²⁴⁻, [Te₂W₅₈O₁₉₈]³⁶⁻, [TeW₁₈O₆₃]⁸⁻, [TeW₁₈O₆₂]¹⁰⁻, [TeW₆O₂₄]⁶⁻, [Te₂W₁₇O₆₁]¹²⁻, [TeW₁₅O₅₄]¹⁴⁻, [InW₁₁PO₄₀]⁸⁻, [InW₁₁SiO₄₀]⁹⁻, and/or the like.

More specific examples of the anion (a) represented by Formula a-3 may include, for example, [Mo₆O₁₇(NC₆H₅)₂]²⁻, [Mo₈O₂₄{CH₃C(CH₂O)₃}₂]⁶⁻, and/or the like.

More specific examples of the anion (a) represented by Formula a-4 may include, for example, [InW₃O₄(C₂H₄COO)₈]²²⁻, [MnMo₆O₁₈{CH₃C(CH₂O)₃}₂]³⁻, [ZnMo₆O₁₈{CH₃C(CH₂O)₃}₂]⁴⁻, [PW₉O₃₀(C₂H₅PO₃)₂]⁶⁻, and/or the like.

A more specific example of the anion (a) represented by Formula a-5 may include, for example, {ZnW₁₂O₄₀[Cu(phen)(H₂O)]₂}²⁻. In the above formulas, (phen) is an abbreviation for 1,10-phenanthrolinyl group.

More specific examples of the anion (a) represented by Formula a-6 may include, for example, [Mo₆O₁₈(NO)]³⁻, [Mo₅O₁₅(PO₄)₂]⁶⁻, [W₅O₁₅(PO₄)₂]⁶⁻, [Mo₅O₁₅(HPO₄)₂]⁴⁻, [Mo₅O₁₅(SO₃)₂]⁴⁻, and/or the like.

The anion (a) may be Mo₆O₁₉]²⁻, [W₆O₁₉]²⁻, [W₇O₂₄]⁶⁻, [W₁₀O₃₂]⁴⁻, [W₁₀O₃₄]⁸⁻, [Mo₇O₂₄]⁶⁻, [Mo₈O₂₆]⁴⁻, [Mo₁₀O₃₄]⁸⁻, [W₁₂O₄₀(OH)₂]¹⁰⁻, [W₁₂O₃₈(OH)₂]⁶⁻, [V₄O₁₂]⁴⁻, [V₁₀O₂₈]⁶⁻, [V₁₂O₃₂]⁴⁻, [V₁₃O₃₄]⁴⁻, [V₁₈O₄₂]¹²⁻, [NbW₅O₁₉]³⁻, [Nb₄W₂O₁₉]⁶⁻, [V₂W₄O₁₉]⁴⁻, [NbVW₄O₁₉]⁴⁻, [V₅Mo₈O₄₀]⁷⁻, [W₆O₁₈S]²⁻, [W₃OS₈]²⁻, [W₄S₁₂]²⁻, [TeMo₆O₂₄]⁶⁻, [CoW₆As₆O₃₀]⁴⁻, [SW₁₂O₄₀]²⁻, [PW₁₂O₄₀]³⁻, [AsW₁₂O₄₀]³⁻, [SiW₁₂O₄₀]⁴⁻, [GeW₁₂O₄₀]⁴⁻, [BW₁₂O₄₀]⁵⁻, [AlW₁₂O₄₀]⁵⁻, [GaW₁₂O₄₀]⁵⁻, [FeW₁₂O₄₀]⁵⁻, [ZnW₁₂O₄₀]⁶⁻, [CoW₁₂O₄₀]⁶⁻, [SMo₁₂O₄₀]²⁻, [PMo₁₂O₄₀]³⁻, [AsMo₁₂O₄₀]³⁻, [SiMo₁₂O₄₀]⁴⁻, [GeMo₁₂O₄₀]⁴⁻, [SiMo₂W₁₀O₄₀]⁴⁻, [SiVW₁₁O₄₀]⁵⁻, [SiMo₂VW₉O₄₀]⁵⁻, [SiW₁₁O₃₉]⁸⁻, [PW₁₁O₃₉]⁸⁻, [B₃W₃₉O₁₃₂]²¹⁻, [AsW₉O₃₃]⁹⁻, [P₂W₁₈O₆₂]⁶⁻, [As₂W₁₈O₆₂]⁶⁻, [S₂W₁₈O₆₂]⁴⁻, [P₂MO₁₈O₆₂]⁶⁻, [As₂Mo₁₈O₆₂]⁶⁻, [S₂Mo₁₈O₆₂]⁴⁻, [AgP₅W₃₀O₁₁₀]¹⁴⁻, [Sn₈W₁₈O₆₆]⁸⁻, [Sn₃W₁₈Si₂O₆₈]¹⁴⁻, [Sn₃W₁₈P₂O₆₈]¹²⁻, [SnW₁₂O₄₂]¹⁰⁻, [Te₁₀W₂₈O₁₁₈]²⁸⁻, [Te₂W₁₈Cu₃O₆₉]¹⁶⁻, [Te₄W₂₀O₈₀]²⁴⁻, [Te₉W₂₈O₁₁₂]²⁴⁻, [Te₂W₅₈O₁₉₈]³⁶⁻, [TeW₁₈O₆₃]⁸⁻, [TeW₁₈O₆₂]¹⁰⁻, [TeW₆O₂₄]⁶⁻, [Te₂W₁₇O₆₁]¹²⁻, [TeW₁₅O₅₄]¹⁴⁻, [InW₁₁PO₄₀]⁸⁻, [InW₁₁SiO₄₀]⁹⁻, [Mo₆O¹⁷(NC₆H₅)₂]²⁻, [Mo₈O₂₄{CH₃C(CH₂O)₃}₂]⁶⁻, [InW₃O₄(C₂H₄COO)₈]²²⁻, [MnMo₆O₁₈{CH₃C(CH₂O)₃}₂]³⁻, [ZnMoO₁₈{CH₃C(CH₂O)₃}₂]⁴⁻, [PW₉O₃₀(C₂H₅PO₃)₂]⁶⁻, {ZnW₁₂O₄₀[Cu(phen)(H₂O)]₂}²⁻, [Mo₆O₁₈(NO)]³⁻, [Mo₅O₁₅(PO₄)₂]⁶⁻, [W₅O₁₅(PO₄)₂]⁶⁻, [Mo₅O₁₅(HPO₄)₂]⁴⁻, or [Mo₅O₁₅(SO₃)₂]⁴⁻.

Specifically, the anion (a) may be [Mo₆O₁₉]²⁻, [W₆O₁₉]²⁻, [W₁₀O₃₂]⁴⁻, [Mo₇O₂₄]⁶⁻, [PW₁₂O₄₀]³⁻, [SiW₁₂O₄₀]⁴, or [PMo₁₂O₄₀]³.

Representative structures of the metal chalcogenide cluster may include a Keggin structure, a Wells-Dawson structure, and an Anderson-Evans-Perloff structure. Examples of a cluster structure of the anion (a) may include such structures, but the cluster structure of the anion (a) is not limited thereto.

<Organic Cation (b)>

The organic cation (b) according to the disclosure may be at least one selected from a secondary ammonium cation having 2 to 30 carbon atoms, a tertiary ammonium cation having 2 to 30 carbon atoms, a quaternary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, and/or a hydrazinium cation having 1 to 30 carbon atoms. The number of carbon atoms in the organic cation (b) may be 30 or less, and when the number of carbon atoms in the organic cation (b) exceeds 30, a proportion of metal atoms having a relatively high absorption coefficient for radiation (particularly, EUV rays) in the ionic salt (A) may decrease, thereby lowering sensitivity.

Examples of an organic group of the organic cation (b) may include a chain hydrocarbon group, an alicyclic hydrocarbon group, an aromatic hydrocarbon group, and/or the like. The organic group may include a heteroatom (e.g., an atom which is not carbon or hydrogen). The chain hydrocarbon group may be any one selected from a straight-chain hydrocarbon group and a branched-chain hydrocarbon group. The chain hydrocarbon group and the alicyclic hydrocarbon group may each be a saturated hydrocarbon group or an unsaturated hydrocarbon group. The alicyclic hydrocarbon group and the aromatic hydrocarbon group may each be monocyclic or polycyclic. In addition, the organic group may be substituted with a substituent such as an alkyl group, an alkenyl group, an alkoxy group, a cycloalkyloxy group, an aryl group, an arylalkyl group, an aryloxy group, an arylalkoxy group, a heterocyclic group, an alkylidene group, an acyl group, an acyloxy group, an amino group, a silyl group, a carboxyl group, a sulfo group, a cyano group, a nitro group, a thiol group, a hydroxy group, or a halogen group.

From the viewpoint of having relatively high proton-donating properties, the organic cation (b) may be at least one selected from a secondary ammonium cation having 2 to 30 carbon atoms, a tertiary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, and/or a hydrazinium cation having 1 to 30 carbon atoms.

In addition, in at least one example embodiment, the organic cation (b) may be at least one selected from a secondary ammonium cation having 2 to 30 carbon atoms, a tertiary ammonium cation having 2 to 30 carbon atoms, a phosphonium cation having 1 to 30 carbon atoms, a pyridinium cation having 5 to 30 carbon atoms, an imidazolium cation having 3 to 30 carbon atoms, a guanidinium cation having 1 to 30 carbon atoms, and/or a hydrazinium cation having 1 to 30 carbon atoms.

When the radiation-sensitive resist composition is a negative type resist composition, a quaternary ammonium cation having 2 to 30 carbon atoms may be used as the organic cation (b).

The organic cation (b) of the disclosure may be a monovalent ion or a divalent or higher polyvalent ion, but may be monovalent from the viewpoint of resolution. Furthermore, one type of the organic cation (b) constituting the ionic salt (A) of the disclosure may be used alone, or two or more types thereof may be used in combination.

Specific examples of the organic cation (b) according to the disclosure may include the following cations.

Examples of a secondary ammonium cation having 2 to 30 carbon atoms include: a dimethylammonium cation, a diethylammonium cation, an N-ethylmethylammonium cation, a dipropylammonium cation, a dibutylammonium cation, an azetidinium cation, a pyrrolidinium cation, an N-methylpropylammonium cation, an N-methylethanolammonium cation, and a piperidinium cation.

Examples of a tertiary ammonium cation having 2 to 30 carbon atoms include: a trimethylammonium cation, a triethylammonium cation, a triethanolammonium cation, an N,N-dimethylethylammonium cation, a 1-methylpyrrolidinium cation, a tris[2-(2-methoxyethoxy)ethyl]ammonium cation, a trihexylammonium cation, a triheptylammonium cation, an anilinium cation, an N,N,N′,N′-tetramethylethylenediammonium cation, a triethanolammonium cation, an N,N-dimethylanilinium cation, a methyldiphenylammonium cation, anN,N,2,4,6-pentamethylanilinium cation, anN,N-dimethyl-1-naphthylammonium cation, an N,N-dipropylanilinium cation, a 1-phenylpiperidinium cation, and a triethylenediammonium cation.

Examples of a quaternary ammonium cation having 2 to 30 carbon atoms include: a tetramethylammonium cation, a 2-hydroxyethyltrimethylammonium cation, a tetraethylammonium cation, a 1,1-dimethylpiperidinium cation, a triethylmethylammonium cation, a trimethylphenylammonium cation, a 2-hydroxypropyltrimethylammonium cation, a 5-azoniaspiro[4.4]nonane cation, a diallyldimethylammonium cation, a trimethylvinylammonium cation, a benzyltrimethylammonium cation, a bis(2-hydroxyethyl)dimethylammonium cation,a 1-butyl-1-methylpyrrolidinium cation, an acetylcholine cation, a trimethylpropylammonium cation, an N,N-dimethylmethyleneammonium cation, a [2-(acryloyloxy)ethyl]trimethylammonium cation, a benzyltriethylammonium cation, a 1-ethyl-1-methylpyrrolidinium cation, a methacholine, a butyltrimethylammonium cation, a tetrapropylammonium cation, a tetrabutylammonium cation, a (3-acrylamidepropyl)trimethylammonium cation, a trimethyl-2-methacryloyloxyethylammonium cation, an n-octyltrimethylammonium cation, a 1-methyl-1-propylpyrrolidinium cation, an N-benzyl-2-((4-iodobenzoyl)oxy)-N,N-dimethylethane-1-aminum cation, a 2-(acryloyloxy)-N-benzyl-N,N-dimethylethane-1-aminum cation, and a 2-((4-azidebenzoyl)oxy)-N-benzyl-N,N-dimethylethane-1-aminum cation.

Examples of a phosphonium cation having 1 to 30 carbon atoms include: a tetraethylphosphonium cation, a tetrabutylphosphonium cation, tributyl(cyanomethyl)phosphonium cation, a methyltriphenylphosphonium cation, an ethyltriphenylphosphonium cation, a (formylmethyl)triphenylphosphonium cation, a tributyl(methyl)phosphonium cation, a (methoxymethyl)triphenylphosphonium cation, a tetraphenylphosphonium cation, an acetonyltriphenylphosphonium cation, a butyltriphenylphosphonium cation, a triphenylpropargylphosphonium cation, a methoxycarbonylmethyl(triphenyl)phosphonium cation, an amyltriphenylphosphonium cation, a tetrakis(hydroxymethyl)phosphonium cation, a tributyl-n-octylphosphonium cation, a benzyltriphenylphosphonium cation, a triphenylpropylphosphonium cation, an allyltriphenylphosphonium cation, a cyclopropyltriphenylphosphonium cation, and a benzyltriphenylphosphonium cation.

Examples of a sulfonium cation having 1 to 30 carbon atoms include: a triphenylsulfonium cation, a trimethylsulfonium cation, a triethylsulfonium cation, a tributylsulfonium cation, a (2-carboxyethyl)dimethylsulfonium cation, a 4-hydroxyphenyldimethylsulfonium cation, a diphenyl(methyl)sulfonium cation, a dimethyl(phenethyl)sulfonium cation, a 5-ethenylthianthrenium cation, a (difluoromethyl)bis(2,5-dimethylphenyl)sulfonium cation, a tri-p-tolylsulfonium cation, a benzyl(4-hydroxyphenyl)methylsulfonium cation, a dimesityl(trifluoromethyl)sulfonium cation, a diphenyl[4-(phenylthio)phenyl]sulfonium cation, and a (thiodi-4,1-phenylene)bis(diphenylsulfonium) cation.

Examples of an iodonium cation having 1 to 30 carbon atoms include: a diphenyliodonium cation, a bis(4-tert-butylphenyl)iodonium cation, a bis(4-methylphenyl)iodonium cation, a bis(4-fluorophenyl)iodonium cation, a (4-nitrophenyl)(phenyl)iodonium cation, a (4-methylphenyl)(2,4,6-trimethylphenyl)iodonium cation, a (2-methylphenyl)(2,4,6-trimethylphenyl)iodonium cation, a (3-methylphenyl)(2,4,6-trimethylphenyl)iodonium cation, a (4-isobutylphenyl)(p-tolyl)iodonium cation, a phenyl[3-(trifluoromethyl)phenyl]iodonium cation, a bis(2,4,6-trimethylphenyl)iodonium cation, a [4-(trifluoromethyl)phenyl](2,4,6-trimethylphenyl)iodonium cation, a [3-(trifluoromethyl)phenyl](2,4,6-trimethylphenyl)iodonium cation, a phenyl(2,4,6-trimethoxyphenyl)iodonium cation, a (3-bromophenyl)(mesityl)iodonium cation, a bis(4-bromophenyl)iodonium cation, a 4-biphenylyl(2,4,6-trimethoxyphenyl)iodonium cation, a (5-fluoro-2-nitrophenyl)(2,4,6-trimethoxyphenyl)iodonium cation, a [(4-trifluoromethyl)phenyl](2,4,6-trimethoxyphenyl)iodonium cation, a (3,5-dichlorophenyl)(2,4,6-trimethoxyphenyl)iodonium cation, a [4-fluoro-3-(trifluoromethyl)phenyl](2,4,6-trimethoxyphenyl)iodonium cation, a [4-(bromomethyl)phenyl](2,4,6-trimethoxyphenyl)iodonium cation, a [4-(octyloxy)phenyl](phenyl)iodonium cation, a [4-[(2-hydroxytetradecyl)oxy]phenyl]phenyliodonium cation, a (4-isopropylphenyl)(p-tolyl)iodonium cation, and a 4-isopropyl-4′-methyldiphenyliodonium cation.

Examples of a pyridinium cation having 5 to 30 carbon atoms include: a pyridinium cation, a 1-methylpyridinium cation, a 1-ethylpyridinium cation, a 1-propylpyridinium cation, a 1-acetonylpyridinium cation, a 1-butylpyridinium cation, a 1-butyl-4-methylpyridinium cation, a 1-butyl-3-methylpyridinium cation, a 1-ethyl-2-methylpyridinium cation, a 1-ethyl-4-methylpyridinium cation, a 1-(3-sulfopropyl)-2-vinylpyridinium cation, a 4-dimethylamino-1-neopentylpyridinium cation, a 1,4-dimethylpyridinium cation, a 1-ethyl-3-methylpyridinium cation, a 2-chloro-1-methylpyridinium cation, a 1,1′-dimethyl-4,4′-bipyridinium cation, a 4-tert-butyl-1-(3-sulfopropyl)pyridinium cation, a 1-ethyl-3-(hydroxymethyl)pyridinium cation, a 2-bromo-1-ethylpyridinium cation, a 1-(2,4-dinitrophenyl)pyridinium cation, a 2-fluoro-1-methylpyridinium cation, a 1-dodecylpyridinium cation, a 1-ethylquinolinium cation, a 1-ethyl-4-(methoxycarbonyl)pyridinium cation, a 10-methylacridinium cation, a 1-ethylquinaldinium cation, a 1-hexylpyridinium cation, a 1-tetradecylpyridinium cation, a 2-benzyloxy-1-methylpyridinium cation, a 1-hexadecyl-4-methylpyridinium cation, a cetylpyridinium cation, a hexadecylpyridinium cation, a 10-methyl-9-phenylacridinium cation, a 1,1′-diethyl-4,4′-bipyridinium cation, and a 1,1′-dibenzyl-4,4′-bipyridinium cation.

Examples of an imidazolium cation having 3 to 30 carbon atoms include: an imidazolium cation, a 1,3-dimethylimidazolium cation, a 1-ethyl-3-methylimidazolium cation, a 1-allyl-3-methylimidazolium cation, a 1-methyl-3-propylimidazolium cation, a 1-(2-hydroxyethyl)-3-methylimidazolium cation, a 1-butyl-3-methylimidazolium cation, a 1-butyl-2,3-dimethylimidazolium cation, a 1-hexyl-3-methylimidazolium cation, a 1-benzyl-3-methylimidazolium cation, a 2-chloro-1,3-dimethylimidazolinium cation, a 1,3-diisopropylimidazolium cation, a 1-methyl-3-n-octylimidazolium cation, a 3-butyl-1-vinylimidazolium cation, a 1-methyl-3-pentylimidazolium cation, a 1,3-di-tert-butylimidazolium cation, a 1,3-dicyclohexylimidazolium cation, a 1,3-diisopropylbenzimidazolium cation, a 1-decyl-3-methylimidazolium cation, a 1-hexadecyl-3-methylimidazolium cation, a 1-carbobenzoxy-3-methylimidazolium cation, a 1-methyl-3-[6-(methylthio)hexyl]imidazolium cation, a 1,1′-(2,6-pyridinediyl)bis(3-methylimidazolium) cation, a 3-ethyl-1-vinylimidazolium cation, a 3,3′-methylenebis(1-tert-butyl-3-imidazolium) cation, a 1,3-di(1-adamantyl)imidazolium cation, and a 1,3-bis(2,6-diisopropylphenyl)imidazolium cation.

Examples of a diazonium cation having 1 to 30 carbon atoms include: a 4-methoxybenzenediazonium cation, a 4-nitrobenzenediazonium cation, a 4-bromobenzenediazonium cation, a 4-aminodiphenylaminediazonium cation, a 4-(pentafluorosulfanyl)phenyldiazonium cation, and a 4-[N-(4-methoxyphenyl)amino]benzenediazonium cation.

Examples of a guanidinium cation having 1 to 30 carbon atoms include: a guanidium cation, a 1,1,3,3-tetramethylguanidinium cation, a 1-acetylguanidinium cation, a 1-methylguanidinium cation, a 1,3,4,6,7,8-hexahydro-2H-pyrimido[1,2-a]pyrimidinium cation, a 1,3,4,6,7,8-hexahydro-1-methyl-2H-pyrimido[1,2-a]pyrimidinium cation, a 2-tert-butyl-1,1,3,3-tetramethylguanidinium cation, a 1,3-diphenylguanidinium cation, and a 1,3-Di-o-tolylguanidinium.

Examples of a hydrazinium cation having 1 to 30 carbon atoms include: a 1,1-dimethylhydrazinium cation, a 1-methyl-1-phenylhydrazinium cation, a phenylhydrazinium cation, a 1,1-diphenylhydrazinium cation, a 1-acetyl-2-phenylhydrazinium cation, a 4-nitrophenylhydrazinium cation, a 2-methylphenylhydrazinium cation, a 4-methoxyphenylhydrazinium cation, a 2-methoxyphenylhydrazinium cation, a 3-(trifluoromethyl)phenylhydrazinium cation, a 1,2-diphenylhydrazinium cation, and a 1-naphthylhydrazinium cation.

Specifically, in some example embodiments, the organic cation (b) may include one or more of the following organic cations: a triethylammonium cation, a triethanolammonium cation, a tris[2-(2-methoxyethoxy)ethyl]ammonium cation, a triheptylammonium cation, an N,N,N′,N′-tetramethylethylenediammonium cation, an N,N-dimethylanilinium cation, an N,N,2,4,6-pentamethylanilinium cation, a 1-phenylpiperidinium cation, a triethylenediammonium cation, a tetrabutylammonium cation, an N-benzyl-2-((4-iodobenzoyl)oxy)-N,N-dimethylethane-1-aminum cation, a 2-(acryloyloxy)-N-benzyl-N,N-dimethylethane-1-aminum cation, a 2-((4-azidobenzoyl)oxy)-N-benzyl-N,N-dimethylethan-1-aminium cation, a methyltriphenylphosphonium cation, a tetraphenylphosphonium cation, a triphenylsulfonium cation, a diphenyliodonium cation, a bis(4-tert-butylphenyl)iodonium cation, a (4-nitrophenyl)(phenyl)iodonium cation, a (4-methylphenyl)(2,4,6-trimethylphenyl)iodonium cation, a phenyl[3-(trifluoromethyl)phenyl]iodonium cation, a [3-(trifluoromethyl)phenyl](2,4,6-trimethylphenyl)iodonium cation, a phenyl(2,4,6-trimethoxyphenyl)iodonium cation, a pyridinium cation, a 1-methylpyridinium cation, an imidazolium cation, a 1,3-dimethylimidazolium cation, a 4-methoxybenzenediazonium cation, a 1,1,3,3-tetramethylguanidinium cation, a 1,3-Di-o-tolylguanidinium cation, and a 1,1-diphenylhydrazinium cation.

In addition, the ionic salt (A) may have a proton (hydrogen cation; H⁺) as a cation component in addition to the organic cation (b).

From the viewpoint of further reducing the size of the ionic salt (A) and further improving resolution, a molecular weight of the organic cation (b) may be in a range of about 50 to about 5,000, specifically, about 100 to about 1,000.

### <Specific Examples of Ionic Salt (A)>

Specific examples of the ionic salt (A) of the disclosure may include the following compounds:
[PMo₁₂O₄₀]³⁻·3{tris[2-(2-methoxyethoxy)ethyl]ammonium}
[SiW₁₂O₄₀]⁴⁻·4(triphenylsulfonium)
[PMo₁₂O₄₀]³⁻·3(diphenyliodonium)
[PW₁₂O₄₀]³⁻·3(triphenylsulfonium)
[PMo₁₂O₄₀]³⁻·3(triphenylsulfonium)
[PW₁₂O₄₀]³⁻·3(diphenyliodonium)
[SiW₁₂O₄₀]⁴⁻·4(diphenyliodonium)
[PW₁₂O₄₀]³⁻·2{tris[2-(2-methoxyethoxy)ethyl]ammonium}H
[PMo₁₂O₄₀]³⁻·2{tris[2-(2-methoxyethoxy)ethyl]ammonium}H
[SiW₁₂O₄₀]⁴⁻·4[bis(4-tert-butylphenyl)iodonium]
[SiW₁₂O₄₀]⁴⁻·4[(4-nitrophenyl)(phenyl)iodonium]
[SiW₁₂O₄₀]⁴⁻·4[(4-methylphenyl)(2,4,6-trimethylphenyl)iodonium]
[SiW₁₂O₄₀]⁴⁻·4[phenyl[3-(trifluoromethyl)phenyl]iodonium]
[SiW₁₂O₄₀]⁴⁻·4[phenyl(2,4,6-trimethoxyphenyl)iodonium]
[SiW₁₂O₄₀]⁴⁻·4[[3-(trifluoromethyl)phenyl](2,4,6-trimethylphenyl)iodonium]
[PMo₁₂O₄₀]³⁻·3(triheptylammonium)
[PMo₁₂O₄₀]³⁻·3(triethylammonium)
[PMo₁₂O₄₀]³⁻·3(pyridinium)
[PMo₁₂O₄₀]³⁻·3(N,N,N′,N′-tetramethylethylenediammonium)
[PMo₁₂O₄₀]³⁻·3(triethanolammonium)
[PMo₁₂O₄₀]³⁻·3(N,N-dimethylanilinium)
[PW₁₂O₄₀]³⁻·3(1,1-diphenylhydrazinium)
[PW₁₂O₄₀]³⁻·3(N,N-dimethylanilinium)
[SiW₁₂O₄₀]⁴⁻·4(N,N-dimethylanilinium)
[PMo₁₂O₄₀]³⁻·3(1-methylpyridinium)
[PMo₁₂O₄₀]³⁻·3(imidazolium)
[PMo₁₂O₄₀]³⁻·3(1,3-dimethylimidazolium)
[PMo₁₂O₄₀]³⁻·3(N,N,2,4,6-pentamethylanilinium)
[PMo₁₂O₄₀]³⁻·3(1,3-di-o-tolylguanidinium)
[PMo₁₂O₄₀]³⁻·3(1-phenylpiperidinium)
[PMo₁₂O₄₀]³⁻·3(triethylenediammonium)
[PMo₁₂O₄₀]³⁻·3(1,1,3,3-tetramethylguanidinium)
[PMo₁₂O₄₀]³⁻·3(methyltriphenylphosphonium)
[PMo₁₂O₄₀]³⁻·3(tetraphenylphosphonium)
[Mo₆O₁₉]²⁻·2(diphenyliodonium)
[PMo₁₂O₄₀]³⁻·3(4-methoxybenzenediazonium)
[W₁₀O₃₂]⁴⁻·4{tris[2-(2-methoxyethoxy)ethyl]ammonium}
[W₁₀O₃₂]⁴⁻·4(diphenyliodonium)
[Mo₇O₂₄]⁶⁻·6{tris[2-(2-methoxyethoxy)ethyl]ammonium}
[Mo₇O₂₄]⁶⁻·6(diphenyliodonium)
[SiW₁₂O₄₀]⁴⁻·4{N-benzyl-2-[(4-iodobenzoyl)oxy]-N,N-dimethylethane-1-aminum}
[W₆O₁₉]²⁻·1.4(tetrabutylammonium)0.6{N-Benzyl-2-[(4-iodobenzoyl)oxy-N,N-dimethylethane-1-aminium}
[Mo₆O₁₉]²⁻·1.2(tetrabutylammonium)0.8{N-benzyl-2-[(4-iodobenzoyl)oxy-N,N-dimethylethane-1-aminium}
[SiW₁₂O₄₀]⁴⁻·4[2-(acryloyloxy)-N-benzyl-N,N-dimethylethane-1-aminium]
[W₆O₁₉]²⁻·1.4(tetrabutylammonium)0.6[2-(acryloyloxy)-N-benzyl-N,N-dimethylethane-1-aminium]
[Mo₆O₁₉]²⁻·1.2(tetrabutylammonium)0.8[2-(acryloyloxy)-N-benzyl-N,N-dimethylethane-1-aminium]
[SiW₁₂O₄₀]⁴⁻·4[2-((4-azidebenzoyl)oxy)-N-benzyl-N,N-dimethylethane-1-aminum]
[W₆O₁₉]²⁻·1.4(tetrabutylammonium)0.6[2-((4-azidebenzoyl)oxy)-N-benzyl-N,N-dimethylethane-1-aminium]
[Mo₆O₁₉]²⁻·1.2(tetrabutylammonium)0.8[2-((4-azidebenzoyl)oxy)-N-benzyl-N,N-dimethylethane-1-aminium]
[V₁₈O₄₂]¹²⁻·12[2-((4-azidebenzoyl)oxy)-N-benzyl-N,N-dimethylethane-1-aminum]
[Nb₆O₁₉]⁸⁻·8{dimethylammonium}
[Nb₇O₂₂]⁹⁻·9{diethylammonium}
[Nb₁₀O₂₈]⁶⁻·6{dipropylammonium}
[Ta₆O₁₉]⁸⁻·8{{dibutylammonium}
[Ta₁₀O₂₈]⁶⁻·6{azetidinium}
[Mo₆O₁₉]²⁻·2{pyrrolidinium}
[W₆O₁₉]²⁻·2{N-methylpropylammonium}
[W₇O₂₄]⁶⁻·6{N-methylethanol ammonium}
[W₁₀O₃₂]⁴⁻·4{piperidinium}
[W₁₀O₃₄]⁸⁻·8 {trimethylammonium}
[Mo₅O₁₅(PO₄)₂]⁶⁻·6{triethylammonium}
[W₅O₁₅(PO₄)₂]⁶⁻·6{N-ethylmethylammonium}
[MosO₁₅(HPO₄)₂]⁴⁻·4{N—N-Dimethylethylammonium}
[Mo₅O₁₅(SO₃)₂]⁴⁻·4{1-methylpyrrolidinium}
[Mo₇O₂₄]⁶⁻·6{tris[2-(2-methoxyethoxy)ethyl]ammonium}
[Mo₈O₂₆]⁴⁻·4{trihexylammonium}
[Mo₁₀O₃₄]⁸⁻·8 {anilinium}
[W₁₂O₄₀(OH)₂]¹⁰⁻·10{N—N—N′—N′-tetramethylethylenediammonium}
[W₁₂O₃₈(OH)₂]⁶⁻·6{triethanolammonium}
[V₄O₁₂]⁴⁻·4{N,N-dimethylanilinium}
[V₁₀O₂₈]⁶⁻·6{methyldiphenylammonium}
[V₁₂O₃₂]⁴⁻·4{N,N,2,4,6-pentamethylanilinium}
[V₁₃O₃₄]⁴⁻·4{N,N-dimethyl-1-naphthylammonium}
[V₁₈O₄₂]¹²⁻·12{N,N-dipropylanilinium}
[NbW₅O₁₉]³⁻·3{1-phenylpiperidinium}
[Nb₄W₂O₁₉]⁶⁻·6{triethyldiammonium}
[V₂W₄O₁₉]⁴⁻·4{tetramethylammonium}
[NbVW₄O₁₉]⁴⁻·4{2-hydroxyethyltrimethylammonium}
[V₅Mo₈O₄₀]⁷⁻·7{tetraethylammonium}
[Mo₆O₁₈(NO)]³⁻·3{1,1-dimethylpiperidinium}
[MoO₁₇(NC₆H₅)₂]²⁻·2{triethylmethylammonium}
[TeMo₆O₂₄]⁶⁻·6{trimethylphenylammonium}
[CoW₆As₆O₃₀]⁴⁻·4{2-hydroxypropyltrimethylammonium}
[MnMo₆O₁₈{CH₃C(CH₂O)₃}₂]³⁻·3{5-azoniaspiro[4.4]nonane}
[ZnMo₆O₁₈{CH₃C(CH₂O)₃}₂]⁴⁻·4{diallyldimethylammonium}
[Mo₈O₂₄{CH₃C(CH₂O)₃}₂]⁶⁻·6{trimethylvinylammonium}
[W₆O₁₈S]²⁻·2{benzyltrimethylammonium}
[W₃OS₈]²⁻·2{bis(2-hydroxyethyl)dimethylammonium}
[W₄S₁₂]²⁻·2{1-butyl-1-methylpyrrolidinium}
[SW₁₂O₄₀]²⁻·2{acetylcholine}
[PW₁₂O₄₀]³⁻·3{trimethylpropylammonium}
[AsW₁₂O₄O]³⁻·3{N,N-dimethylmethylene ammonium}
[SiW₁₂O₄₀]⁴⁻·4{[2-(acryloyloxy)ethyl]trimethyleneammonium}
[GeW₁₂O₄₀]⁴⁻·4{benzyltriethylammonium}
[BW₁₂O₄₀]⁵⁻·5{1-ethyl-1-methylpyrrolidinium}
[AlW₁₂O₄₀]⁵⁻·5{methacholine}
[GaW₁₂O₄₀]⁵⁻·5{butyltrimethylammonium}
[FeW₁₂O₄₀]⁵⁻·5{tetrapropylammonium}
[ZnW₁₂O₄₀]⁶⁻·6{(3-acrylamidepropyl)trimethylammonium}
[CoW₁₂O₄₀]⁶⁻·6{trimethyl-2-methacryloyloxyethylammonium}
[SMo₁₂O₄₀]²⁻·2{n-octyltrimethylammonium}
[PMo₁₂O₄₀]³⁻·3{1-methyl-1-propylpyrrolidinium}
[AsMo₁₂O₄₀]³⁻·3{N-benzyl-2-((4-iodobenzoyl)oxy)-N,N-dimethylethane-1-aminum}
[SiMo₁₂O₄₀]⁴⁻·4{2-(acryloyloxy)-N-benzyl-N,N-dimethylethane-1-aminum}
[GeMo₁₂O₄₀]⁴⁻·4{2-{(azidebenzoyl)oxy}-N-benzyl-N,N-dimethylethane-1-aminum}
[SiMo₂W₁₀O₄₀]⁴⁻·4{tetraethylphosphonium}
[SiVW₁₁O₄₀]⁵⁻·5{tetrabutylphosphonium}
[SiMo₂VW₉O₄₀]⁵⁻·5{tributyl(cyanomethyl)phosphonium}
[ZnW₁₂O₄₀[Cu(phen)(H₂O)]₂]²⁻·2{methyltriphenylphosphonium}
[SiW₁₁O₃₉]⁸⁻·8{ethyltriphenylphosphonium}
[PW₁₁O₃₉]⁸⁻·8{(formylmethyl)triphenylphosphonium}
[B₃W₃₉O₁₃₂]²¹⁻·21{tributyl(methyl)phosphonium}
[AsW₉O₃₃]⁹⁻·9{(methoxymethyl)triphenylphosphonium}
[PW₉O₃₀(C₂H₅PO₃)₂]⁶⁻·6{tetraphenylphosphonium}
[P₂W₁₈O₆₂]⁶⁻·6{acetonytriphenylphosphonium}
[As₂W₁₈O₆₂]⁶⁻·6{butyltriphenylphosphonium}
[S₂W₁₈O₆₂]⁴⁻·4{triphenylpropargylphosphonium}
[P₂Mo₁₈O₆₂]⁶⁻·6{methoxycarbonylmethyl(triphenyl)phosphonium}
[As₂Mo₁₈O₆₂]⁶⁻·6{amyltriphenylphosphonium}
[S₂Mo₁₈O₆₂]⁴⁻·4{tetrakis(hydroxymethyl)phosphonium}
[AgP₅W₃₀O₁₁₀]¹⁴⁻·14{tributyl-n-octylphosphonium}
[Sn₈W₁₈O₆₆]⁸⁻·8{benzyltriphenylphosphonium}
[Sn₃W₁₈Si₂O₆₈]¹⁴⁻·14{triphenylpropylphosphonium}
[Sn₃W₁₈P₂O₆₈]¹²⁻·12{allyltriphenylphosphonium}
[SnW₁₂O₄₂]¹⁰⁻·10{cyclopropyltriphenylphosphonium}
[Te₁₀W₂₈O₁₁₈]²⁸⁻·28{bBenzyltriphenylphosphonium}
[Te₂W₁₈Cu₃O₆₉]¹⁶⁻·16{triphenylsulfonium}
[Te₄W₂₀O₈₀]²⁴⁻·24{trimethylsulfonium}
[Te₉W₂₈O₁₁₂]²⁴⁻·24{triethylsulfonium}
[Te₂W₅₈O₁₉₈]³⁶⁻·36{tributylsulfonium}
[TeW₁₈O₆₃]⁸⁻·8{(2-carboxyethyl)dimethylsulfonium}
[TeW₁₈O₆₂]¹⁰⁻·10{(4-hydroxyphenyldimethylsulfonium}
[TeW₆O₂₄]⁶⁻·6{diphenyl(methyl)sulfonium}
[Te₂W₁₇O₆₁]¹²⁻·12{dimethyl(phenethyl)sulfonium}
[TeW₁₅O₅₄]¹⁴⁻·14{5-ethenylthianthrhenium}
[InW₁₁PO₄₀]⁸⁻·8{(difluoromethyl)bis(2,5-dimethylphenyl)sulfonium}
[InW₁₁SiO₄₀]⁹⁻·9{tri-p-tolylsulfonium}
[InW₃O₄(C₂H₄COO)₈]²²⁻·22{benzyl(4-hydroxyphenyl)methylsulfonium}
[Nb₆O₁₉]⁸⁻·8{dimesityl(trifluoromethyl)sulfonium}
[Nb₇O₂₂]⁹⁻·9{diphenyl[4-(phenylthio)phenyl]sulfonium}
[Nb₁₀O₂₈]⁶⁻·6{(thiodi-4,1-phenylene)bis(diphenylsulfonium)}
[Ta₆O₁₉]⁸⁻·8{diphenyliodonium}
[Ta₁₀O₂₈]⁶⁻·6{bis((4-tert-butylphenyl)iodonium chloride}
[Mo₆O₁₉]²⁻·2 {bis(4-methylphenyl)iodonium}
[W₆O₁₉]²⁻·2{bis(4-fluorophenyl)iodonium}
[W₇O₂₄]⁶⁻·4{(4-nitrophenyl)(phenyl)iodonium}
[W₁₀O₃₂]⁴⁻·4{(4-methylphenyl)(2,4,6-trimethylphenyl)iodonium}
[W₁₀O₃₄]⁸⁻·8{(2-methylphenyl)(2,4,6-trimethylphenyl)iodonium}
[Mo₅O₁₅(PO₄)₂]⁶⁻·6{(3-methylphenyl)(2,4,6-trimethylphenyl)iodonium}
[W₅O₁₅(PO₄)₂]⁶⁻·6{4-isobutylene(p-tolyl)iodonium}
[Mo₅O₁₅(HPO₄)₂]⁴⁻·4{phenyl[3-(trifluoromethyl)phenyl]iodonium}
[Mo₅O₁₅(SO₃)₂]⁴⁻·4{bis(2,4,6-trimethylphenyl]iodonium}
[Mo₇O₂₄]⁶⁻·6{[4-(trifluoromethyl)phenyl](2,4,6-trimethylphenyl)iodonium}
[Mo₈O₂₆]⁴⁻·4{[3-(trifluoromethyl)phenyl](2,4,6-trimethylphenyl)iodonium}
[Mo₁₀O₃₄]⁸⁻·8{phenyl(2,4,6-trimethoxyphenyl]iodine}
[W₁₂O₄₀(OH)₂]¹⁰⁻·10{(3-bromophenyl)(mesityl)iodonium}
[W₁₂O₃₈(OH)₂]⁶⁻·6{bis(4-bromophenyl)iodonium}
[V₄O₁₂]⁴⁻·4{4-biphenylyl](2,4,6-trimethoxyphenyl)iodonium}
[V₁₀O₂₈]⁶⁻·6{(5-fluoro-2-nitrophenyl(2,4,6-trimethoxyphenyl)iodonium}
[V₁₂O₃₂]⁴⁻·4{[(4-(trifluoromethyl)phenyl]-2-nitrophenyl(2,4,6-trimethoxyphenyl)iodonium}
[V₁₃O₃₄]⁴⁻·4{(3,5-dichlorophenyl)(2,4,6-trimethoxyphenyl)iodonium}
[V₁₈O₄₂]¹²⁻·12{[4-fluoro-3-(trifluoromethyl)phenyl(2,4,6-trimethoxyphenyl)iodonium}
[NbW₅O₁₉]³⁻·3{[4-(bromomethyl)phenyl](2,4,6-trimethoxyphenyl)iodonium}
[Nb₄W₁₂O₁₉]⁶⁻·6 {[4-(octyloxy)phenyl](phenyl)iodonium}
[V₂W₄O₁₉]⁴⁻·4{[4-[(2-hydroxytetradecyl)oxy]phenyl]phenyliodonium}
[NbVW₄O₁₉]⁴⁻·4{(4-isopropenyl)(p-tolyl)iodonium}
[VsMo₈O₄₀]⁷⁻·7{4-isopropyl-4′-methyldiphenyliodonium}
[Mo₆O₁₈(NO)]³⁻·3{pyridinium}
[MoO₁₇(NC₆H₅)₂]²⁻·2{1-methylpyridinium}
[TeMo₆O₂₄]⁶⁻·6{1-ethylpyridinium}
[CoW₆As₆O₃₀]⁴⁻·4{1-propylpyridinium}
[MnMo₆O₁₈(CH₃C(CH₂O)₃)₂]³⁻·3{1-acetonylpyridinium}
[ZnMoO₁₈(CH₃C(CH₂O)₃)₂]⁴⁻·4{1-butylpyridinium}
[Mo₈O₂₄(CH₃C(CH₂O)₃)₂]⁶⁻·6{1-butyl-4-methylpyridinium}
[W₆O₁₈S]²⁻·2{1-butyl-3-methylpyridinium}
[W₃OS₈]²⁻·2{1-ethyl-2-methylpyridinium}
[W₄S₁₂]²⁻·2{1-ethyl-4-methylpyridinium}
[SW₁₂O₄₀]²⁻·2{1-(3-sulfopropyl)-2-vinylpyridinium}
[PW₁₂O₄₀]³⁻·3{4-dimethylamino-1-neopentylpyridinium}
[AsW₁₂O₄₀]³⁻·3{1,4-dimethylpyridinium}
[SiW₁₂O₄₀]⁴⁻·4{1-ethyl-3-methylpyridinium}
[GeW₁₂O₄₀]⁴⁻·4{2-chloro-1-methylpyridinium}
[BW₁₂O₄₀]⁵⁻·5{1,1′-dimethyl-4,4′-bipyridinium}
[AlW₁₂O₄₀]⁵⁻·5 {4-tert-butyl-1-(3-sulfopropyl)pyridinium}
[GaW₁₂O₄₀]⁵⁻·5{1-ethyl-3-(hydroxymethyl)pyridinium}
[FeW₁₂O₄₀]⁵⁻·5{2-bromo-1-ethylpyridinium}
[ZnW₁₂O₄₀]⁶⁻·6{1-(2,4-dinitrophenyl)pyridinium}
[CoW₁₂O₄₀]⁶⁻·6{2-fluoro-1-methylpyridinium}
[SMo₁₂O₄₀]²⁻·2{1-dodecylpyridinium}
[PMo₁₂O₄₀]³⁻·3{1-ethylquinolinium}
[AsMo₁₂O₄₀]³⁻·3{1-ethyl-4-(methoxycarbonyl)pyridinium}
[SiMo₁₂O₄₀]⁴⁻·4{10-methylacridinium}
[GeMo₁₂O₄₀]⁴⁻·4{1-ethylquinaldinium}
[SiMo₁₂W₁₀O₄₀]⁴⁻·4{1-hexylpyridinium}
[SiVW₁₁O₄₀]⁵⁻·5{1-tetradecylpyridinium}
[SiMo₂VW₉O₄₀]⁵⁻·5{2-benzyloxy-1-methylpyridinium}
[ZnW₁₂O₄₀(Cu(phen)(H₂O))₂]²⁻·2{1-hexadecyl-4-methylpyridinium}
[SiW₁₁O₃₉]⁸⁻·8{cetylpyridinium}
[PW₁₁O₃₉]⁸⁻·8{hexadecylpyridinium}
[B₃W₃₉O₁₃₂]²¹⁻·21{10-methyl-9-phenylacridinium}
[AsW₉O₃₃]⁹⁻·9{1,1′-diethyl-4,4′-bipyridinium}
[PW₉O₃₄(C₂H₅₀PO₃)₂]⁶⁻·6{1,1′-dibenzyl-4,4′-bipyridinium}
[P₂W₁₈O₆₂]⁶⁻·6{imidazolium}
[As₂W₁₈O₆₂]⁶⁻·6{1,3-dimethylimidazolium}
[S₂W₁₈O₆₂]⁴⁻·4{1-ethyl-3-methylimidazolium}
[P₂Mo₁₈O₆₂]⁶⁻·6{1-allyl-3-methylimidazolium}
[As₂Mo₁₈O₆₂]⁶⁻·6{1-methyl-3-propylimidazolium}
[S₂Mo₁₈O₆₂]⁴⁻·4 {1-(2-hydroxyethyl)-3-methylimidazolium}
[Ag₂P₅W₃₀O₁₀]¹⁴⁻·14{1-butyl-3-methylimidazolium}
[Sn₈W₁₈O₆₆]⁸⁻·8{1-butyl-2,3-dimethylimidazolium}
[Sn₃W₁₈Si₂O₆₈]¹⁴⁻·14{1-hexyl-3-methylimidazolium}
[Sn₃W₁₈P₂O₆₈]¹²⁻·12{1-benzyl-3-methylimidazolium}
[SnW₁₂O₄₂]¹⁰⁻·10{2-chloro-1,3-dimethylimidazolium}
[Te₁₀W₂₈O₁₁₈]²⁸⁻·28{1,3-diisopropylimidazolium}
[Te₂W₁₈Cu₃O₆₉]¹⁶⁻·16{1-methyl-3-n-octylimidazole}
[Te₄W₂₀O₈₀]²⁴⁻·24{3-butyl-1-vinylimidazolium}
[Te₉W₂₈O₁₁₂]²⁴⁻·24 {1-methyl-3-pentylimidazolium}
[Te₂W₅₈O₁₉₈]³⁶⁻·36{1,3-di-tert-butylimidazolium}
[TeW₁₈O₆₃]⁸⁻·8{1,3-dicyclohexylimidazolium}
[TeW₁₈O₆₂]¹⁰⁻·10{1,3-diisopropylbenzimidazolium}
[TeW₆O₂₄]⁶⁻·6{1-decyl-3-methylimidazolium}
[Te₂W₁₇O₆₁]¹²⁻·12{1-hexadecyl-3-methylimidazolium}
[TeW₁₅O₅₄]¹⁴⁻·14{1-carbobenzoxy-3-methylimidazolium}
[InW₁₁PO₄₀]⁸⁻·8{1-methyl-3-[6-(methylthio)hexyl]imidazolium}
[InW₁₁SiO₄₀]⁹⁻·9{1,1′-(2,6-pyridinediyl)bis(3-methylimidazolium)}
[InW₃O₄](C₂H₄COO)₈]²²⁻·22{3-ethyl-1-vinylimidazolium}
[Nb₆O₁₉]⁸⁻·8{3,3′-methylenebis(1-tert-butyl-3-imidazolium)}
[Nb₇O₂₂]⁹⁻·9{1,3-di(1-adamantyl)imidazolium}
[Nb₀O₂₈]⁶⁻·6{1,3-bis(2,6-diisopropylphenyl)imidazolium}
[Ta₆O₁₉]⁸⁻·8{4-methoxybenzenediazonium}
[Ta₁₀O₂₈]⁶⁻·6{4-nitrobenzenediazonium}
[MoO₁₉]²⁻·2{4-bromobenzenediazonium}
[W₆O₁₉]²⁻·2{4-aminodiphenylaminediazonium}
[W₇O₂₄]⁶⁻·6{4-(pentafluorosulfanyl)phenylaminediazonium}
[W₁₀O₃₂]⁴⁻·4{4-[N-(4-methoxyphenyl)amino]benzenediazonium}
[W₁₀O₃₄]⁸⁻·8{guanidinium}
[Mo₅O₁₅(PO₄)₂]⁶⁻·6{1,1,3,3-tetramethylguanidinium}
[W₅O₁₅(PO₄)₂]⁶⁻·6{1-acetylguanidinium}
[Mo₅O₁₅(HPO₄)₂]⁴⁻·4{1-methylguanidinium}
[Mo₅O₁₅(SO₃)₂]⁴⁻·4{1,3,4,6,7,8-hexahydro-2H-pyrimido[1,2-a]pyrimidinium}
[MoO₂₄]⁶⁻·6{1,3,4,6,7,8-hexahydro-1-methyl-2H-pyrimido[1,2-a]pyrimidiniumium}
[Mo₈O₂₆]⁴⁻·4{2-tert-butyl-1,1,3,3-tetramethylguanidinium}
[Mo₁₀O₃₄]⁸⁻·8{1,3-diphenylguanidinium}
[W₁₂O₄₀(OH)₂]¹⁰⁻·10{1,3-di-o-tolylguanidinium}
[W₁₂O₃₈(OH)₂]₆₋·6{1,1-dimethylhydrazinium}
[V₄O₁₂]⁴⁻·4{1-methyl-1-phenylhydrazinium}
[V₁₀O₂₈]⁶⁻·6{phenylhydrazinium}
[V₁₂O₃₂]⁴⁻·4{1,1-diphenylhydrazinium}
[V₁₃O₃₄]⁴⁻·4{1-acetyl-2-phenylhydrazinium}
[V₁₈O₄₂]¹²⁻·12{4-nitrophenylhydrazinium}
[NbW₅O₁₉]³⁻·3{2-methylphenylhydrazinium}
[Nb₄W₂O₁₉]⁶⁻·6{4-methoxyphenylhydrazinium}
[V₂W₄O₁₉]⁴⁻·4{2-methoxyphenylhydrazinium} and
[NbVW₄O₁₉]⁴⁻·4{3-(trifluoromethyl)phenylhydrazinium}.

One type of the ionic salt (A) included in the radiation-sensitive resist composition of the disclosure may be used alone or two or more types thereof may be used in combination.

Specifically, the ionic salt (A) according to at least one example embodiment may be one or more of the following compounds:
[PMo₁₂O₄₀]³⁻·3{tris[2-(2-methoxyethoxy)ethyl]ammonium}
[SiW₁₂O₄₀]⁴⁻·4(triphenylsulfonium)
[PMo₁₂O₄₀]³⁻·3(diphenyliodonium)
[PW₁₂O₄₀]³⁻·3(triphenylsulfonium)
[PMo₁₂O₄₀]³⁻·3(triphenylsulfonium)
[PW₁₂O₄₀]³⁻·3(diphenyliodonium)
[SiW₁₂O₄₀]⁴⁻·4(diphenyliodonium)
[PW₁₂O₄₀]³⁻·2{tris[2-(2-methoxyethoxy)ethyl]ammonium}H
[PMo₁₂O₄₀]³⁻·2{tris[2-(2-methoxyethoxy)ethyl]ammonium}H
[SiW₁₂O₄₀]⁴⁻·4[bis(4-tert-butylphenyl)iodonium]
[SiW₁₂O₄₀]⁴⁻·4[(4-nitrophenyl)(phenyl)iodonium]
[SiW₁₂O₄₀]⁴⁻·4[(4-methylphenyl)(2,4,6-trimethylphenyl)iodonium]
[SiW₁₂O₄₀]⁴⁻·4[phenyl[3-(trifluoromethyl)phenyl]iodonium]
[SiW₁₂O₄₀]⁴⁻·4[phenyl(2,4,6-trimethoxyphenyl)iodonium]
[SiW₁₂O₄₀]⁴⁻·4[[3-(trifluoromethyl)phenyl](2,4,6-trimethylphenyl)iodonium]
[PMo₁₂O₄₀]³⁻·3(triheptylammonium)
[PMo₁₂O₄₀]³⁻·3(triethylammonium)
[PMo₁₂O₄₀]³⁻·3(pyridinium)
[PMo₁₂O₄₀]³⁻·3(N,N,N′,N′-tetramethylethylenediammonium)
[PMo₁₂O₄₀]³⁻·3(triethanolammonium)
[PMo₁₂O₄₀]³⁻·3(N,N-dimethylanilinium)
[PW₁₂O₄₀]³⁻·3(1,1-diphenylhydrazinium)
[PW₁₂O₄₀]³⁻·3(N,N-dimethylanilinium)
[SiW₁₂O₄₀]⁴⁻·4(N,N-dimethylanilinium)
[PMo₁₂O₄₀]³⁻·3(1-methylpyridinium)
[PMo₁₂O₄₀]³⁻·3(imidazolium)
[PMo₁₂O₄₀]³⁻·3(1,3-dimethylimidazolium)
[PMo₁₂O₄₀]³⁻·3(N,N,2,4,6-pentamethylanilinium)
[PMo₁₂O₄₀]³⁻·3(1,3-di-o-tolylguanidinium)
[PMo₁₂O₄₀]³⁻·3(1-phenylpiperidinium)
[PMo₁₂O₄₀]³⁻·3(triethylenediammonium)
[PMo₁₂O₄₀]³⁻·3(1,1,3,3-tetramethylguanidinium)
[PMo₁₂O₄₀]³⁻·3(methyltriphenylphosphonium)
[PMo₁₂O₄₀]³⁻·3(tetraphenylphosphonium)
[Mo₆O₁₉]²⁻·2(diphenyliodonium)
[PMo₁₂O₄₀]³⁻·3(4-methoxybenzenediazonium)
[W₁₀O₃₂]⁴⁻·4{tris[2-(2-methoxyethoxy)ethyl]ammonium}
[W₁₀O₃₂]⁴⁻·4(diphenyliodonium)
[MoO₂₄]⁶⁻·6{tris[2-(2-methoxyethoxy)ethyl]ammonium}
[MoO₂₄]⁶⁻·6(diphenyliodonium)
[SiW₁₂O₄₀]⁴⁻·4{N-benzyl-2-[(4-iodobenzoyl)oxy]-N,N-dimethylethane-1-aminum}
[W₆O₁₉]²⁻·1.4(tetrabutylammonium)0.6{N-Benzyl-2-[(4-iodobenzoyl)oxy-N,N-dimethylethane-1-aminium}
[Mo₆O₁₉]²⁻·1.2(tetrabutylammonium)0.8{N-benzyl-2-[(4-iodobenzoyl)oxy-N,N-dimethylethane-1-aminium}
[SiW₁₂O₄₀]⁴⁻·4[2-(acryloyloxy)-N-benzyl-N,N-dimethylethane-1-aminium]
[W₆O₁₉]²⁻·1.4(tetrabutylammonium)0.6[2-(acryloyloxy)-N-benzyl-N,N-dimethylethane-1-aminium]
[Mo₆O₁₉]²⁻·1.2(tetrabutylammonium)0.8[2-(acryloyloxy)-N-benzyl-N,N-dimethylethane-1-aminium]
[SiW₁₂O₄₀]⁴⁻·4[2-((4-azidebenzoyl)oxy)-N-benzyl-N,N-dimethylethane-1-aminum]
[W₆O₁₉]²⁻·1.4(tetrabutylammonium)0.6[2-((4-azidebenzoyl)oxy)-N-benzyl-N,N-dimethylethane-1-aminium]
[Mo₆O₁₉]²⁻·1.2(tetrabutylammonium)0.8[2-((4-azidebenzoyl)oxy)-N-benzyl-N,N-dimethylethane-1-aminium] and
[V₁₈O₄₂]¹²⁻·12[2-((4-azidebenzoyl)oxy)-N-benzyl-N,N-dimethylethane-1-aminum].

The ionic salt (A) of the disclosure may have a total molecular weight of about 650 to about 30,000, specifically, about 900 to about 15,000, which may improve the resolution of the radiation-sensitive resist composition.

In addition, from the viewpoint of radiation absorption and photosensitivity, in the ionic salt (A) according to the disclosure, a ratio of a molecular weight of the anion (a) to a total molecular weight of the organic cation (b) [molecular weight of the anion (a)/total molecular weight of the organic cation (b)] may be in a range of about 0.3 to about 30, specifically, about 0.5 to about 10.

In addition, the total molecular weight of the organic cation (b) may refer to the total molecular weight of all organic cations (b) included in the ionic salt. For example, five monovalent organic cations (b) may be bonded to a pentavalent anion (a), and the total molecular weight of the five monovalent organic cations (b) may be the total molecular weight of the organic cation (b).

A content of the ionic salt (A) in the total solid content of the radiation-sensitive resist composition of the disclosure may be in a range of about 20 mass % to about 100 mass %. When the content of the ionic salt (A) in the total solid content of the radiation-sensitive resist composition is less than 20 mass %, dissolution contrast may be reduced. The content of the ionic salt (A) in the total solid content of the radiation-sensitive resist composition may be in a range of about 50 mass % to about 100 mass %, specifically, about 80 mass % to about 100 mass %.

The content of the ionic salt (A) in the radiation-sensitive resist composition of the disclosure (the total amount of two or more ionic salts (A)) may be in a range of about 0.5 mass % to about 30 mass %, specifically, about 2 mass % to about 20 mass %, with respect of 100 mass % of the total mass of the radiation-sensitive resist composition.

### <Method of Preparing Ionic Salt>

A method of preparing the ionic salt (A) may be a method of performing a salt exchange reaction by mixing a compound having the anion (a) including a metal chalcogenide cluster and a compound having the organic cation (b). The salt exchange reaction may be easily performed through a known method, and if necessary, purification may be performed through a typical method as filtration, distillation, extraction, washing with water or an organic solvent, crystallization, treatment with an acid, treatment with an alkali, or column chromatography. Such purification methods may be repeated to adjust a concentration of impurities in a composition to a desired range. However, the example embodiments are not limited thereto.

The compound having the anion (a) and the compound having the organic cation (b) may be commercially available products or synthetic products.

The compound having the anion (a) and the compound having the organic cation (b) may be purified through the following method. Purification methods may include filtration, distillation, extraction, washing with water and/or an organic solvent, recrystallization, crystallization, treatment with an acid, treatment with an alkali, purification through column chromatography, and/or the like, and an appropriate method may be selected therefrom according to the properties of impurities to be removed. Among these purification methods, purification may be performed through filtration, column chromatography, recrystallization, or standardization. Specifically, purification may be performed through recrystallization. Such purification methods may be repeated to adjust a concentration of impurities in a composition to a desired range.

A structure (composition) of an ionic salt according to the disclosure may be confirmed by performing Fourier transform infrared (FT-IR) analysis, nuclear magnetic resonance (NMR) analysis, X-ray fluorescence (XRF) analysis, mass spectrometry, ultraviolet (UV) analysis, single crystal X-ray structural analysis, powder X-ray diffraction (PXRD) analysis, liquid chromatography (LC) analysis, size exclusion chromatography (SEC) analysis, thermal analysis, or the like. Details of a confirmation method are as described in the Examples below.

### [Solvent (B)]

The solvent (B) included in the radiation-sensitive resist composition of the disclosure may be a solvent selected for dissolving or dispersing at least the ionic salt (A) and any components that are contained as desired. As the solvent (B), a solvent used when the ionic salt (A) is synthesized may be used. One type of the solvent (B) may be used alone, or two or more types thereof may be used in combination. In addition, a mixed solvent of water and an organic solvent may be used.

Examples of the solvent may include an alcohol-based solvent, an ether-based solvent, a ketone-based solvent, an amide-based solvent, an ester-based solvent, a sulfoxide-based solvent, a hydrocarbon-based solvent, and/or the like, but the examples are not limited thereto.

More specifically, examples of the alcohol-based solvent may include a monoalcohol-based solvent such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexanol, 3,3,5-trimethylcyclohexanol, benzyl alcohol, or diacetone alcohol; a polyhydric alcohol-based solvent such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, or tripropylene glycol; and a polyhydric alcohol-containing ether-based solvent such as ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, diethylene glycol dimethyl ether, propylene glycol monomethyl ether (PGME), propylene glycol dimethyl ether, propylene glycol monoethyl ether, propylene glycol monopropyl ether, propylene glycol monobutyl ether, dipropylene glycol monomethyl ether, dipropylene glycol monoethyl ether, or dipropylene glycol monopropyl ether.

Examples of the ether-based solvent may include: a dialkyl ether-based solvent such as diethyl ether, dipropyl ether, or dibutyl ether; a cyclic ether-based solvent such as tetrahydrofuran or tetrahydropyran; an aromatic ring-containing ether-based solvent such as diphenyl ether or anisole; and/or the like.

Examples of the ketone-based solvent may include: a chain ketone-based solvent such as acetone, methyl ethyl ketone, methyl n-propyl ketone, methyl n-butyl ketone, diethyl ketone, methyl iso-butyl ketone, 2-heptanone, ethyl-n-butyl ketone, methyl-n-hexyl ketone, diisobutyl ketone, or trimethylnonanone; a cyclic ketone-based solvent such as cyclopentanone, cyclohexanone, cycloheptanone, cyclooctanone, or methylcyclohexanone; 2,4-pentanedione; acetonyl acetone; acetophenone; and/or the like.

Examples of the amide-based solvent may include: a cyclic amide-based solvent such as N,N′-dimethylimidazolidinone or N-methyl-2-pyrrolidone; a chain amide-based solvent such as N-methylformamide, N,N-dimethylformamide, N,N-diethylformamide, acetamide, N-methylacetamide, N,N-dimethylacetamide, or N-methylpropionamide; and/or the like.

Examples of the ester-based solvent may include: an acetate ester-based solvent such as methyl acetate, ethyl acetate, n-propyl acetate, isopropyl acetate, n-butyl acetate, isobutyl acetate, sec-butyl acetate, t-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, or n-nonyl acetate; a polyhydric alcohol-containing ether carboxylate-based solvent such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate (PGMEA), propylene glycol monoethyl ether acetate, propylene glycol monopropyl ether acetate, propylene glycol monobutyl ether acetate, dipropylene glycol monomethyl ether acetate, or dipropylene glycol monoethyl ether acetate; a lactone-based solvent such as γ-butyrolactone (GBL) or δ-valerolactone; a carbonate-based solvent such as dimethyl carbonate, diethyl carbonate, ethylene carbonate, or propylene carbonate; a lactate ester-based solvent such as methyl lactate, ethyl lactate (EL), n-butyl lactate, or n-amyl lactate; glycoldiacetate; methoxytriglycol acetate; ethyl propionate; n-butyl propionate; isoamyl propionate, diethyloxalate; di-n-butyloxalate, methyl acetoacetate; ethyl acetoacetate; diethyl malonate; dimethyl phthalate; diethyl phthalate; and/or the like.

Examples of the sulfoxide-based solvent may include dimethyl sulfoxide, diethyl sulfoxide, and/or the like.

Examples of the hydrocarbon-based solvent may include: an aliphatic hydrocarbon-based solvent such as n-pentane, isopentane, n-hexane, isohexane, n-heptane, isoheptane, 2,2,4-trimethylpentane, n-octane, isooctane, cyclohexane, or methylcyclohexane; and an aromatic hydrocarbon-based solvent such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, n-amylnaphthalene; and/or the like.

Specifically, the solvent (B) may be selected from an alcohol-based solvent, a ketone-based solvent, an amide-based solvent, an ester-based solvent, a sulfoxide-based solvent, any combination thereof and/or the like.

More specifically, the solvent (B) may be selected from PGME, propylene glycol monoethyl ether, cyclohexanone, PGMEA, N-methyl-2-pyrrolidone, N,N-dimethylacetamide, EL, dimethyl sulfoxide, and/or any combination thereof.

In particular, since the solvent (B) may not substantially include water the radiation-sensitive resist composition may not substantially include water. Specifically, the radiation-sensitive resist composition may include water in an amount of 3 mass % or less with respect to the total mass of the radiation-sensitive resist composition, and the solvent (B) may include water in an amount of 3 mass % or less with respect to the total mass of the solvent (B). Thereby, the solvent (B) and/or the radiation-sensitive resist composition may be referred to as being substantially anhydrous.

### <Additional Components>

In addition to the ionic salt (A) and the solvent (B), the radiation-sensitive resist composition of the disclosure may include one or more additional components such as a radiation-sensitive acid generator, a fluorine atom-containing polymer, a surfactant, a crosslinking agent, a leveling agent, a colorant, a combination thereof, and/or the like.

The surfactant may exhibit an effect of improving applicability, striation, developability, and/or the like. A specific example of the surfactant may include, for example, a nonionic surfactant such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, or polyethylene glycol distearate. As the surfactant, a commercially available product or a synthetic product may be used. Examples of the commercially available product of the surfactant may include, for example, KP341 (manufactured by Shin-Etsu Chemical Co., Ltd.), Polyflow No. 75 and Polyflow No. 95 (manufactured by Kyoeisha Chemical Co., LTD.), Eftop EF301, Eftop 303, and Eftop 352 (manufactured by Mitsubishi Materials Electronic Chemicals Co., Ltd.), MEGAFACE™ F171, MEGAFACE™ F173, R-40, R-41, and R-43 (products manufactured by DIC Corporation), Fluorad™ FC430 and Fluorad™ FC431 (manufactured by Sumitomo 3M, Ltd.), Asahi Guard™ AG710 (manufactured by AGC Seimi Chemical Co., Ltd.), and Surflon™ S-382, Surflon™ SC-101, Surflon™ SC-102, Surflon™ SC_103, Surflon™ SC-104, Surflon™ SC-105, and Surflon™ SC-106 (manufactured by AGC Seimi Chemical Co., Ltd.), and/or the like.

Examples of the crosslinking agent may include, for example, a melamine-based crosslinking agent, a substituted urea-based crosslinking agent, or a polymer-based crosslinking agent, but one or more embodiments are not limited thereto. A crosslinking agent having at least two crosslinking-forming substituents may include, for example, a compound such as methoxymethylated glycoluril, butoxymethylated glycoluril, methoxymethylated melamine, butoxymethylated melamine, methoxymethylated benzoguanamine, butoxymethylated benzoguanamine, methoxymethylated urea, butoxymethylated urea, methoxymethylated thiourea, and/or the like.

The leveling agent may be used to improve the flatness of a coating film during printing (application), and any known leveling agent that is available commercially may be used.

In addition, in the radiation-sensitive resist composition of the disclosure, a silane coupling agent may be used as any component to improve adhesion to a substrate or the like. Examples of the silane coupling agent may include, for example: vinyltrimethoxysilane, vinyltriethoxysilane, vinyltrichlorosilane, or vinyltris(β-methoxyethoxy)silane; a silane compound having a carbon-carbon unsaturated bond such as 3-methacryloxypropyl trimethoxysilane, 3-acryloxypropyl trimethoxysilane, p-styryl trimethoxysilane, 3-methacryloxypropylmethyl dimethoxysilane, or 3-methacryloxypropylmethyl diethoxysilane; trimethoxy[3-(phenylamino)propyl]silane; and/or the like.

An usage amount of any additional components may be adjusted and appropriately set according to the desired physical properties. In addition, any additional components may be used alone or in combination of two or more.

A method of preparing the radiation-sensitive resist composition of the disclosure is not particularly limited, and for example, a method of mixing the ionic salt (A) and any component added as needed in the solvent (B). A temperature or time during mixing is not particularly limited. Filtration may be performed after the mixing if necessary.

### [Pattern Formation Method]

A pattern formation method using a radiation-sensitive resist composition of the disclosure is not particularly limited.

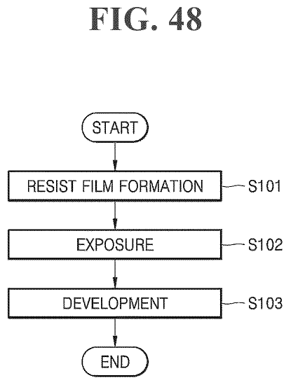

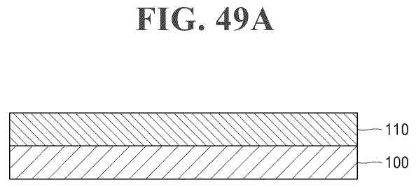

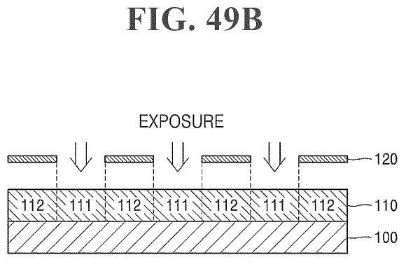

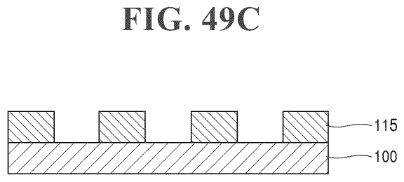

Hereinafter, a pattern formation method according to embodiments will be described in more detail with reference to FIGS. 48 and 49A to 49C. FIG. 48 is a flowchart illustrating the pattern formation method according to embodiments, and FIGS. 49A to 49C are side cross-sectional views illustrating the pattern formation method according to embodiments. Hereinafter, a case in which the radiation-sensitive resist composition is a positive type radiation-sensitive resist composition will be described in detail as an example, but one or more embodiments are not limited thereto.

Referring to FIG. 48, the pattern formation method may include operation S101 of applying a radiation-sensitive resist composition onto a substrate to form a resist film (hereinafter referred to as “application process”), operation S102 of exposing at least a portion of the resist film to radiation through the application process (hereinafter referred to as “exposure process”), and operation S103 of developing the exposed resist film by using a developer (hereinafter referred to as “development process”). Such operations may be omitted if necessary or may be performed in a different order.

Since the pattern formation method uses the radiation-sensitive resist composition according to at least one example embodiment, a pattern with higher sensitivity, higher developability, and/or higher resolution may be formed. Hereinafter, each process will be described.

### <Application Process>

In a process, according to at least one example embodiment, a radiation-sensitive resist composition may be applied onto one surface of a substrate 100 to form a resist film 110.

First, the substrate 100 may be prepared. The substrate 100 may include, for example, a semiconductor substrate (such as a silicon substrate or a germanium substrate), glass, quartz, ceramic, copper, and/or the like. In some embodiments, the substrate 100 may include a Group III-V compound such as GaP, GaAs, or GaSb.

An application method is not particularly limited, and examples thereof may include spin coating, spray coating, dip coating, knife edge coating, inkjet printing, and screen printing.

Specifically, after the radiation-sensitive resist composition is applied such that the obtained resist film has a certain thickness, post-application bake (PAB) may be performed as needed, thereby removing a solvent remaining on the resist film.

A film thickness of the resist film after the PAB may be in a range of about 1 nanometer (nm) to about 1,000 nm. More specifically, the film thickness of the resist film after the PAB may be 5 nm or more, 10 nm or more, 200 nm or less, or 100 nm or less.

A lower limit of a temperature of the PAB may be 60° C. or more, specifically, 80° C. or more. In addition, an upper limit of the temperature of the PAB may be 150° C. or less, specifically, 140° C. or less. A lower limit of a time of the PAB may be 5 seconds or more, specifically, 10 seconds or more. An upper limit of the time of the PAB may be 600 seconds or less, specifically, 300 seconds or less.

Before the resist composition is applied onto the substrate 100, an etching target film (not shown) may be further formed on the substrate 100. The etching target film may refer to a layer on which an image is transferred from a resist pattern 115 and converted into a certain pattern. In at least one example embodiment, the etching target film may be formed to include, for example, an insulating material such as silicon oxide, silicon nitride, and/or silicon oxynitride. In some embodiments, the etching target film may be formed to include a conductive material such as a metal, a metal nitride, a metal silicide, or a metal silicide nitride. In some embodiments, the etching target film may be formed to include a semiconductor material such as polysilicon.

In at least one example embodiment, an antireflection film may be further formed on the substrate 100 to maximize the efficiency of a resist. The antireflection film may be an organic and/or inorganic antireflection film.

In at least one example embodiment, a protective film may be further provided on the resist film 110 to reduce the influence of alkaline impurities or the like included during a process. In addition, when immersion exposure is performed, for example, a protective film for immersion may also be installed on the resist film 110 to avoid direct contact between an immersion medium and the resist film 110.

### <Exposure Process>

Next, at least a portion of the resist film 110 may be exposed to radiation. For example, radiation passing through a mask 120 may be irradiated onto at least a portion of the resist film 110. Thus, the resist film 110 may have an exposed portion 111 and an unexposed portion 112 based on a pattern included in the mask 120.

In some cases, the exposure may be performed by irradiating radiation through a mask 120 with a certain pattern by using an immersion medium such as water. Examples of the radiation may include electromagnetic waves such as visible light, ultraviolet (UV) rays, deep ultraviolet (DUV) rays, EUV rays (with a wavelength of 13.5 nm), X-rays, and γ-rays; and charged particle beams such as electron beams (EBs) and α-rays. Irradiating these radiations may be collectively referred to as “exposure.”

In particular, among these radiations, EUV rays or EBs may be used.

Examples of an exposure light source may include various light sources such as a light source that emits laser light in an ultraviolet (UV) region, such as a KrF excimer laser (with a wavelength of 248 nm), an ArF excimer laser (with a wavelength of 193 nm), or an F₂ excimer laser (with a wavelength of 157 nm), a light source that converts a wavelength of laser light from a solid-state laser light source (yttrium aluminum garnet (YAG) or semiconductor laser or the like) to emit harmonic laser light in a far UV or vacuum UV region, and a light source that irradiates EBs or EUV rays. During exposure, the exposure may be usually performed through a mask corresponding to a desired pattern, but when exposure light is an EB, the exposure may be performed through direct writing without using a mask.

Regarding an integral dose of radiation, for example, when EUV rays are used as the radiation, the integral dose may be 2,000 mJ/cm² or less, specifically, 500 mJ/cm² or less. In addition, when EBs are used as the radiation, the integral dose may be 5,000 μC/cm² or less, specifically, 1,000 μC/cm² or less.

In addition, post-exposure bake (PEB) may be performed. A lower limit of a temperature of the PEB may be 50° C. or more, specifically, 80° C. or more. An upper limit of the temperature of the PEB may be 180° C. or less, specifically, 130° C. or less. A lower limit of a time of the PEB may be 5 seconds or more, specifically, 10 seconds or more. An upper limit of the time of the PEB may be 600 seconds or less, specifically, 300 seconds or less.

### <Development Process>

Next, the exposed resist film 110 may be developed by using a developer to form the resist pattern 115. In this case, the exposed portion 111 may be washed away and removed by the developer, and the unexposed portion 112 may remain without being washed away by the developer.

Examples of the developer used in the development may include: water such as pure water or ultrapure water; an alkaline developer; and a developer including an organic solvent (hereinafter referred to as “organic developer”). Examples of a development method may include a dipping method, a puddle method, a spray method, a dynamic injection method, and/or the like. A development temperature may be, for example, in a range of about 5° C. to about 60° C., and a development time may be, for example, in a range of about 5 seconds to about 300 seconds.

The alkaline developer may include, for example, an alkaline aqueous solution in which one or more alkaline compounds such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethyamine, ethyldimethylamine, triethanolamine, tetramethyl ammonium hydroxide (TMAH), pyrrole, piperidine, choline, 1,8-diazabicyclo[5.4.0]-7-undecene (DBU), and 1,5-diazabicyclo[4.3.0]-5-nonene (DBN) are dissolved. The alkaline developer may further include a surfactant.

A lower limit of a content of the alkaline compound in the alkaline developer may be 0.1 mass % or more, specifically, 0.5 mass % or more, or more specifically, 1 mass % or more. In addition, an upper limit of the content of the alkaline compound in the alkaline developer may be 20 mass % or less, specifically, 10 mass % or less, or more specifically, 5 mass % or less.

After development, the resist pattern 115 may be washed with ultrapure water, and then the remaining water on the substrate 100 and a pattern may be removed.

In some example embodiments, the same organic solvent discussed in the part of [Solvent (B)] of [Resist composition] may be used as the organic solvent included in the organic developer.

Specifically, n-butyl acetate (nBA), PGME, PGMEA, EL, GBL, IPA, and/or the like may be used as the organic developer. The organic developer may further include an organic acid such as an acetic acid, a formic acid, or a citric acid.

A lower limit of a content of the organic solvent in the organic developer may be 80 mass % or more, specifically, 90 mass % or more, more specifically, 95 mass % or more, or particularly, 99 mass % or more.

The organic developer may also include a surfactant. In addition, a trace amount of water may be included in the organic developer. Furthermore, during development, the development may be stopped by substituting the organic developer with a solvent that is a different type therefrom.

The resist pattern 115 after the development may be further washed. Ultrapure water, a rinse solution, or the like may be used as a cleaning solution. A rinse solution is not particularly limited as long as the rinse solution does not dissolve the resist pattern 115, and a solution including a general organic solvent may be used. For example, the rinse solution may be an alcohol-based solvent or an ester-based solvent. After the washing, the rinse solution remaining on the substrate 100 and the pattern may be removed. In addition, when ultrapure water is used, water remaining on the substrate 100 and the pattern may be removed.

In addition, developers may be used alone or in a combination of two or more.

After the resist pattern 115 is formed as described above, a pattern interconnection substrate may be obtained through etching. An etching method may be performed through a known method including dry etching using plasma gas and wet etching using an alkaline solution, a copper (II) chloride solution, an iron (II) chloride solution, or the like.

After the resist pattern 115 is formed, plating may be performed. A plating method is not particularly limited, and examples thereof may include copper plating, solder plating, nickel plating, gold plating, and/or the like.

The resist pattern 115 remaining after the etching may be peeled off with an organic solvent. One or more embodiments are not limited thereto, but examples of such an organic solvent may include PGMEA, PGME, EL, and/or the like. A peeling method is not particularly limited, but examples thereof may include an immersion method, a spray method, and/or the like. In addition, the pattern interconnection substrate on which the resist pattern 115 is formed may be a multi-layer interconnection substrate or may have small-diameter through-holes.

In at least one example embodiment, the pattern interconnection substrate may be formed through a method of forming a resist pattern, depositing a metal in a vacuum, and then melting the resist pattern with a solution, that is, a lift-off method.

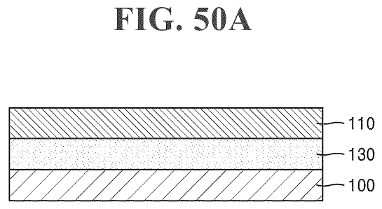

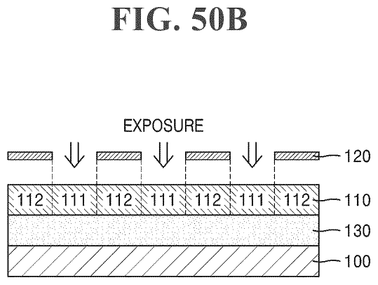

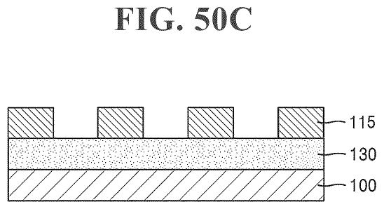

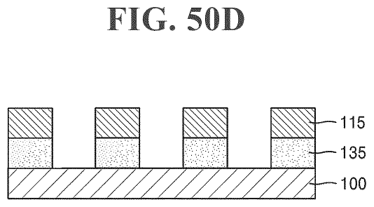

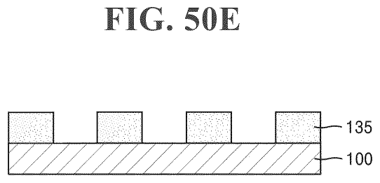

FIGS. 50A to 50E are side cross-sectional views illustrating a method of forming a patterning structure, according to at least one example embodiment.

As shown in FIG. 50A, before a resist film 110 is formed on a substrate 100, a material layer 130 may be formed on the substrate 100. The resist film 110 may be formed on the material layer 130. The material layer 130 may include an insulating material (for example, silicon oxide or silicon nitride), a semiconductor material (for example, silicon), or a metal (for example, copper). In some embodiments, the material layer 130 may have a multi-layer structure. A material of the material layer 130 may be different from a material of the substrate 100.

As shown in FIG. 50B, the resist film 110 may be subjected to a pre-exposure bake process and exposed to high-energy rays through a mask 120, and then the resist film 110 may include an exposed portion 111 and an unexposed portion 112.

As shown in FIG. 50C, the exposed resist film 110 may be developed by using a developer (for example, an organic developer). The exposed portion 111 may be washed away by the developer, and the unexposed portion 112 may remain without being washed away by the developer.

As shown in FIG. 50D, an exposed portion of the material layer 130 may be etched by using a resist pattern 115 as a mask to form a material pattern 135 on the substrate 100.

As shown in FIG. 50E, the resist pattern 115 may be removed.

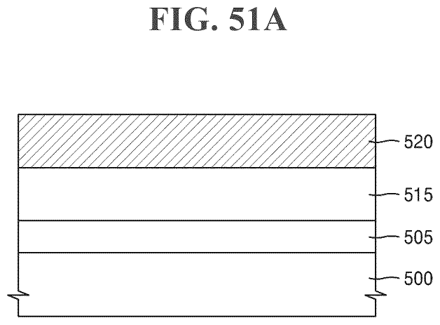

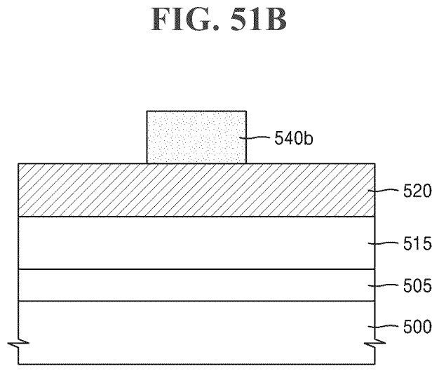

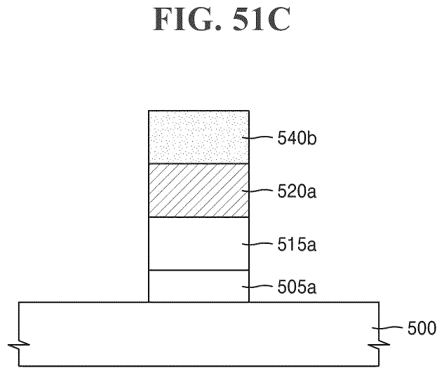

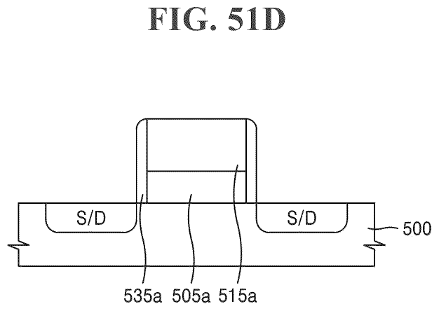

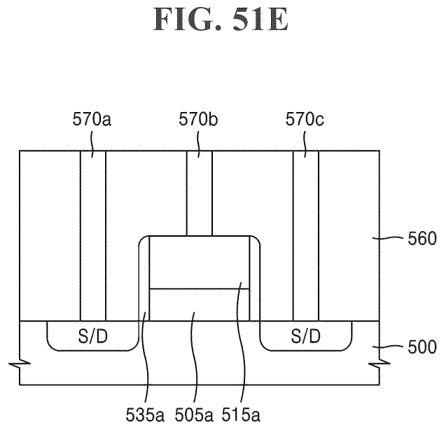

FIGS. 51A to 51E are side cross-sectional views illustrating a method of forming a semiconductor device, according to at least one example embodiment.

As shown in FIG. 51A, a gate dielectric 505 (for example, silicon oxide) may be formed on a substrate 500. The substrate 500 may be a semiconductor substrate such as a silicon substrate. A gate layer 515 (for example, doped polysilicon) may be formed on the gate dielectric 505. A hardmask layer 520 may be formed on the gate layer 515.

As shown in FIG. 51B, a resist pattern 540b may be formed on the hardmask layer 520. The resist pattern 540b may be formed by using a resist composition according to at least one example embodiment described above. The resist composition may include an organic solvent.

As shown in FIG. 51C, the gate layer 515 and the gate dielectric 505 may be etched to form a hardmask pattern 520a, a gate electrode pattern 515a, and a gate dielectric pattern 505a.

As shown in FIG. 51D, a spacer layer may be formed on the gate electrode pattern 515a and the gate dielectric pattern 505a. The spacer layer may be formed by using a deposition process (for example, chemical vapor deposition (CVD)). The spacer layer may be etched to form a spacer 535a (for example, silicon nitride) on sidewalls of the gate electrode pattern 515a and the gate dielectric pattern 505a. After the spacer 535a is formed, ions may be implanted into the substrate 500 to form source/drain impurity regions S/D.

As shown in FIG. 51E, an interlayer insulating film 560 (for example, oxide) may be formed on the substrate 500 to cover the gate electrode pattern 515a, the gate dielectric pattern 505a, and the spacer 535a. Thereafter, electrical contacts 570a, 570b, and 570c connected to the gate electrode pattern 515a and the source/drain impurity regions S/D may be formed in the interlayer insulating film 560. The electrical contacts 570a, 570b, and 570c may be formed of a conductive material (for example, metal). Although not shown, a barrier layer may be formed between a sidewall of the interlayer insulating film 560 and the electrical contacts 570a, 570b, and 570c.

FIGS. 51A to 51E illustrate an example in which a transistor is formed, but the disclosure is not limited thereto.

The resist composition according to at least one example embodiment may be used in a patterning process of forming other types of semiconductor apparatuses.

### [Use]

A radiation-sensitive resist composition according to at least one example embodiment may be suitable as a resist composition for KrF excimer laser exposure, a resist composition for ArF excimer laser exposure, a resist composition for EB exposure, or a resist composition for EUV exposure. Specifically, the radiation-sensitive resist composition according to at least one example embodiment may be a resist composition for EB exposure or a resist composition for EUV exposure, and may be suitably used for fine processing of semiconductors.

The disclosure will be described in more detail by using the following examples and comparative examples, but these are illustrative examples only and are not intended to limit the scope of the disclosure, and the technical scope of the disclosure is not limited only to the following examples.

### EXAMPLES

### [Analysis Method]

### (FT-IR Spectroscopy Measurement)

An FT-IR spectrum was measured through an attenuated total reflectance (ATR) method using an FT-IR spectrophotometer (Nicolet iS10 manufactured by Thermo Fisher Scientific Inc.).

### (Measurement of Contents of V, Nb, Ta, Mo, and W Elements (Elemental Analysis))

The total content (unit: mass %) of five elements of V, Nb, Ta, Mo, and W with respect to the total mass of an ionic salt was obtained by using an inductively coupled plasma (ICP) optical emission spectrometer (EMAX Evolution manufactured by HORIBA, Ltd.).

### Synthesis Example 1

### Compound 1: Synthesis of [PMo₁₂O₄₀]³⁻ 3{tris[2-(2-methoxyethoxy)ethyl]ammonium}

Compound 1 was synthesized according to a synthetic method described in Angew. Chem. Int. Ed. 2017, 56, 2974-2978. Specifically, after 0.797 grams (g) (2.47 millimole (mmol_) of tris[2-(2-methoxyethoxy)ethyl]amine (manufactured by Tokyo Chemical Industry Co., Ltd.) and 54.0 g of pure water were put into a 100 milliliter (ml) Nasu flask, a 6 N hydrochloric acid aqueous solution was added, and the pH was adjusted to 1.5 to obtain a tris[2-(2-methoxyethoxy)ethyl]amine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the tris[2-(2-methoxyethoxy)ethyl]amine hydrochloride aqueous solution obtained above was added dropwise. After the dropwise addition, stirring was performed at room temperature, and a supernatant was removed through centrifugation. An operation of adding 27.4 g of pure water and removing a supernatant through centrifugation was repeated twice to obtain a solid, and the obtained solid was vacuum-dried to obtain 1.51 g of compound 1 as a yellow solid.

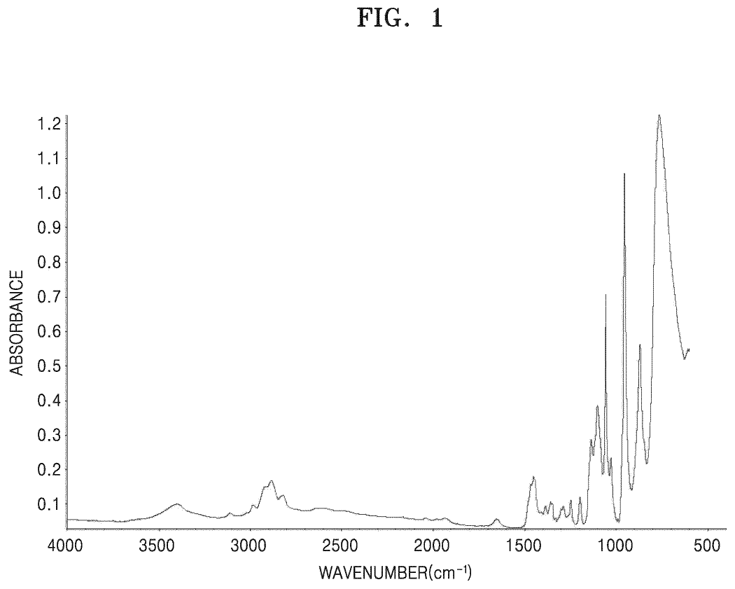

The FT-IR spectrum of obtained compound 1 is shown in FIG. 1.

### Synthesis Example 2

### Compound 2: Synthesis of [SiW₁₂O₄₀]⁴⁻·4(triphenylsulfonium)

0.700 g (0.236 mmol) of sodium 12-tungsto(VI) silicate n-hydrate (manufactured by FUJIFILM Wako Pure Chemical Corporation) and 17.5 g of dimethyl sulfoxide (manufactured by FUJIFILM Wako Pure Chemical Corporation) were put into a 100 ml Nasu flask and stirred at room temperature. Next, 0.648 g (1.89 mmol) of triphenylsulfonium bromide (manufactured by Tokyo Chemical Industry Co., Ltd.) was added and stirred at room temperature. Here, 37.1 g of pure water was added and stirred at room temperature, and then a solid was separated. The obtained solid was washed with pure water and vacuum-dried to obtain 0.861 g of compound 2 as a white solid.

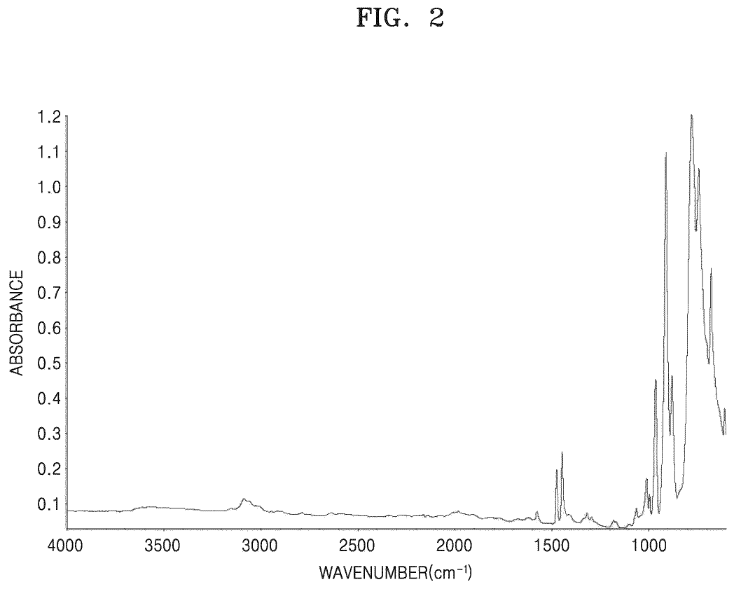

The FT-IR spectrum of obtained compound 2 is shown in FIG. 2.

### Synthesis Example 3

### Compound 3: Synthesis of [PMo₁₂O₄₀]³⁻·3(diphenyliodonium)

0.416 g (1.32 mmol) of diphenyliodonium chloride (manufactured by Tokyo Chemical Industry Co., Ltd.), 10.6 g of pure water, and 7.92 g of methanol (manufactured by FUJIFILM Wako Pure Chemical Corporation) were put into a 30 ml Nasu flask and stirred at room temperature to obtain a diphenyliodonium chloride aqueous solution. 0.400 g (0.219 mmol) of 12-molybdo(VI) phosphate n-hydrate (manufactured by FUJIFILM Wako Pure Chemical Corporation) and 10.6 g of pure water were put into another 100 ml Nasu flask and stirred at room temperature. Here, the diphenyliodonium chloride aqueous solution obtained above was added dropwise and stirred at room temperature. Here, 21.2 g of pure water was added and stirred at room temperature, and then a solid was separated. The separated solid was washed with pure water and vacuum-dried to obtain 0.436 g of compound 3 as a yellow solid.

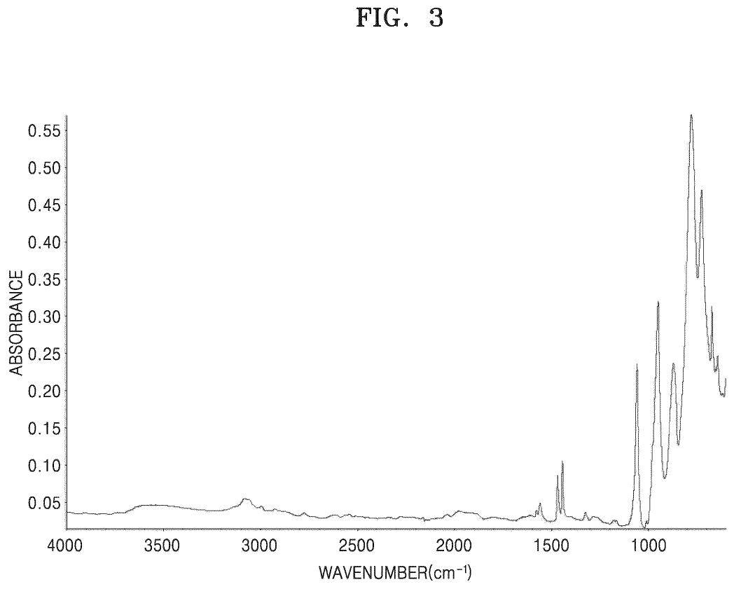

The FT-IR spectrum of obtained compound 3 is shown in FIG. 3.

### Synthesis Example 4

### Compound 4: Synthesis of [PW₁₂O₄₀]³⁻·3(triphenylsulfonium)

0.358 g (1.04 mmol) of triphenylsulfonium bromide (manufactured by Tokyo Chemical Industry Co., Ltd.) and 13.3 g of pure water were put into a 30 ml Nasu flask and stirred at room temperature to obtain a triphenylsulfonium bromide aqueous solution. 0.500 g (0.174 mmol) of 12-tungsto(VI) phosphate n-hydrate (manufactured by FUJIFILM Wako Pure Chemical Corporation) and 13.3 g of pure water were put into another 100 ml Nasu flask and stirred at room temperature. Here, the triphenylsulfonium bromide aqueous solution obtained above was added dropwise and stirred at room temperature. Here, 26.5 g of pure water was added and stirred at room temperature, and then a solid was separated. The separated solid was washed with pure water and vacuum-dried to obtain 0.532 g of compound 4 as a white solid.

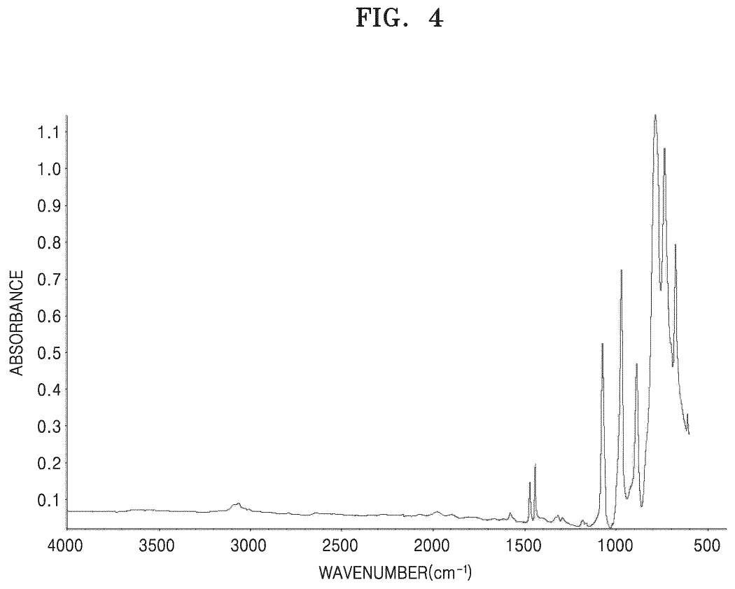

The FT-IR spectrum of obtained compound 4 is shown in FIG. 4.

### Synthesis Example 5

### Compound 5: Synthesis of [PMo₁₂O₄₀]³⁻·3(triphenylsulfonium)

0.451 g (1.32 mmol) of triphenylsulfonium bromide (manufactured by Tokyo Chemical Industry Co., Ltd.) and 10.6 g of pure water were put into a 30 ml Nasu flask and stirred at room temperature to obtain a triphenylsulfonium bromide aqueous solution. 0.400 g (0.219 mmol) of 12-molybdo(VI) phosphate n-hydrate (manufactured by FUJIFILM Wako Pure Chemical Corporation) and 10.6 g of pure water were put into another 100 ml Nasu flask and stirred at room temperature. Here, the triphenylsulfonium bromide aqueous solution obtained above was added dropwise and stirred at room temperature. Here, 21.2 g of pure water was added and stirred at room temperature, and then a solid was separated. The separated solid was washed with pure water and vacuum-dried to obtain 0.435 g of compound 5 as a yellow solid.

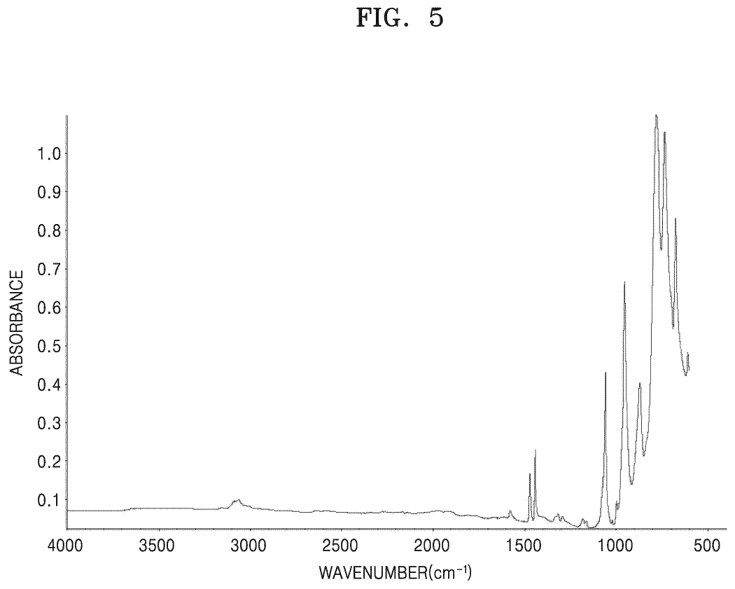

The FT-IR spectrum of obtained compound 5 is shown in FIG. 5.

### Synthesis Example 6

### Compound 6: Synthesis of [PW₁₂O₄₀]³⁻·3(diphenyliodonium)

0.330 g (1.04 mmol) of diphenyliodonium chloride (manufactured by Tokyo Chemical Industry Co., Ltd.), 13.1 g of pure water, and 6.73 g of methanol (manufactured by FUJIFILM Wako Pure Chemical Corporation) were put into a 30 ml Nasu flask and stirred at room temperature to obtain a diphenyliodonium chloride aqueous solution. 0.500 g (0.174 mmol) of 12-tungsto(VI) phosphate n-hydrate (manufactured by FUJIFILM Wako Pure Chemical Corporation) and 13.3 g of pure water were put into another 100 ml Nasu flask and stirred at room temperature. Here, the diphenyliodonium chloride aqueous solution obtained above was added dropwise and stirred at room temperature. Here, 26.5 g of pure water was added and stirred at room temperature, and then a solid was separated. The separated solid was washed with pure water and vacuum-dried to obtain 0.526 g of compound 6 as a white solid.

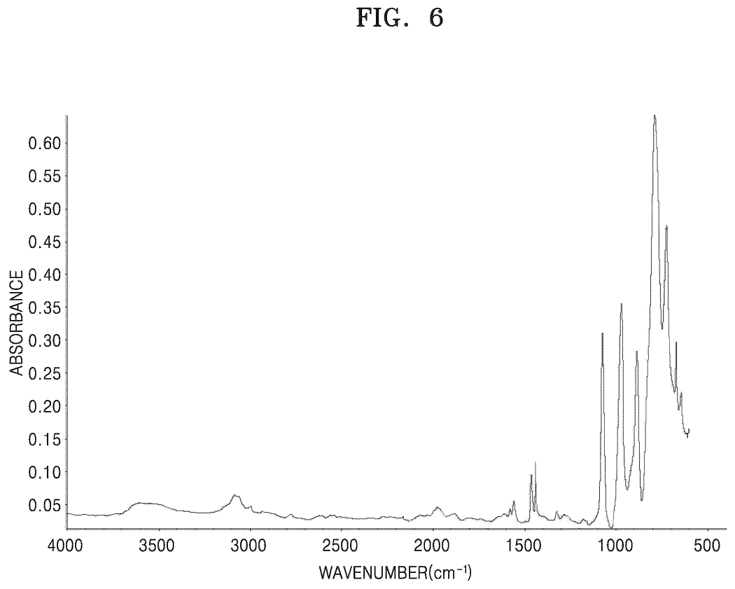

The FT-IR spectrum of obtained compound 6 is shown in FIG. 6.

### Synthesis Example 7

### Compound 7: Synthesis of [SiW₁₂O₄₀]⁴⁻·4(diphenyliodonium)

0.191 g (0.604 mmol) of diphenyliodonium chloride (manufactured by Tokyo Chemical Industry Co., Ltd.), 13.3 g of pure water, and 5.94 g of methanol (manufactured by FUJIFILM Wako Pure Chemical Corporation) were put into a 30 ml Nasu flask and stirred at room temperature to obtain a diphenyliodonium chloride aqueous solution. 0.500 g (0.151 mmol) of 12-tungsto(VI) silica n-hydrate (manufactured by FUJIFILM Wako Pure Chemical Corporation) and 13.3 g of pure water were put into another 100 ml Nasu flask and stirred at room temperature. Here, the diphenyliodonium chloride aqueous solution obtained above was added dropwise and stirred at room temperature. Here, 26.5 g of pure water was added and stirred at room temperature, and then a solid was separated. The separated solid was washed with pure water and vacuum-dried to obtain 0.543 g of compound 7 as a white solid.

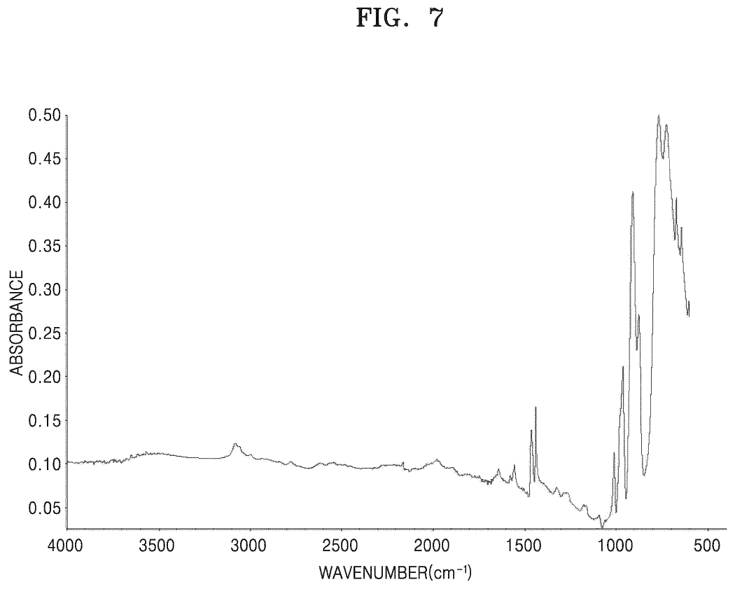

The FT-IR spectrum of obtained compound 7 is shown in FIG. 7.

### Synthesis Example 8

### Compound 8: Synthesis of [PW₁₂O₄₀]³⁻·2{tris[2-(2-methoxyethoxy)ethyl]ammonium}H

Compound 8 was synthesized according to a synthetic method described in Angew. Chem. Int. Ed. 2017, 56, 2974-2978. Specifically, after 0.112 g (0.347 mmol) of tris[2-(2-methoxyethoxy)ethyl]amine (manufactured by Tokyo Chemical Industry Co., Ltd.) and 22.8 g of pure water were put into a 30 ml Nasu flask, a 6 N hydrochloric acid aqueous solution was added, and the pH was adjusted to 1.5 to obtain a tris[2-(2-methoxyethoxy)ethyl]amine hydrochloride aqueous solution. 1.00 g (0.347 mmol) of 12-tungsto(VI) phosphate n-hydrate (manufactured by FUJIFILM Wako Pure Chemical Corporation) and 23.1 g of pure water were put into another 100 ml Nasu flask, and then the tris[2-(2-methoxyethoxy)ethyl]amine hydrochloride aqueous solution obtained above was added dropwise. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.619 g of compound 8 as a white solid.

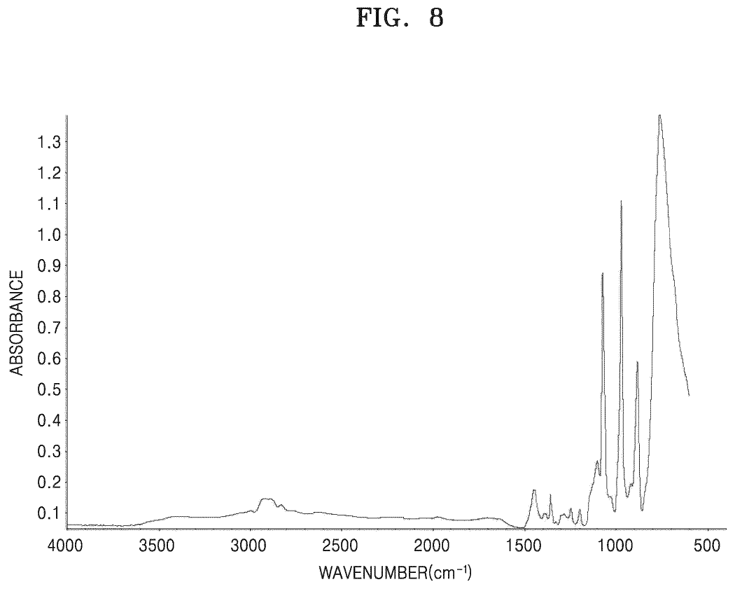

The FT-IR spectrum of obtained compound 8 is shown in FIG. 8.

### Synthesis Example 9

### Compound 9: Synthesis of [PMo₁₂O₄₀]³⁻·2{tris[2-(2-methoxyethoxy)ethyl]ammonium}H

Compound 9 was synthesized according to a synthetic method described in Angew. Chem. Int. Ed. 2017, 56, 2974-2978. Specifically, after 0.160 g (0.493 mmol) of tris[2-(2-methoxyethoxy)ethyl]amine (manufactured by Tokyo Chemical Industry Co., Ltd.) and 32.4 g of pure water were put into a 50 ml Nasu flask, a 6 N hydrochloric acid aqueous solution was added, and the pH was adjusted to 1.5 to obtain a tris[2-(2-methoxyethoxy)ethyl]amine hydrochloride aqueous solution. 0.900 g (0.493 mmol) of 12-molybdo(VI) phosphate n-hydrate (manufactured by FUJIFILM Wako Pure Chemical Corporation) and 32.9 g of pure water were put into another 100 ml Nasu flask, and then the tris[2-(2-methoxyethoxy)ethyl]amine hydrochloride aqueous solution obtained above was added dropwise. Stirring was performed at room temperature, and a supernatant was removed through centrifugation. Here, an operation of adding 16.4 g of pure water and removing a supernatant through centrifugation was repeated twice to obtain a solid, and the obtained solid was vacuum-dried to obtain 0.562 g of compound 9 as a white solid.

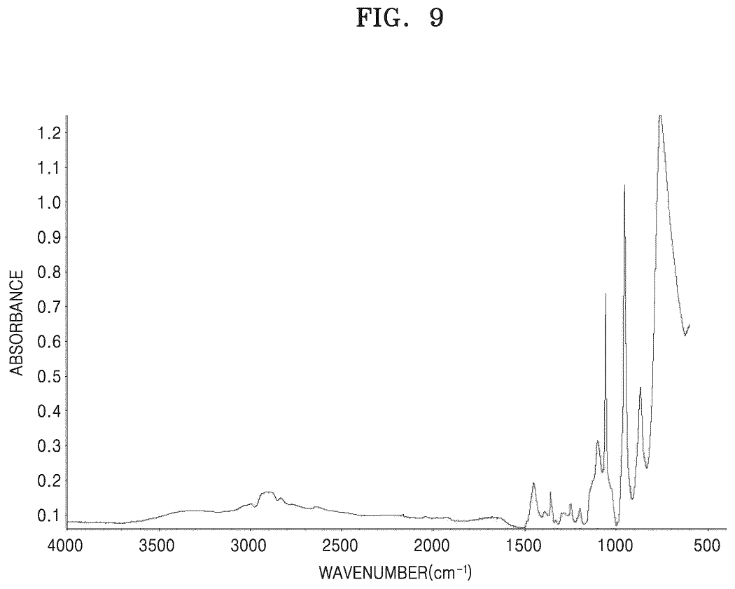

The FT-IR spectrum of obtained compound 9 is shown in FIG. 9.

### Synthesis Example 10

### Compound 10: Synthesis of [SiW₁₂O₄₀]⁴⁻·4[bis(4-tert-butylphenyl)iodonium]

0.518 g (1.21 mmol) of bis(4-tert-butylphenyl)iodonium chloride (manufactured by Tokyo Chemical Industry Co., Ltd.), 6.50 g of pure water, and 6.50 g of methanol (manufactured by FUJIFILM Wako Pure Chemical Corporation) were put into a 30 ml Nasu flask and stirred at room temperature to obtain a bis(4-tert-butylphenyl)iodonium chloride aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the bis(4-tert-butylphenyl)iodonium chloride aqueous solution obtained above was added dropwise and stirred at room temperature. Here, 6.50 g of pure water and 6.50 g of methanol were added and stirred at room temperature, and then a solid was separated. The separated solid was washed with a mixture of pure water and methanol in a mass ratio of 1:1 and vacuum-dried to obtain 0.583 g of compound 10 as a white solid.

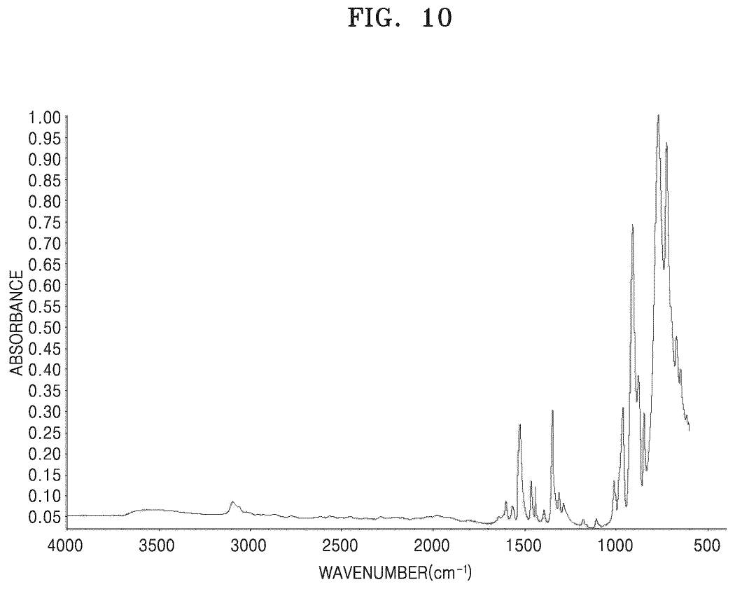

The FT-IR spectrum of obtained compound 10 is shown in FIG. 10.

### Synthesis Example 11

### Compound 11: Synthesis of [SiW₁₂O₄₀]⁴⁻·4[(4-nitrophenyl)(phenyl)iodonium]

0.574 g (1.21 mmol) of (4-nitrophenyl)(phenyl)iodonium trifluoromethanesulfonate (manufactured by Tokyo Chemical Industry Co., Ltd.), 6.50 g of pure water, and 6.50 g of methanol (manufactured by FUJIFILM Wako Pure Chemical Corporation) were input into a 30 ml Nasu flask and stirred at room temperature to obtain a (4-nitrophenyl)(phenyl)iodonium trifluoromethanesulfonate aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the (4-nitrophenyl)(phenyl)iodonium trifluoromethanesulfonate aqueous solution obtained above was added dropwise and stirred at room temperature. Here, 6.50 g of pure water and 6.50 g of methanol were added and stirred at room temperature, and a solid was separated. The separated solid was washed with a mixture of pure water and methanol in a mass ratio of 1:1 and vacuum-dried to obtain 0.658 g of compound 11 as a white solid.

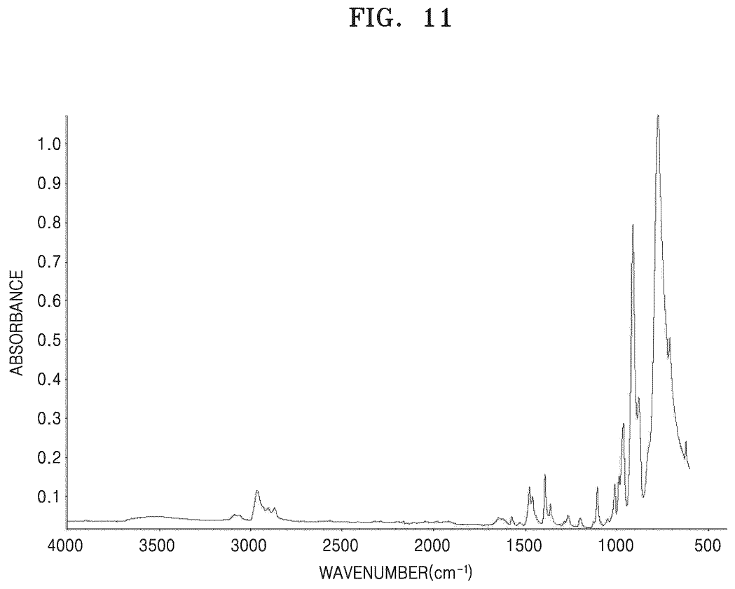

The FT-IR spectrum of obtained compound 11 is shown in FIG. 11.

### Synthesis Example 12

### Compound 12: Synthesis of SiW₁₂O₄₀]⁴⁻·4[(4-methylphenyl)(2,4,6-trimethylphenyl)iodonium]

0.588 g (1.21 mmol) of (4-methylphenyl)(2,4,6-trimethylphenyl)iodonium trifluoromethanesulfonate (manufactured by Tokyo Chemical Industry Co., Ltd.), 6.50 g of pure water, and 6.50 g of methanol (manufactured by FUJIFILM Wako Pure Chemical Corporation) were put into a 30 ml Nasu flask and stirred at room temperature to obtain a (4-methylphenyl)(2,4,6-trimethylphenyl)iodonium trifluoromethanesulfonate aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the (4-methylphenyl)(2,4,6-trimethylphenyl)iodonium trifluoromethanesulfonate aqueous solution obtained above was added dropwise and stirred at room temperature. Here, 6.50 g of pure water and 6.50 g of methanol were added and stirred at room temperature, and a solid was separated. The separated solid was washed with a mixture of pure water and methanol in a mass ratio of 1:1 and vacuum-dried to obtain 0.623 g of compound 12 as a white solid.

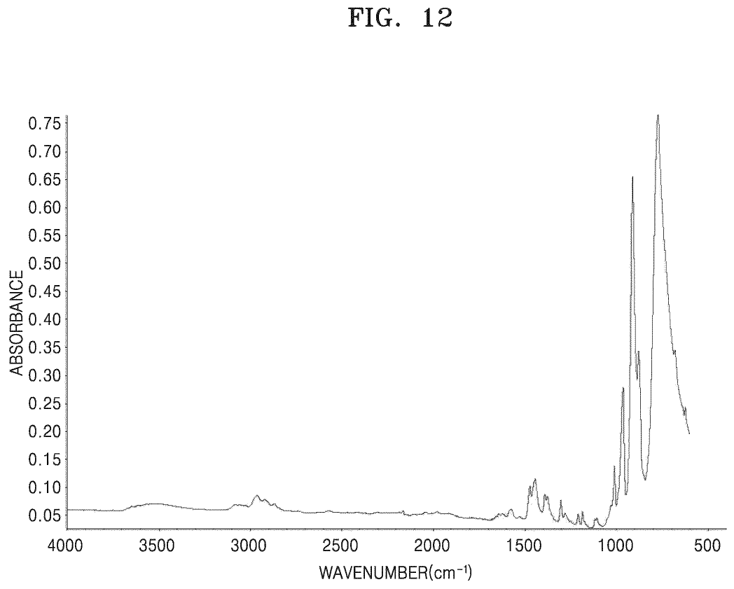

The FT-IR spectrum of obtained compound 12 is shown in FIG. 12.

### Synthesis Example 13

### Compound 13: Synthesis of [SiW₁₂O₄₀]⁴⁻·4[phenyl[3-(trifluoromethyl)phenyl]iodonium]

0.602 g (1.21 mmol) of phenyl[3-(trifluoromethyl)phenyl]iodonium trifluoromethanesulfonate (manufactured by Tokyo Chemical Industry Co., Ltd.), 6.50 g of pure water, and 6.50 g of methanol (manufactured by FUJIFILM Wako Pure Chemical Corporation) were put into a 30 ml Nasu flask and stirred at room temperature to obtain a phenyl[3-(trifluoromethyl)phenyl]iodonium trifluoromethanesulfonate aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the phenyl[3-(trifluoromethyl)phenyl]iodonium trifluoromethanesulfonate aqueous solution obtained above was added dropwise and stirred at room temperature. Here, 6.50 g of pure water and 6.50 g of methanol were added and stirred at room temperature, and a solid was separated. The separated solid was washed with a mixture of pure water and methanol in a mass ratio of 1:1 and vacuum-dried to obtain 0.618 g of compound 13 as a white solid.

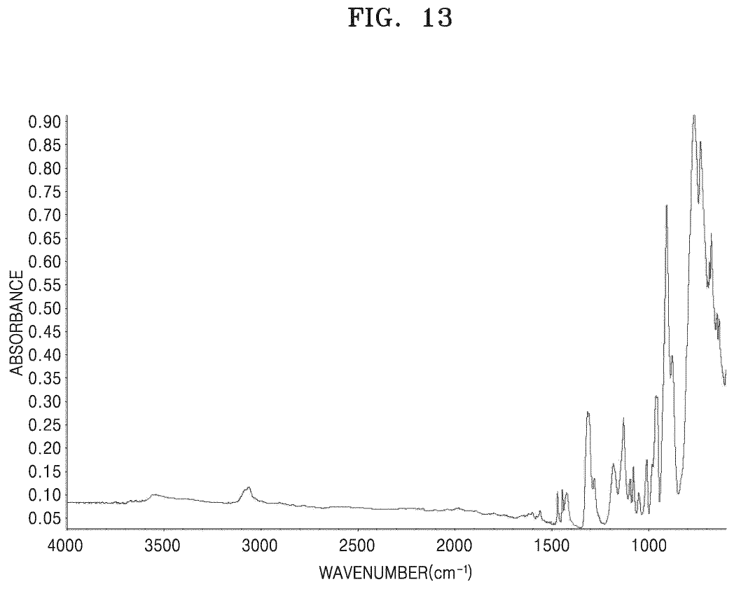

The FT-IR spectrum of obtained compound 13 is shown in FIG. 13.

### Synthesis Example 14

### Compound 14: Synthesis of [SiW₁₂O₄₀]⁴⁻·4[phenyl(2,4,6-trimethoxyphenyl)iodonium]

0.655 g (1.21 mmol) of phenyl(2,4,6-trimethoxyphenyl)iodonium tosylate (manufactured by Tokyo Chemical Industry Co., Ltd.), 6.50 g of pure water, and 6.50 g of methanol (manufactured by FUJIFILM Wako Pure Chemical Corporation) were put into a 30 ml Nasu flask and stirred at room temperature to obtain a phenyl(2,4,6-trimethoxyphenyl)iodonium tosylate aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the phenyl(2,4,6-trimethoxyphenyl)iodonium tosylate aqueous solution obtained above was added dropwise and stirred at room temperature. Here, 6.50 g of pure water and 6.50 g of methanol were added and stirred at room temperature, and a solid was separated. The separated solid was washed with a mixture of pure water and methanol in a mass ratio of 1:1 and vacuum-dried to obtain 0.645 g of compound 14 as a white solid.

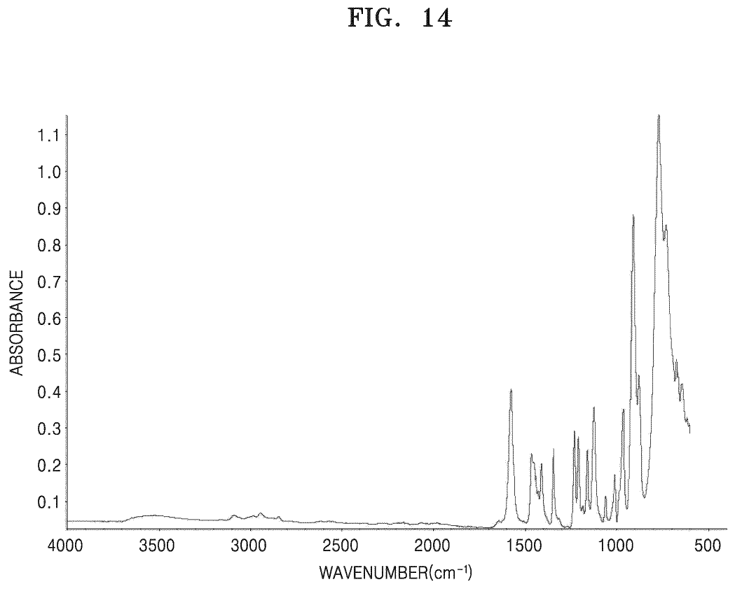

The FT-IR spectrum of obtained compound 14 is shown in FIG. 14.

### Synthesis Example 15

### Compound 15: Synthesis of [SiW₁₂O₄₀]⁴⁻·4[[3-(trifluoromethyl)phenyl](2,4,6-trimethylphenyl)iodonium]

0.653 g (1.21 mmol) of [3-(trifluoromethyl)phenyl](2,4,6-trimethylphenyl)iodonium trifluoromethanesulfonate (manufactured by Tokyo Chemical Industry Co., Ltd.), 6.50 g of pure water, and 6.50 g of methanol (manufactured by FUJIFILM Wako Pure Chemical Corporation) were put into a 30 ml Nasu flask and stirred at room temperature to obtain a phenyl(2,4,6-trimethoxyphenyl)iodonium trifluoromethanesulfonate aqueous solution. 0.500 g (0.151 mmol) of dodecatungsto(VI) silica n-hydrate (manufactured by FUJIFILM Wako Pure Chemical Corporation), 6.50 g of pure water, and 6.50 g of methanol were put into another 100 ml Nasu flask and stirred at room temperature. Here, the phenyl(2,4,6-trimethoxyphenyl)iodonium trifluoromethanesulfonate aqueous solution obtained above was added dropwise and stirred at room temperature. Here, 6.50 g of pure water and 6.50 g of methanol were added and stirred at room temperature, and a solid was separated. The separated solid was washed with a mixture of pure water and methanol in a mass ratio of 1:1 and vacuum-dried to obtain 0.658 g of compound 15 as a white solid.

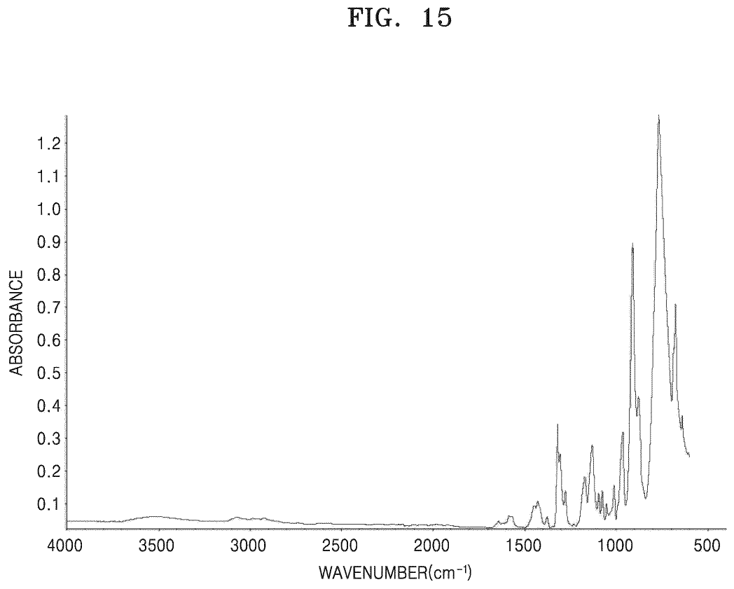

The FT-IR spectrum of obtained compound 15 is shown in FIG. 15.

### Synthesis Example 16

### Compound 16: Synthesis of PMo₁₂O₄₀]³⁻·3(triheptylammonium)

Compound 16 was synthesized according to a synthetic method described in Angew. Chem. Int. Ed. 2017, 56, 2974-2978. Specifically, 2.00 g (1.10 mmol) of 12-molybdo(VI) phosphate n-hydrate (manufactured by FUJIFILM Wako Pure Chemical Corporation) and 73.0 g of pure water were put into a 100-ml Nasu flask and stirred at room temperature to obtain a 12-molybdo(VI) phosphate n-hydrate aqueous solution. After 0.341 g (1.10 mmol) of triheptylamine (manufactured by Tokyo Chemical Industry Co., Ltd.), 68.3 g of pure water, and 2.88 g of ethanol (manufactured by FUJIFILM Wako Pure Chemical Corporation) were put into another 300 ml Nasu flask, a 6 N hydrochloric acid solution was added, and the pH was adjusted to 1.5. Next, here, the 12-molybdo(VI) phosphate n-hydrate aqueous solution obtained above was added dropwise. Stirring was performed at room temperature, and a supernatant was removed through centrifugation. Here, an operation of adding 36.5 g of pure water and removing a supernatant through centrifugation was repeated twice to obtain a solid, and the obtained solid was vacuum-dried to obtain 0.820 g of compound 16 as a yellow solid.

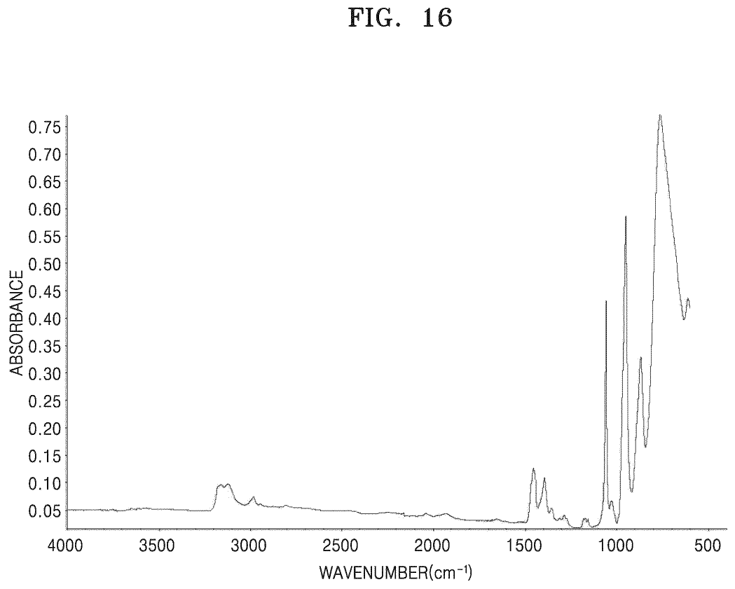

The FT-IR spectrum of obtained compound 16 is shown in FIG. 16.

### Synthesis Example 17

### Compound 17: Synthesis of [PMo₁₂O₄₀]³⁻·3(triethylammonium)

After 0.499 g (0.493 mmol) of triethylamine (manufactured by Tokyo Chemical Industry Co., Ltd.) and 32.4 g of pure water were put into a 50 ml Nasu flask, a 6 N hydrochloric acid aqueous solution was added, and the pH was adjusted to 1.5 to obtain a triethylamine hydrochloride aqueous solution. 0.900 g (0.493 mmol) of 12-molybdo(VI) phosphate n-hydrate (manufactured by FUJIFILM Wako Pure Chemical Corporation) and 32.9 g of pure water were into another 100 ml Nasu flask, and then the triethylamine hydrochloride aqueous solution obtained above was added dropwise thereto. Stirring was performed at room temperature, and a supernatant was removed through centrifugation. Here, an operation of adding 16.4 g of pure water and removing a supernatant through centrifugation was repeated twice to obtain a solid, and the obtained solid was vacuum-dried to obtain 0.261 g of compound 17 a yellow solid.

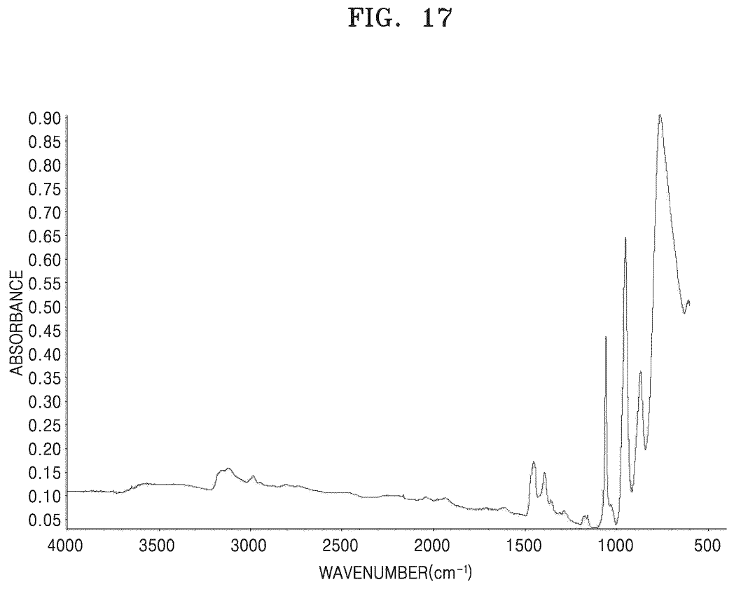

The FT-IR spectrum of obtained compound 17 is shown in FIG. 17.

### Synthesis Example 18

### Compound 18: Synthesis of [PMo₁₂O₄₀]³⁻·3(pyridinium)

After 0.0770 g (0.822 mmol) of pyridine hydrochloride (manufactured by Tokyo Chemical Industry Co., Ltd.) and 54.0 g of pure water were put into a 100 ml Nasu flask, placed, a 6 N hydrochloric acid aqueous solution was added, and the pH was adjusted to 1.5 to obtain a pyridine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the pyridine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.307 g of compound 18 as a yellow solid.

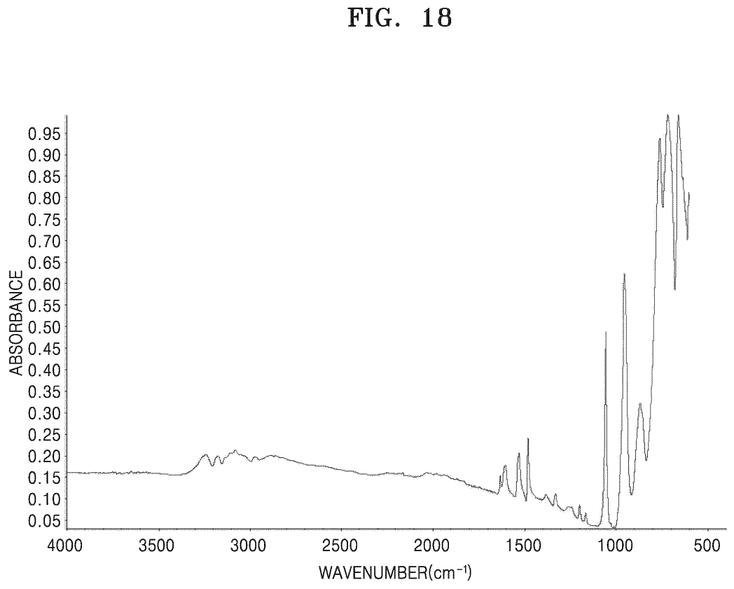

The FT-IR spectrum of obtained compound 18 is shown in FIG. 18.

### Synthesis Example 19

### Compound 19: Synthesis of [PMo₁₂O₄₀]³⁻·3(N,N,N′,N′-tetramethylethylenediammonium)

After 0.0955 g (0.822 mmol) of N,N,N′,N′-tetramethylethylenediamine (manufactured by Tokyo Chemical Industry Co., Ltd.) and 54.0 g of pure water were put into a 100 ml Nasu flask, a 6 N aqueous hydrochloric acid solution was added, and the pH was adjusted to 1.5 to obtain an N,N,N′,N′-tetramethylethylenediamine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the N,N,N′,N′-tetramethylethylenediamine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.750 g of compound 19 as a yellow solid.

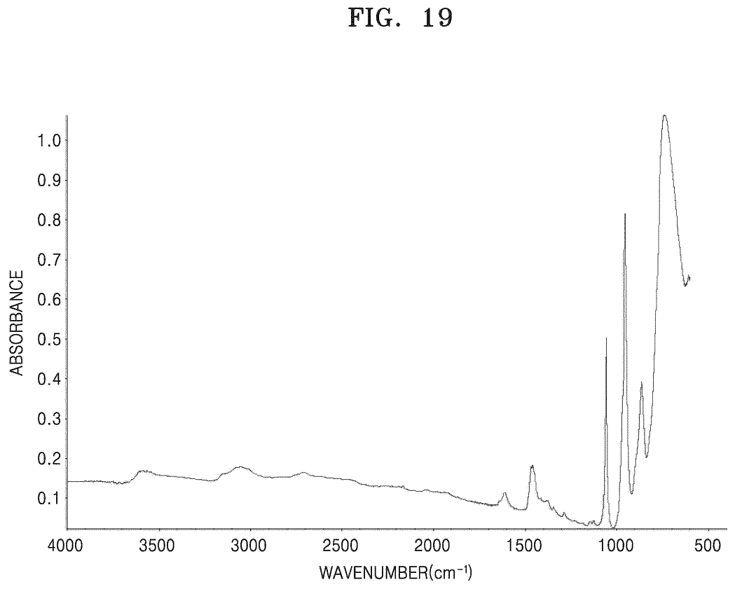

The FT-IR spectrum of obtained compound 19 is shown in FIG. 19.

### Synthesis Example 20

### Compound 20: Synthesis of [PMo₁₂O₄₀]³⁻·3(triethanolammonium)

After 0.153 g (0.822 mmol) of triethanolamine hydrochloride (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a triethanolamine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the triethanolamine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.230 g of compound 20 as a yellow solid.

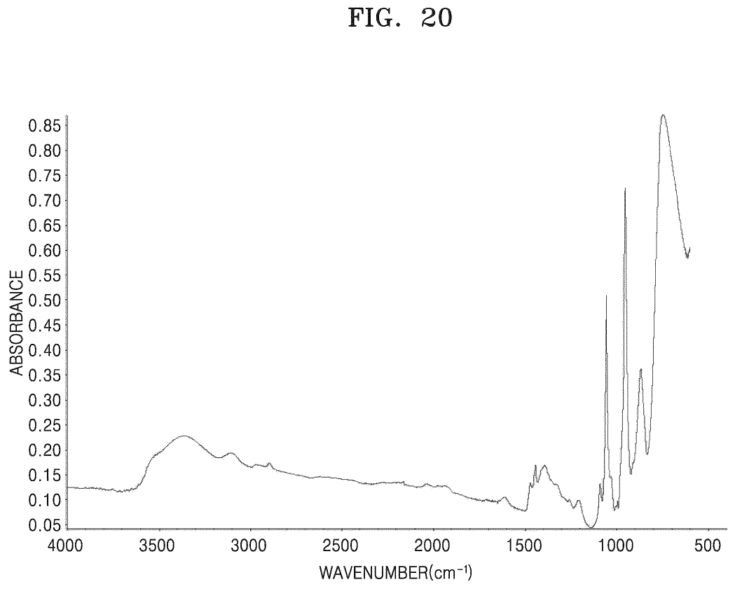

The FT-IR spectrum of obtained compound 20 is shown in FIG. 20.

### Synthesis Example 21

### Compound 21: Synthesis of [PMo₁₂O₄₀]³⁻·3(N,N-dimethylanilinium)

After 0.100 g (0.822 mmol) of N,N-dimethylaniline (manufactured by Tokyo Chemical Industry Co., Ltd.) and 54.0 g of pure water were put into a 100 ml Nasu flask, a 6 N aqueous hydrochloric acid solution was added, and the pH was adjusted to 1.5 to obtain an N,N-dimethylaniline hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the N,N-dimethylaniline hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.534 g of compound 21 as a yellow solid.

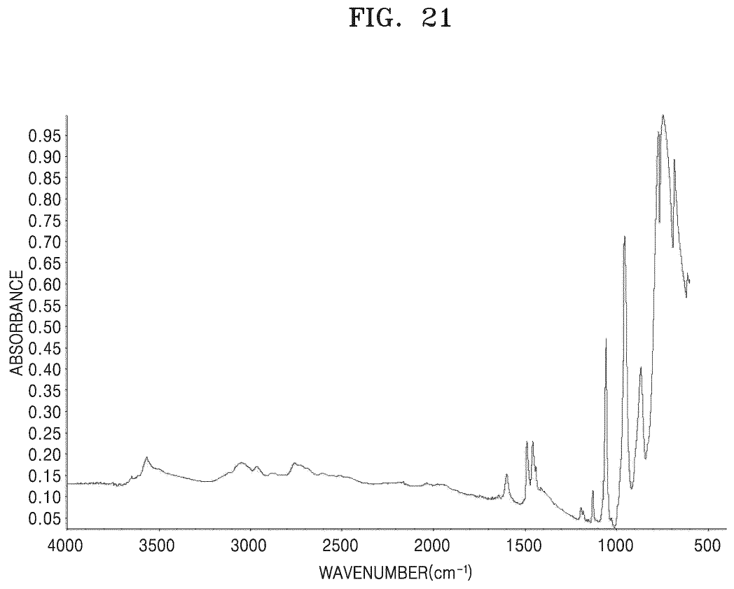

The FT-IR spectrum of obtained compound 21 is shown in FIG. 21.

### Synthesis Example 22

### Compound 22: Synthesis of [PW₁₂O₄₀]³⁻·3(1,1-diphenylhydrazinium)

After 0.115 g (0.521 mmol) of 1,1-diphenylhydrazine hydrochloride (manufactured by Tokyo Chemical Industry Co., Ltd.) and 34.2 g of pure water were put into a 100 ml Nasu flask, a 6 N hydrochloric acid aqueous solution was added, and the pH was adjusted to 1.5 to obtain a 1,1-diphenylhydrazine hydrochloride aqueous solution. 1.50 g (0.521 mmol) of dodecatungsto(VI) phosphate n-hydrate (manufactured by FUJIFILM Wako Pure Chemical Corporation) and 34.7 g of pure water were put into another 200 mL Nasu flask, and then the 1,1-diphenylhydrazine hydrochloride aqueous solution obtained above was added dropwise thereto. Stirring was performed at room temperature, and a supernatant was removed through centrifugation. Here, an operation of adding 8.68 g of pure water and removing a supernatant through centrifugation was repeated twice to obtain a solid, and the obtained solid was vacuum-dried to obtain 0.405 g of compound 22 as a white solid.

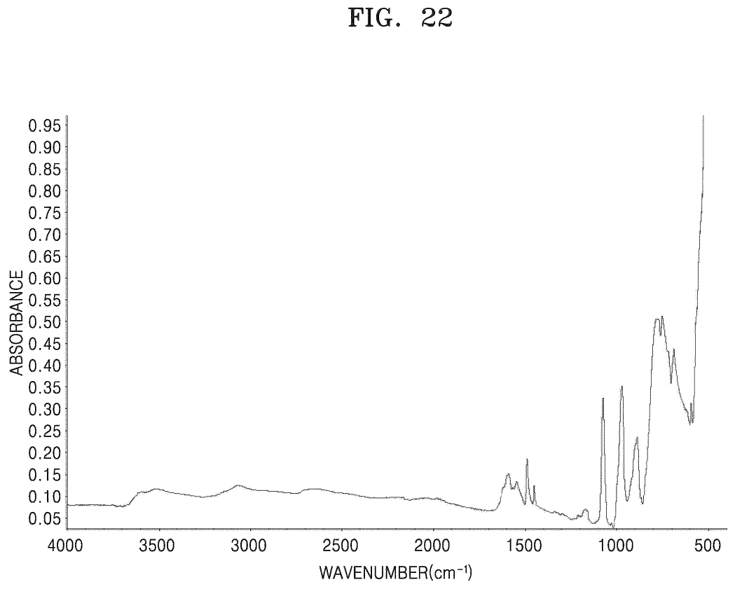

The FT-IR spectrum of obtained compound 22 is shown in FIG. 22.

### Synthesis Example 23

### Compound 23: Synthesis of [PW₁₂O₄₀]³⁻·3(N,N-dimethylanilinium)

After 0.631 g (0.521 mmol) of N,N-dimethylaniline (manufactured by Tokyo Chemical Industry Co., Ltd.) and 34.2 g of pure water were put into a 100 ml Nasu flask, a 6 N aqueous hydrochloric acid solution was added, and the pH was adjusted to 1.5 to obtain an N,N-dimethylaniline hydrochloride aqueous solution. 1.50 g (0.521 mmol) of dodecatungsto(VI) phosphate n-hydrate (manufactured by FUJIFILM Wako Pure Chemical Corporation) and 34.7 g of pure water were put into another 200 mL Nasu flask, and then the N,N-dimethylaniline hydrochloride aqueous solution obtained above was added dropwise thereto. Stirring was performed at room temperature, and a supernatant was removed through centrifugation. Here, an operation of adding 17.4 g of pure water and removing a supernatant through centrifugation was repeated twice to obtain a solid, and the obtained solid was vacuum-dried to obtain 0.536 g of compound 23 as a white solid.

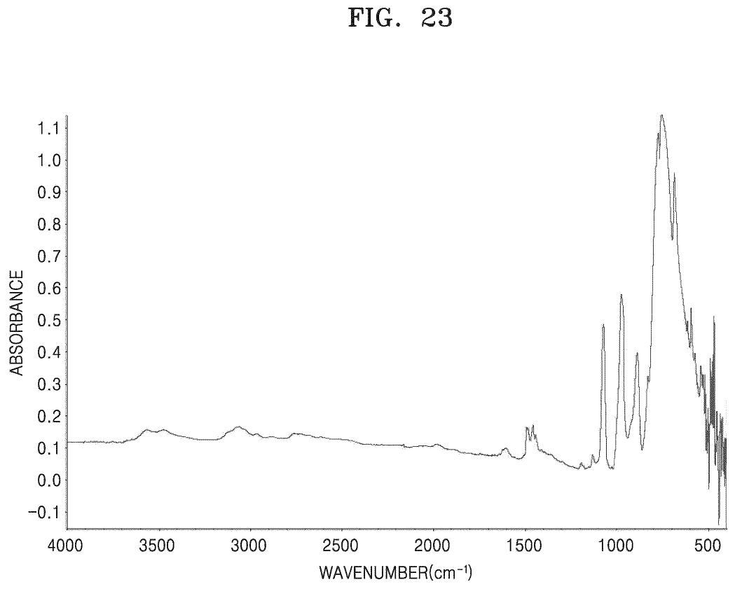

The FT-IR spectrum of obtained compound 23 is shown in FIG. 23.

### Synthesis Example 24

### Compound 24: Synthesis of [SiW₁₂O₄₀]⁴⁻·4(N,N-dimethylanilinium)

After 0.110 g (0.906 mmol) of N,N-dimethylaniline (manufactured by Tokyo Chemical Industry Co., Ltd.) and 29.8 g of pure water were put into a 100 ml Nasu flask, a 6 N aqueous hydrochloric acid solution was added, and the pH was adjusted to 1.5 to obtain an N,N-dimethylaniline hydrochloride aqueous solution. 1.50 g (0.453 mmol) of dodecatungsto(VI) silica n-hydrate (manufactured by FUJIFILM Wako Pure Chemical Corporation) and 30.2 g of purified water were put into another 200 mL Nasu flask, and then the N,N-dimethylaniline hydrochloride aqueous solution obtained above was added dropwise thereto. Stirring was performed at room temperature, and a supernatant was removed through centrifugation. Here, an operation of adding 15.1 g of pure water and removing a supernatant through centrifugation was repeated twice to obtain a solid, and the obtained solid was vacuum-dried to obtain 0.709 g of compound 24 as a white solid.

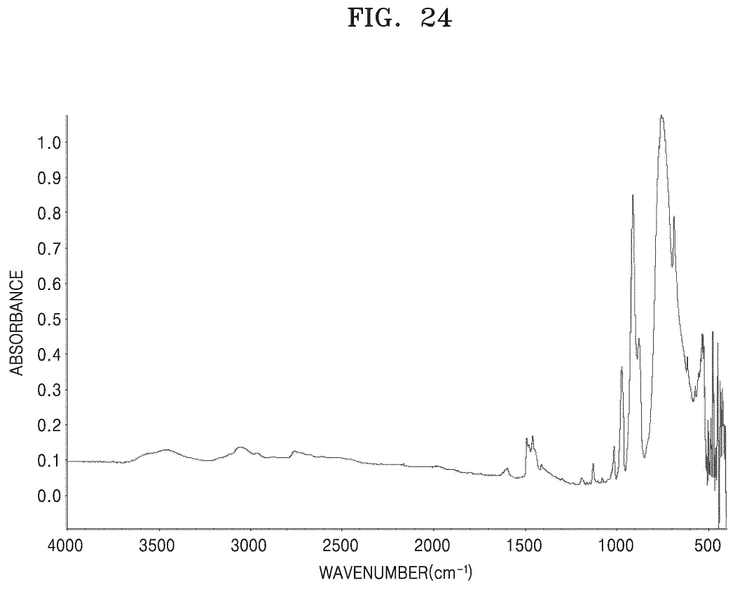

The FT-IR spectrum of obtained compound 24 is shown in FIG. 24.

### Synthesis Example 25

### Compound 25: Synthesis of [PMo₁₂O₄₀]³⁻·3(1-methylpyridinium)

After 0.106 g (0.822 mmol) of 1-methylpyridine hydrochloride (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a 1-methylpyridine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 1-methylpyridine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.510 g of compound 25 as a yellow solid.

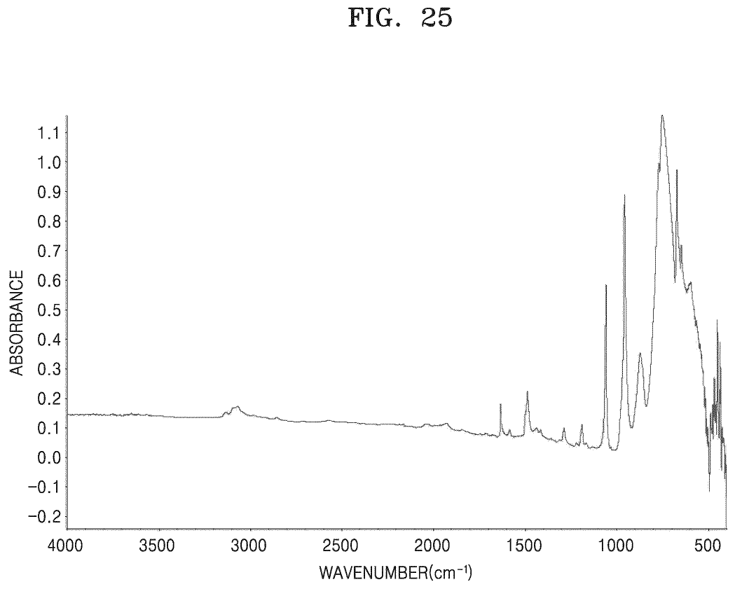

The FT-IR spectrum of obtained compound 25 is shown in FIG. 25.

### Synthesis Example 26

### Compound 26: Synthesis of [PMo₁₂O₄₀]³⁻·3(imidazolium)

After 0.0859 g (0.822 mmol) of imidazole (manufactured by Tokyo Chemical Industry Co., Ltd.) and 54.0 g of pure water were put into a 100 ml Nasu flask, a 6 N aqueous hydrochloric acid solution was added, and the pH was adjusted to 1.5 to obtain an imidazole hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the imidazole hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.325 g of compound 26 as a yellow solid.

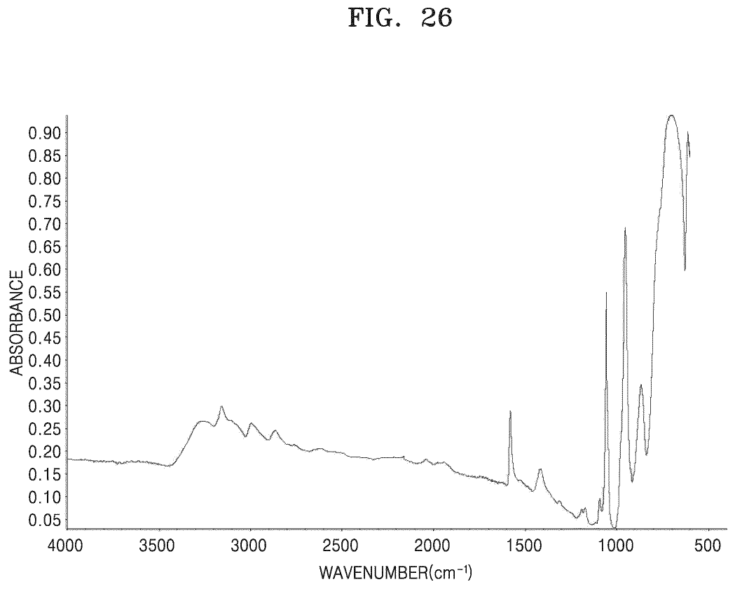

The FT-IR spectrum of obtained compound 26 is shown in FIG. 26.

### Synthesis Example 27

### Compound 27: Synthesis of [PMo₁₂O₄₀]³⁻·3(1,3-dimethylimidazolium)

After 0.109 g (0.822 mmol) of 1,3-dimethylimidazole hydrochloride (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a 1,3-dimethylimidazole hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 1,3-dimethylimidazole hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.423 g of compound 27 as a yellow solid.

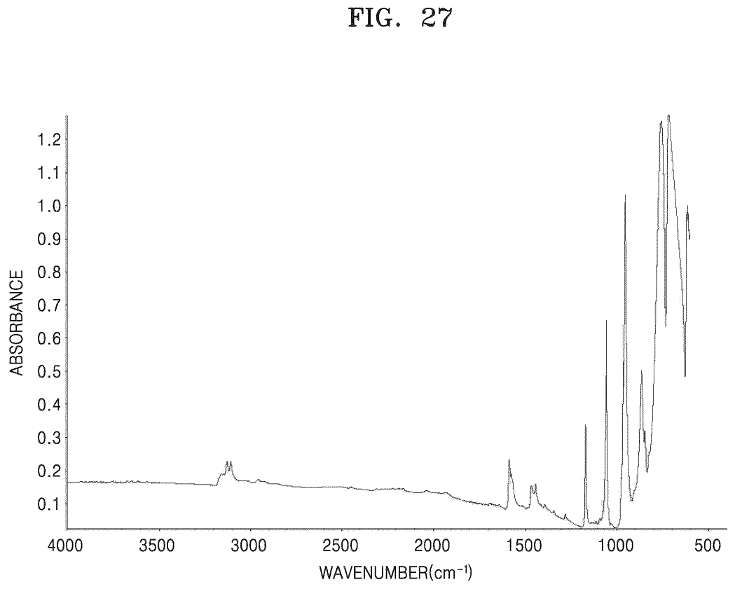

The FT-IR spectrum of obtained compound 27 is shown in FIG. 27.

### Synthesis Example 28

### Compound 28: Synthesis of [PMo₁₂O₄₀]³⁻·3(N,N,2,4,6-pentamethylanilinium)

After 0.134 g (0.822 mmol) of N,N,2,4,6-pentamethylaniline (manufactured by Tokyo Chemical Industry Co., Ltd.) and 54.0 g of pure water were put into a 100 ml Nasu flask, a 6 N aqueous hydrochloric acid solution was added, and the pH was adjusted to 1.5 to obtain an N,N,2,4,6-pentamethylaniline hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the N,N,2,4,6-pentamethylaniline hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.475 g of compound 28 as a yellow solid.

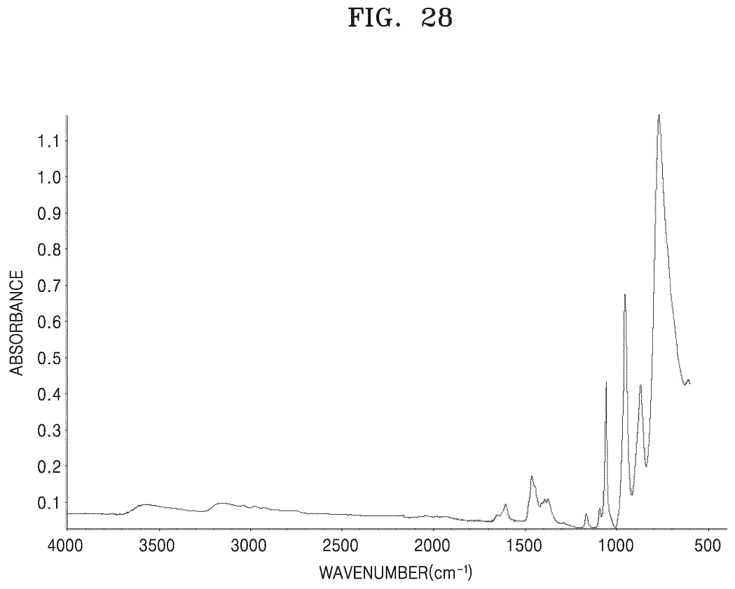

The FT-IR spectrum of obtained compound 28 is shown in FIG. 28.

### Synthesis Example 29

### Compound 29: Synthesis of [PMo₁₂O₄₀]³⁻·3(1,3-di-o-tolylguanidinium)

After 0.197 g (0.822 mmol) of 1,3-di-o-tolylguanidine (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a 1,3-di-o-tolylguanidine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 1,3-di-o-tolylguanidine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.451 g of compound 29 as a yellow solid.

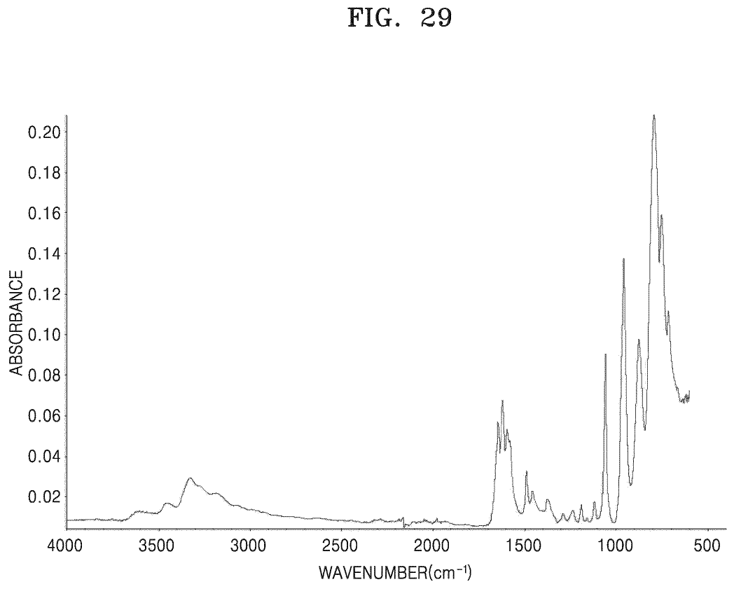

The FT-IR spectrum of obtained compound 29 is shown in FIG. 29.

### Synthesis Example 30

### Compound 30: Synthesis of [PMo₁₂O₄₀]³⁻·3(1-phenylpiperidinium)

After 0.132 g (0.822 mmol) of 1-phenylpiperidine (manufactured by Tokyo Chemical Industry Co., Ltd.), 54.0 g of pure water, and 10.8 g of ethanol (manufactured by FUJIFILM Wako Pure Chemical Corporation) were put into a 100 ml Nasu flask, a 6 N hydrochloric acid aqueous solution was added, and the pH was adjusted to 1.5 to obtain a 1-phenylpiperidine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 1-phenylpiperidine hydrochloride aqueous solution obtained above was added dropwise thereto. Stirring was performed at room temperature, and a supernatant was removed through centrifugation. Here, an operation of adding 13.7 g of pure water and removing a supernatant through centrifugation was repeated twice to obtain a solid, and the obtained solid was vacuum-dried to obtain 1.19 g of compound 30 as a yellow solid.

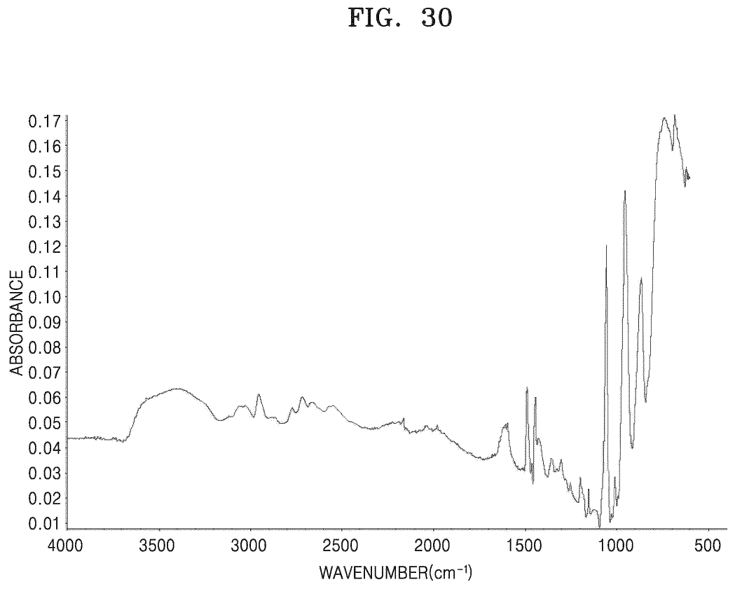

The FT-IR spectrum of obtained compound 30 is shown in FIG. 30.

### Synthesis Example 31

### Compound 31: Synthesis of [PMo₁₂O₄₀]³⁻·3(triethylenediammonium)

After 0.0992 g (0.822 mmol) of triethylenediamine (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a triethylenediamine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the triethylenediamine hydrochloride aqueous solution obtained above was added dropwise. Stirring was performed at room temperature, and a supernatant was removed through centrifugation. Here, an operation of adding 13.7 g of pure water and removing a supernatant through centrifugation was repeated twice to obtain a solid, and the obtained solid was vacuum-dried to obtain 1.07 g of compound 31 as a yellow solid.

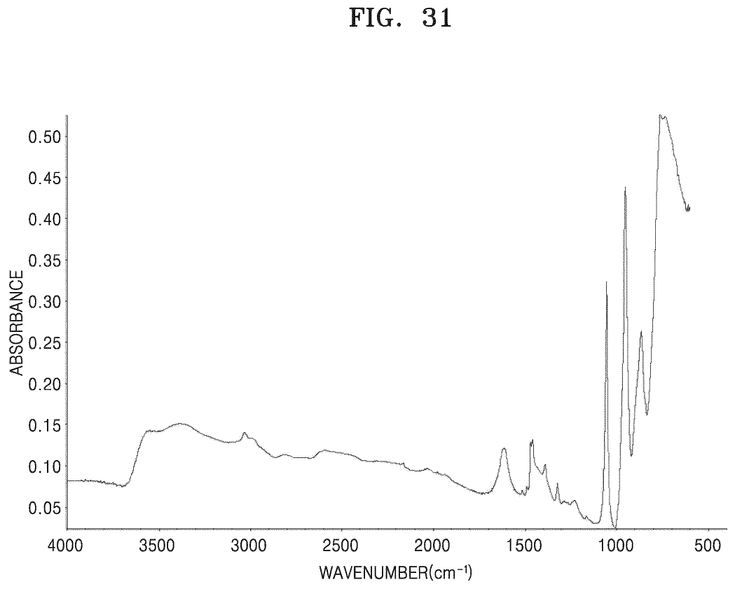

The FT-IR spectrum of obtained compound 31 is shown in FIG. 31.

### Synthesis Example 32

### Compound 32: Synthesis of [PMo₁₂O₄₀]³⁻·3(1,1,3,3-tetramethylguanidinium)

After 0.0946 g (0.822 mmol) of 1,1,3,3-tetramethylguanidine (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a 1,1,3,3-tetramethylguanidine hydrochloride aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 1,1,3,3-tetramethylguanidine hydrochloride aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.466 g of compound 32 as a yellow solid.

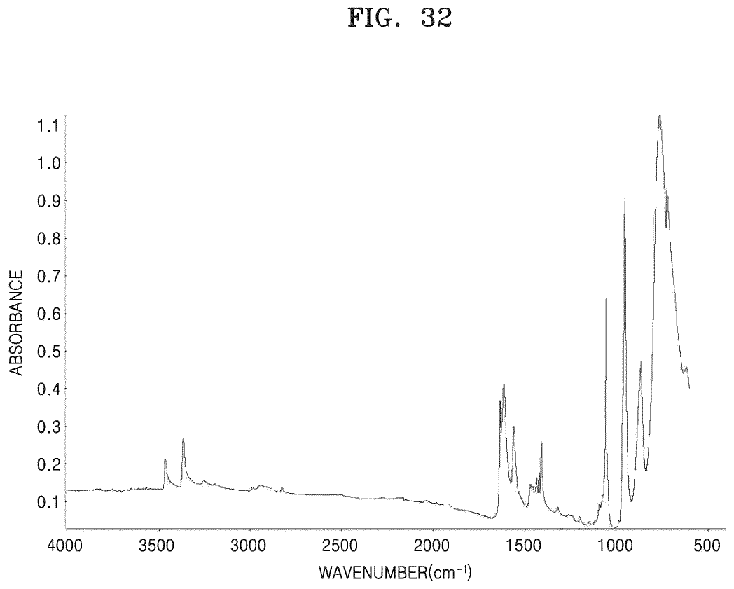

The FT-IR spectrum of obtained compound 32 is shown in FIG. 32.

### Synthesis Example 33

### Compound 33: Synthesis of [PMo₁₂O₄₀]³⁻·3(methyltriphenylphosphonium)

After 0.294 g (0.822 mmol) of methyltriphenylphosphonium bromide (manufactured by Tokyo Chemical Industry Co., Ltd.) and 54.0 g of pure water put into a 100 ml Nasu flask, a 6 N hydrochloric acid aqueous solution was added, and the pH was adjusted to 1.5 to obtain a methyltriphenylphosphonium bromide aqueous solution. 1.50 g (0.822 mmol) of 12-molybdo(VI) phosphate n-hydrate (manufactured by FUJIFILM Wako Pure Chemical Corporation) and 54.8 g of pure water put into another 200 mL Nasu flask, and then the methyltriphenylphosphonium bromide aqueous solution obtained above was added dropwise thereto. Stirring was performed at room temperature, and a supernatant was removed through centrifugation. Here, an operation of adding 13.7 g of pure water and removing a supernatant through centrifugation was repeated twice to obtain a solid, and the obtained solid was vacuum-dried to obtain 0.520 g of compound 33 as a yellow solid.

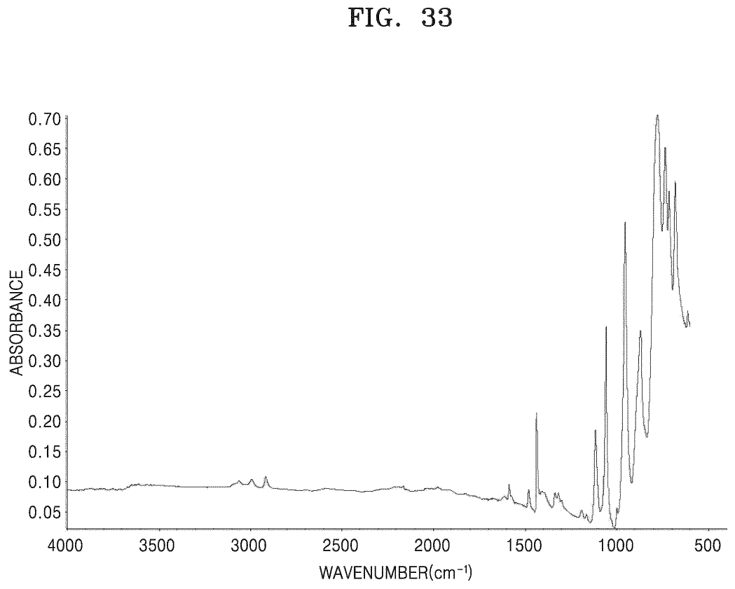

The FT-IR spectrum of obtained compound 33 is shown in FIG. 33.

### Synthesis Example 34

### Compound 34: Synthesis of [PMo₁₂O₄₀]³⁻·3(tetraphenylphosphonium)

After 0.345 g (0.822 mmol) of tetraphenylphosphonium bromide (manufactured by Tokyo Chemical Industry Co., Ltd.) and 54.0 g of pure water were put into a 100 ml Nasu flask, a 6 N hydrochloric acid aqueous solution was added, and the pH was adjusted to 1.5 to obtain a tetraphenylphosphonium bromide aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and the tetraphenylphosphonium bromide aqueous solution obtained above was added dropwise thereto. Stirring was performed at room temperature, and a supernatant was removed through centrifugation. Here, an operation of adding 13.7 g of pure water and removing a supernatant through centrifugation was repeated twice to obtain a solid, and the obtained solid was vacuum-dried to obtain 0.570 g of compound 34 as a yellow solid.

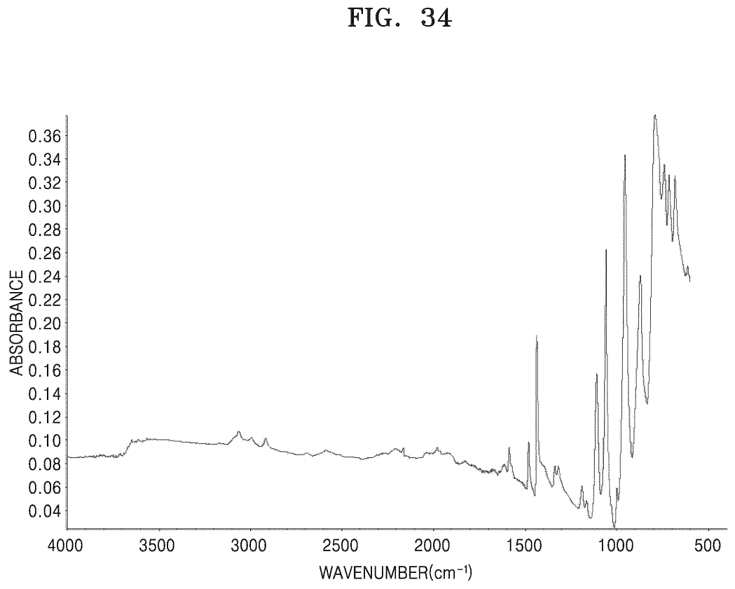

The FT-IR spectrum of obtained compound 34 is shown in FIG. 34.

### Synthesis Example 35

### Compound 35: Synthesis of [Mo₆O₁₉]²⁻·2(diphenyliodonium)

2.70 g (7.328 mmol) of diphenyliodonium tetrafluoroborate (manufactured by Tokyo Chemical Industry Co., Ltd.) and 24.4 g of acetonitrile (manufactured by FUJIFILM Wako Pure Chemical Corporation) were put into a 100 ml Nasu flask and stirred at room temperature to obtain a diphenyliodonium tetrafluoroborate solution. 0.500 g (0.366 mmol) of [Mo₆O₁₉][(C₁₆H₃₆N)₂] and 24.4 g of acetonitrile were put into another 200 mL Nasu flask, and then the diphenyliodonium tetrafluoroborate solution obtained above was added dropwise thereto. After stirring was performed at room temperature, 48.1 g of pure water was added, stirring was further performed at room temperature, and a supernatant was removed through centrifugation. Here, an operation of adding 12.2 g of pure water and removing a supernatant through centrifugation was repeated twice to obtain a solid, and the obtained solid was vacuum-dried to obtain 0.484 g of compound 35 as a yellow solid.

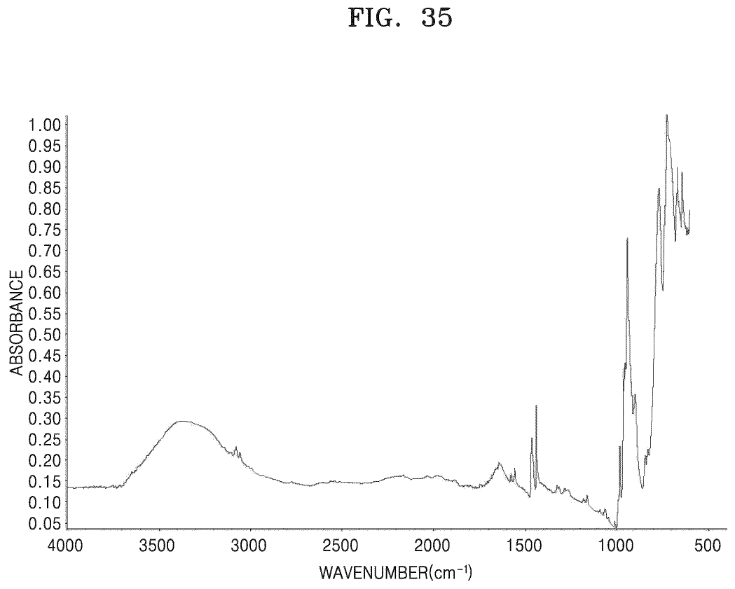

The FT-IR spectrum of obtained compound 35 is shown in FIG. 35.

### Synthesis Example 36

### Compound 36: Synthesis of [PMo₁₂O₄₀]³⁻·3(4-methoxybenzenediazonium)

After 0.182 g (0.822 mmol) of 4-methoxyazobenzenediazonium tetrafluoroborate (manufactured by Tokyo Chemical Industry Co., Ltd.) and 54.0 g of pure water were put into a 100 ml Nasu flask, a 6 N aqueous hydrochloric acid solution was added, and the pH was adjusted to 1.5 to obtain a 4-methoxyazobenzenediazonium tetrafluoroborate aqueous solution. 1.50 g (0.822 mmol) of 12-molybdo(VI) phosphate n-hydrate (manufactured by FUJIFILM Wako Pure Chemical Corporation) and 54.8 g of pure water were put into another 200 mL Nasu flask, and then the 4-methoxyazobenzenediazonium tetrafluoroborate aqueous solution obtained above was added dropwise thereto. Stirring was performed at room temperature, and a supernatant was removed through centrifugation. Here, an operation of adding 27.4 g of pure water and removing a supernatant through centrifugation was repeated twice to obtain a solid, and the obtained solid was vacuum-dried to obtain 0.558 g of compound 36 as a yellow solid.

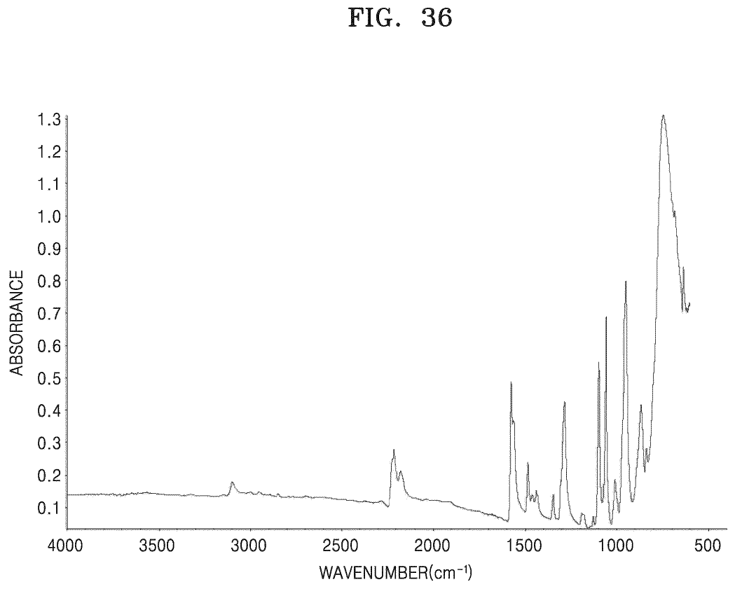

The FT-IR spectrum of obtained compound 36 is shown in FIG. 36.

### Synthesis Example 37

### Compound 37: Synthesis of W₁₀O₃₂]⁴⁻·4{tris[2-(2-methoxyethoxy)ethyl]ammonium}

After 0.132 g (0.409 mmol) of tris[2-(2-methoxyethoxy)ethyl]amine (manufactured by Tokyo Chemical Industry Co., Ltd.) and 3.41 g of pure water were put into a 10 ml Nasu flask, 6 N aqueous hydrochloric acid solution was added, and the pH was adjusted to 1.0 to obtain a tris[2-(2-methoxyethoxy)ethyl]amine hydrochloride aqueous solution. 0.250 g (0.102 mmol) of sodium decatungstate (manufactured by Aldrich Chemical Company) and 3.41 g of pure water were put into another 50 mL Nasu flask, and then the tris[2-(2-methoxyethoxy)ethyl]amine hydrochloride aqueous solution obtained above was added dropwise thereto. Stirring was performed at room temperature, 13.4 g of ethanol (manufactured by FUJIFILM Wako Pure Chemical Corporation) was added, stirring was further performed at room temperature, and a supernatant was removed through centrifugation. Here, an operation of adding 3.41 g of ethanol and removing a supernatant through centrifugation was repeated twice to obtain a solid, and the obtained solid was vacuum-dried to obtain 0.101 g of compound 37 as a white solid.

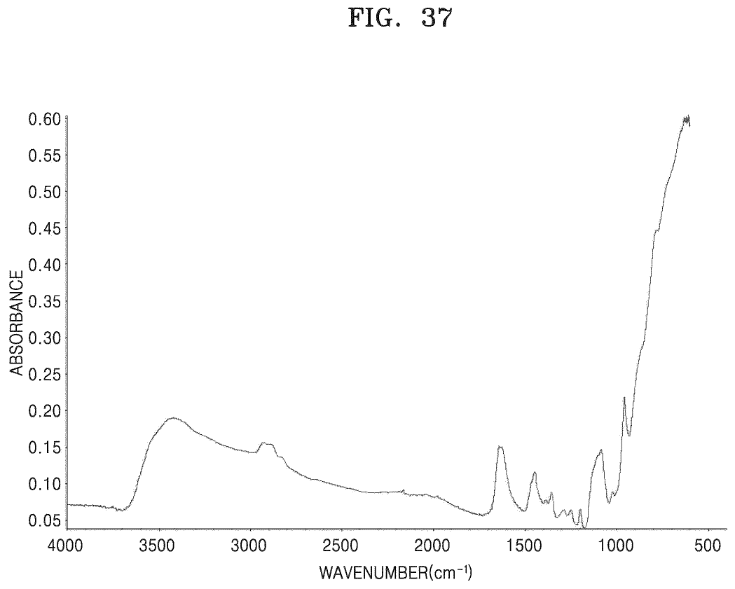

The FT-IR spectrum of obtained compound 37 is shown in FIG. 37.

### Synthesis Example 38

### Compound 38: Synthesis of W₁₀O₃₂]⁴⁻·4(diphenyliodonium)

After 0.151 g (0.409 mmol) of diphenyliodonium tetrafluoroborate (manufactured by Tokyo Chemical Industry Co., Ltd.) and 6.82 g of acetonitrile (manufactured by FUJIFILM Wako Pure Chemical Corporation) were put into a 10 ml Nasu flask, a 6 N hydrochloric acid solution was added, and the pH was adjusted to 1.0 to obtain a diphenyliodonium tetrafluoroborate solution. 0.250 g (0.102 mmol) of sodium decatungstate (Aldrich Chemical Company), 36.9 g of acetonitrile, and 120 g of pure water were put into another 200 mL Nasu flask, and then the diphenyliodonium tetrafluoroborate solution obtained above was added dropwise thereto. Stirring was performed at room temperature, 13.4 g of pure water was added, stirring was further performed at room temperature, and a supernatant was removed through centrifugation. Here, an operation of adding 3.41 g of pure water and removing a supernatant through centrifugation was repeated twice to obtain a solid, and the obtained solid was vacuum-dried to obtain 0.178 g of compound 38 as a white solid.

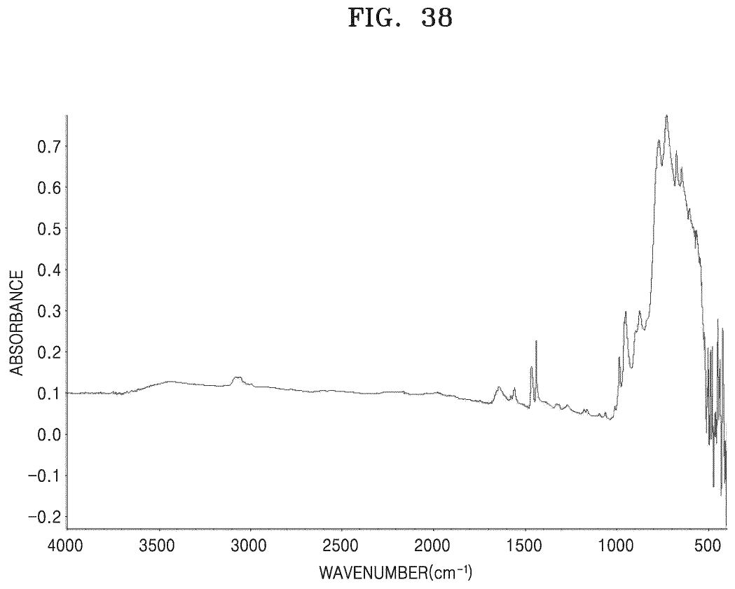

The FT-IR spectrum of obtained compound 38 is shown in FIG. 38.

### Synthesis Example 39

### Compound 39: Synthesis of [Mo₇O₂₄]⁶⁻·6{tris[2-(2-methoxyethoxy)ethyl]ammonium}

After 1.67 g (5.12 mmol) of tris[2-(2-methoxyethoxy)ethyl]amine (manufactured by Tokyo Chemical Industry Co., Ltd.) and 23.5 g of ethanol (manufactured by FUJIFILM Wako Pure Chemical Corporation) were put into a 100 ml Nasu flask, a 1 N hydrochloric acid aqueous solution was added, and the pH was adjusted to 6.0 to obtain a tris[2-(2-methoxyethoxy)ethyl]amine hydrochloride aqueous solution. 0.500 g (0.430 mmol) of ammonium molybdate(VI) tetrahydrate (manufactured by FUJIFILM Wako Pure Chemical Corporation) and 28.6 g of pure water were put into another 200 mL Nasu flask, and then the tris[2-(2-methoxyethoxy)ethyl]amine hydrochloride aqueous solution obtained above was added dropwise thereto. Stirring was performed at room temperature, 23.5 g of ethanol (manufactured by FUJIFILM Wako Pure Chemical Corporation) was added, stirring was further performed at room temperature, and a supernatant was removed through centrifugation. Here, an operation of adding 23.5 g of ethanol and removing a supernatant through centrifugation was repeated twice to obtain a solid, and the obtained solid was vacuum-dried to obtain 0.534 g of compound 39 as a yellow solid.

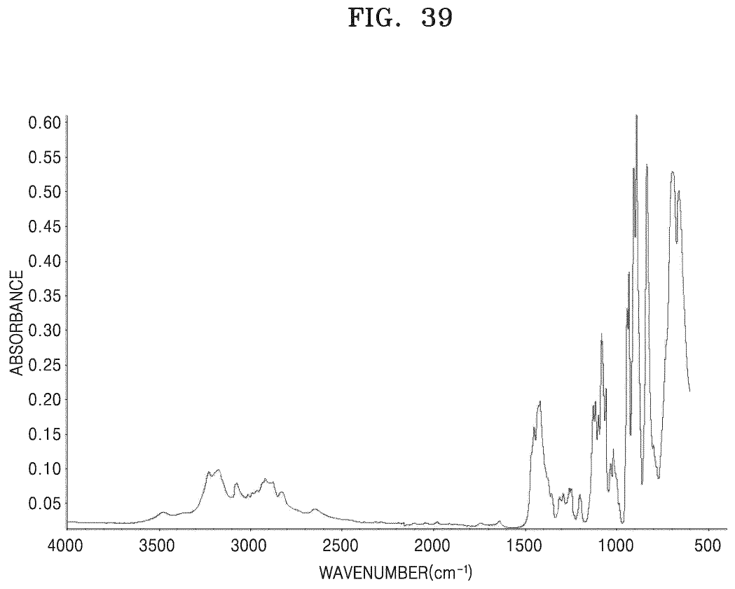

The FT-IR spectrum of obtained compound 39 is shown in FIG. 39.

### Synthesis Example 40

### Compound 40: Synthesis of [Mo₇O₂₄]⁶⁻·6(diphenyliodonium)

0.948 g (2.58 mmol) of diphenyliodonium tetrafluoroborate (manufactured by Tokyo Chemical Industry Co., Ltd.) and 14.3 g of acetonitrile (manufactured by FUJIFILM Wako Pure Chemical Corporation) were put into a 50 ml Nasu flask to obtain a diphenyliodonium tetrafluoroborate solution. 0.250 g (0.215 mmol) of ammonium molybdate(VI) tetrahydrate (manufactured by FUJIFILM Wako Pure Chemical Corporation), 44.3 g of acetonitrile, and 40.0 g of pure water were put into another 200 mL Nasu flask, and then the diphenyliodonium tetrafluoroborate solution obtained above was added dropwise thereto. Stirring was performed at room temperature, 28.2 g of pure water was added, stirring was further performed at room temperature, and a supernatant was removed through centrifugation. Here, an operation of adding 7.16 g of pure water and removing a supernatant through centrifugation was repeated twice to obtain a solid, and the obtained solid was vacuum-dried to obtain 0.258 g of compound 40 as a yellow solid.

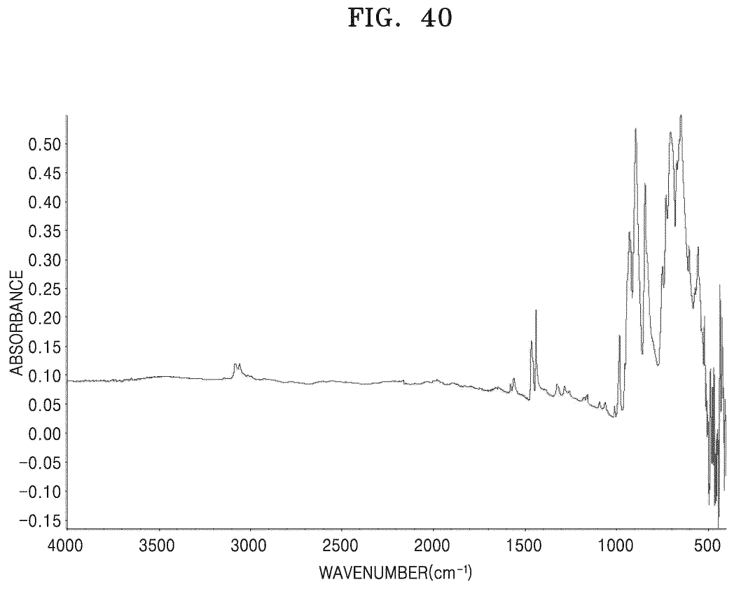

The FT-IR spectrum of obtained compound 40 is shown in FIG. 40.

### Synthesis Example A

### (Synthesis of N-benzyl-2-[(4-iodobenzoyl)oxy]-N,N-dimethylethane-1-aminum bromide)

1.34 g (15.0 mmol) of 2-(dimethylamino)ethanol (Tokyo Chemical Industry Co., Ltd.) and dichloromethane (FUJIFILM Wako Pure Chemical Corporation product) were put into a 100 ml Nasu flask and stirred under ice-cooling. Next, 1.52 g (15.0 mmol) of triethylamine (Tokyo Chemical Industry Co., Ltd.) and 4.00 g (15.0 mmol) of 4-iodobenzoyl chloride (Tokyo Chemical Industry Co., Ltd.) were added and stirred at room temperature. 17.7 g of a saturated sodium bicarbonate aqueous solution was added dropwise, and liquid-liquid separation was performed to obtain an organic layer. After sodium sulfate was added to perform dehydration, filtration was performed to obtain an organic layer. After dichloromethane was removed by using an evaporator, purification was performed through silica gel column chromatography to obtain 3.49 g of 2-(dimethylamino)ethyl-4-iodobenzoate as an orange solid.

2.39 g (7.50 mmol) of the 2-(dimethylamino)ethyl-4-iodobenzoate obtained above and 25.7 g of acetonitrile (manufactured by FUJIFILM Wako Pure Chemical Corporation) were put into a 50 ml Nasu flask and stirred at room temperature. Next, 1.28 g (7.50 mmol) of benzyl bromide (manufactured by Tokyo Chemical Industry Co., Ltd.) was added and stirred at room temperature. A precipitated solid was filtered, washed with acetonitrile, and vacuum-dried to obtain 3.20 g of N-benzyl-2-[(4-iodobenzoyl)oxy]-N,N-dimethylethane-1-aminum bromide as a white solid.

### Synthesis Example 41

### Compound 41: Synthesis of [SiW₁₂O₄₀]⁴⁻·4[2-(acryloyloxy)-N-benzyl-N,N-dimethylethane-1-aminium]

0.523 g (0.150 mmol) of sodium dodecatungsto(VI) silicate n-hydrate (manufactured by FUJIFILM Wako Pure Chemical Corporation) and 13.1 g of dimethyl sulfoxide (manufactured by FUJIFILM Wako Pure Chemical Corporation) were put into a 100 ml Nasu flask and stirred at room temperature. Here, a solution in which 0.432 g (1.20 mmol) of 2-(acryloyloxy)-N-benzyl-N,N-dimethylethane-1-aminium chloride (manufactured by Tokyo Chemical Industry Co., Ltd.) was dissolved in 13.1 g of dimethyl sulfoxide was added dropwise. Stirring was performed at room temperature, 26.2 g of pure water was added, stirring was further performed at room temperature, and a supernatant was removed through centrifugation. Here, an operation of adding 13.1 g of pure water and removing a supernatant through centrifugation was repeated twice. Here, 13.1 g of methanol was added, a supernatant was removed through centrifugation to obtain a solid, and the obtained solid was vacuum-dried to obtain 0.449 g of compound 41 as a white solid.

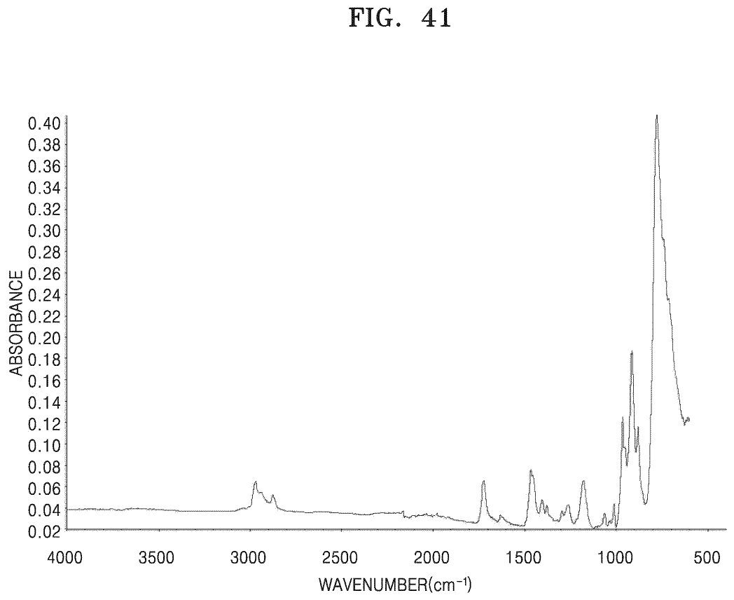

The FT-IR spectrum of obtained compound 41 is shown in FIG. 41.

### Synthesis Example 42

### Compound 42: Synthesis of [W₆O₁₉]²⁻·1.4(tetrabutylammonium)0.6[2-(acryloyloxy)-N-benzyl-N,N-dimethylethane-1-aminium]

0.473 g (0.250 mmol) of [W₆O₁₉][(tetrabutylammonium)₂] and 11.8 g of dimethyl sulfoxide (manufactured by FUJIFILM Wako Pure Chemical Corporation) were put into a 100 ml Nasu flask and stirred at room temperature. Here, a solution in which 0.360 g (1.00 mmol) of 2-(acryloyloxy)-N-benzyl-N,N-dimethylethane-1-aminum chloride (manufactured by Tokyo Chemical Industry Co., Ltd.) was dissolved in 11.8 g of dimethyl sulfoxide was added dropwise. Stirring was performed at room temperature, 23.7 g of pure water was added, stirring was further performed at room temperature, and a supernatant was removed through centrifugation. Here, an operation of adding 11.8 g of pure water and removing a supernatant through centrifugation was repeated twice. Here, 11.8 g of methanol was added, a supernatant was removed through centrifugation to obtain a solid, and the obtained solid was vacuum-dried to obtain 0.387 g of compound 42 as a white solid.

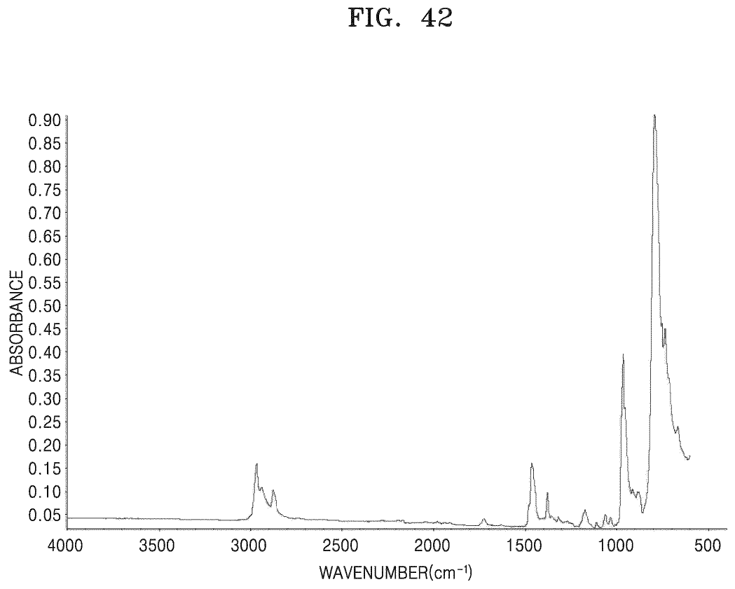

The FT-IR spectrum of obtained compound 42 is shown in FIG. 42.

### Synthesis Example 43

### Compound 43: Synthesis of [Mo₆O₁₉]²⁻·1.2(tetrabutylammonium)0.8[2-(acryloyloxy)-N-benzyl-N,N-dimethylethane-1-aminium]

0.409 g (0.300 mmol) of [Mo₆O₁₉][(tetrabutylammonium)₂] and 10.2 g of dimethyl sulfoxide (manufactured by FUJIFILM Wako Pure Chemical Corporation) were put into a 100 ml Nasu flask and stirred at room temperature. Here, a solution in which 0.432 g (1.20 mmol) of 2-(acryloyloxy)-N-benzyl-N,N-dimethylethane-1-aminum chloride (manufactured by Tokyo Chemical Industry Co., Ltd.) was dissolved in 10.2 g of dimethyl sulfoxide was added dropwise. Stirring was performed at room temperature, 20.4 g of pure water was added, stirring was further performed at room temperature, and a supernatant was removed through centrifugation. Here, an operation of adding 10.2 g of pure water and removing a supernatant through centrifugation was repeated twice. Here, 10.2 g of methanol was added, a supernatant was removed through centrifugation to obtain a solid, and the obtained solid was vacuum-dried to obtain 0.347 g of compound 43 as a yellow solid.

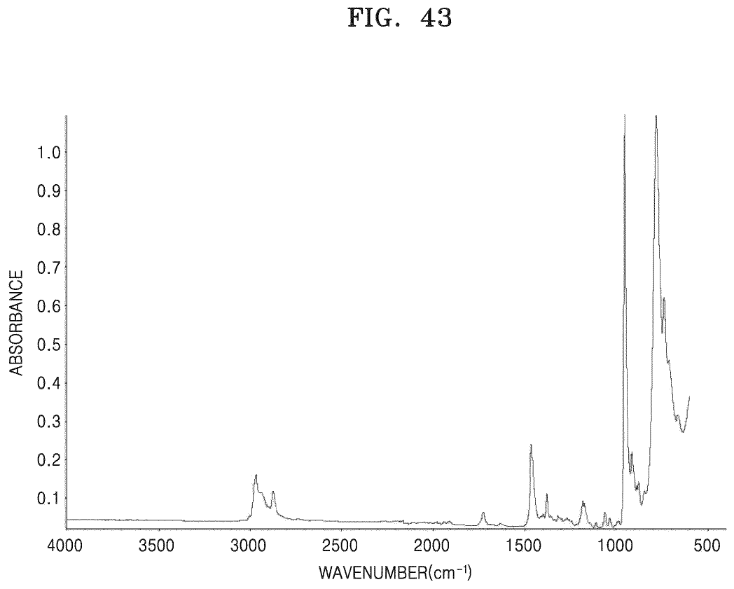

The FT-IR spectrum of obtained compound 43 is shown in FIG. 43.

### Synthesis Example B

### Synthesis of 2-((4-azidebenzoyl)oxy)-N-benzyl-N,N-dimethylethane-1-aminum bromide

5.00 g (30.7 mmol) of a 4-azidecarboxylic acid (manufactured by Tokyo Chemical Industry Co., Ltd.) and 17.9 g of dichloromethane (manufactured by FUJIFILM Wako Pure Chemical Corporation) were put into a 100 ml Nasu flask and stirred at room temperature. Next, 2.73 g (30.7 mmol) of 2-(dimethylamino)ethanol (Tokyo Chemical Industry Co., Ltd.), 0.374 g (3.07 mmol) of dimethylaminopyridine (Tokyo Chemical Industry Co., Ltd.), and 7.05 g (36.8 mmol) of 1-(3-dimethylaminopropyl)-3-ethylcarbodiimide hydrochloride (Tokyo Chemical Industry Co., Ltd.) were added and stirred at room temperature. Here, 17.9 g of dichloromethane and 17.9 g of pure water were added, and liquid-liquid separation was performed to obtain an organic layer. After the organic layer was washed with saturated brine, sodium sulfate was added to perform dehydration, and filtering was performed to obtain an organic layer. Dichloromethane was removed by using an evaporator, and purification was performed through silica gel column chromatography to obtain 4.05 g of 2-(dimethylamino)ethyl-4-azidebenzoate as a colorless oil.

1.17 g (5.00 mmol) of the 2-(dimethylamino)ethyl-4-azidebenzoate obtained above and 17.1 g of acetonitrile (manufactured by FUJIFILM Wako Pure Chemical Corporation) were put into a 50 ml Nasu flask and stirred at room temperature. Next, 0.860 g (5.00 mmol) of benzyl bromide (manufactured by Tokyo Chemical Industry Co., Ltd.) was added and stirred at room temperature. A precipitated solid was filtered, washed with acetonitrile, and vacuum-dried to obtain 1.40 g of 2-((4-azidebenzoyl)oxy)-N-benzyl-N,N-dimethylethane-1-aminum bromide as a white solid.

### Synthesis Example 44

### Compound 44: Synthesis of [SiW₁₂O₄₀]⁴⁻·4[2-((4-azidebenzoyl)oxy)-N-benzyl-N,N-dimethylethane-1-aminum]

0.523 g (0.150 mmol) of sodium dodecatungsto(VI) silicate n-hydrate (manufactured by FUJIFILM Wako Pure Chemical Corporation) and 13.1 g of dimethyl sulfoxide (manufactured by FUJIFILM Wako Pure Chemical Corporation) were put into a 100 ml Nasu flask and stirred at room temperature. Here, a solution in which 0.486 g (1.20 mmol) of the 2-((4-azidebenzoyl)oxy)-N-benzyl-N,N-dimethylethane-1-aminum bromide obtained in Synthesis Example B was dissolved in 13.1 g of dimethyl sulfoxide was added dropwise. Stirring was performed at room temperature, 26.2 g of pure water was added, stirring was further performed at room temperature, and a supernatant was removed through centrifugation. Here, an operation of adding 13.1 g of pure water and removing a supernatant through centrifugation was repeated twice. Here, 13.1 g of methanol was added, and a supernatant was removed through centrifugation. Through vacuum drying, 0.456 g of compound 44 as a white solid was obtained.

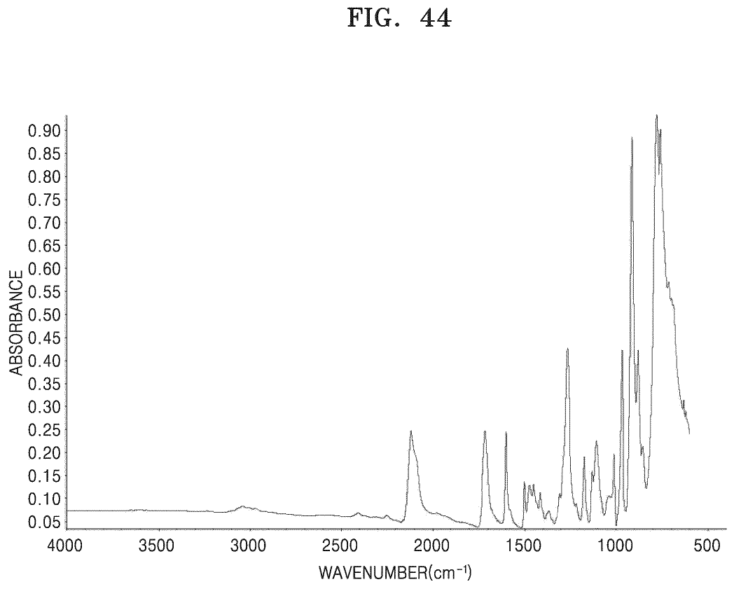

The FT-IR spectrum of obtained compound 44 is shown in FIG. 44.

### Synthesis Example 45

### Compound 45: Synthesis of [W₆O₁₉]²⁻·1.4(tetrabutylammonium)0.6[2-((4-azidebenzoyl)oxy)-N-benzyl-N,N-dimethylethane-1-aminium]

0.473 g (0.250 mmol) of [W₆O₁₉][(tetrabutylammonium)₂] and 11.8 g of dimethyl sulfoxide (manufactured by FUJIFILM Wako Pure Chemical Corporation) were put into a 100 ml Nasu flask and stirred at room temperature. Here, a solution in which 0.405 g (1.00 mmol) of the 2-((4-azidebenzoyl)oxy)-N-benzyl-N,N-dimethylethane-1-aminum bromide obtained in Synthesis Example B was dissolved in 11.8 g of dimethyl sulfoxide was added dropwise. Stirring was performed at room temperature, 23.7 g of pure water was added, stirring was further performed at room temperature, and a supernatant was removed through centrifugation. Here, an operation of adding 11.8 g of pure water and removing a supernatant through centrifugation was repeated twice. Here, 11.8 g of methanol was added, a supernatant was removed through centrifugation to obtain a solid, and the obtained solid was vacuum-dried to obtain 0.390 g of compound 45 as a white solid.

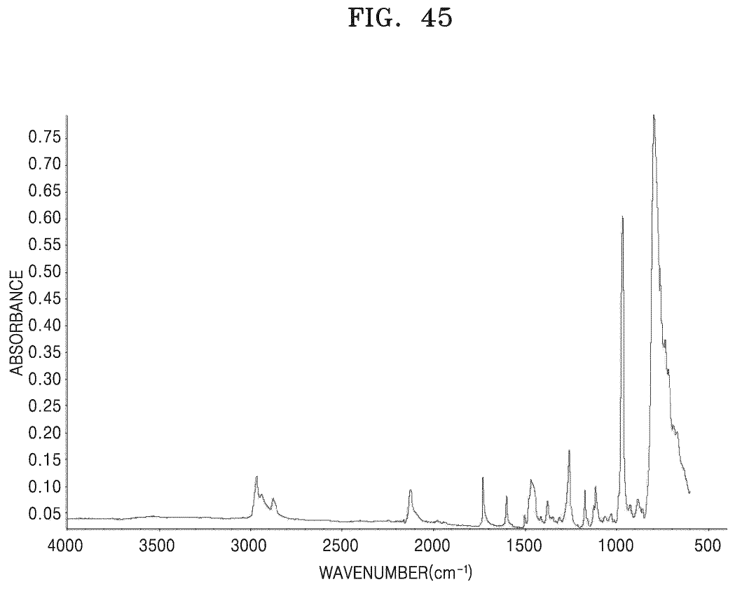

The FT-IR spectrum of obtained compound 45 is shown in FIG. 45.

### Synthesis Example 46

### Compound 46: Synthesis of [Mo₆O₁₉]²⁻·1.2(tetrabutylammonium)0.8[2-((4-azidebenzoyl)oxy)-N-benzyl-N,N-dimethylethane-1-aminium]

0.409 g (0.300 mmol) of [Mo₆O₁₉][(tetrabutylammonium)₂] and 10.2 g of dimethyl sulfoxide (manufactured by FUJIFILM Wako Pure Chemical Corporation) were put into a 100 ml Nasu flask and stirred at room temperature. Here, a solution in which 0.486 g (1.20 mmol) of the 2-((4-azidebenzoyl)oxy)-N-benzyl-N,N-dimethylethane-1-aminum bromide obtained in Synthesis Example B was dissolved in 10.2 g of dimethyl sulfoxide was added dropwise. Stirring was performed at room temperature, 20.4 g of pure water was added, stirring was further performed at room temperature, and a supernatant was removed through centrifugation. Here, an operation of adding 10.2 g of pure water and removing a supernatant through centrifugation was repeated twice. Here, 10.2 g of methanol was added, a supernatant was removed through centrifugation to obtain a solid, and the obtained solid was vacuum-dried to obtain 0.355 g of compound 46 as a yellow solid.

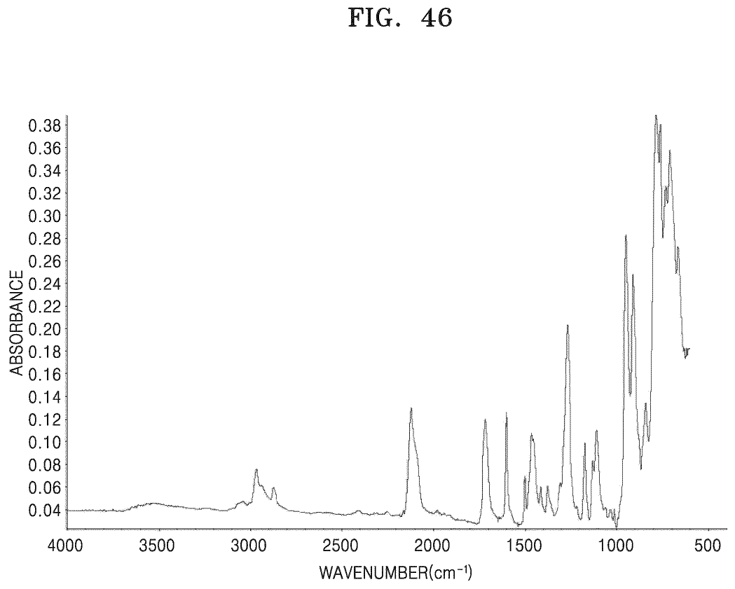

The FT-IR spectrum of obtained compound 46 is shown in FIG. 46.

### Synthesis Example 47

### Compound 47: Synthesis of [V₁₈O₄₂]¹²⁻·12[2-((4-azidebenzoyl)oxy)-N-benzyl-N,N-dimethylethane-1-aminum]

0.206 g (0.0100 mmol) of [V₁₈O₄₂]K₁₂ and 5.15 g of dimethyl sulfoxide (manufactured by FUJIFILM Wako Pure Chemical Corporation) were put into a 50 ml Nasu flask and stirred at room temperature. Here, a solution in which 0.973 g (2.40 mmol) of the 2-((4-azidebenzoyl)oxy)-N-benzyl-N,N-dimethylethane-1-aminum bromide obtained in Synthesis Example B was dissolved in 10.3 g of dimethyl sulfoxide was added dropwise. Stirring was performed at room temperature, 10.3 g of pure water was added, stirring was further performed at room temperature, and a supernatant was removed through centrifugation. Here, an operation of adding 5.15 g of pure water and removing a supernatant through centrifugation was repeated twice. Here, 5.15 g of methanol was added, a supernatant was removed through centrifugation to obtain a solid, and the obtained solid was vacuum-dried to obtain 0.339 g of compound 47 as a yellow solid.

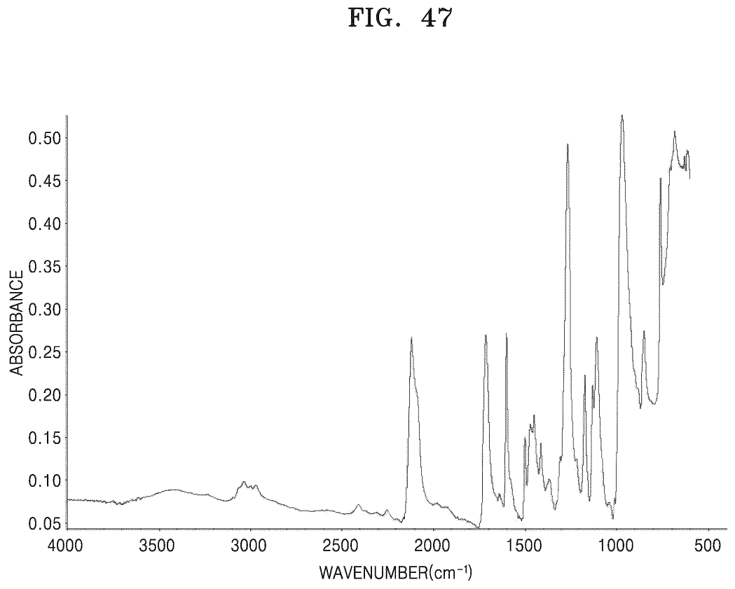

The FT-IR spectrum of obtained compound 47 is shown in FIG. 47.

### Synthesis Example 48

### Compound 48: Synthesis of bis-(triphenylsulfonium)-tungstate(IV)

Compound 48 was synthesized according to the synthetic method described in Japanese Patent Application Laid-Open No. 2017-207532. Specifically, 2.00 g (5.12 mmol) of triphenylsulfonium iodide and 0.68 g (2.93 mmol) of silver oxide (manufactured by FUJIFILM Wako Pure Chemical Corporation) were added to 20 g of pure water in a 50 ml Nasu flask and stirred at room temperature. After that, a solid was separated, and 0.57 g (2.28 mmol) of a tungstic acid (manufactured by FUJIFILM Wako Pure Chemical Corporation) was added to an obtained aqueous solution and stirred at room temperature. After the stirring, an aqueous solution obtained through filtration was concentrated, and then 5.00 g of PGME was added to distill off a solvent, thereby obtaining 1.25 g of compound 48 as a white solid.

Results of measured values of contents of V, Nb, Ta, Mo, and W elements of compounds 1 to 48 obtained above are shown in Table 1 below along with theoretical values. In addition, contents of five elements of dodecatungsto(VI) silica n-hydrate were measured. Results thereof are shown in Table 1 below as those of compound 49.

TABLE 1

| | | Theoretical | Measured |
|---|---|---|---|
| | | values of | values of |
| | | contents of V, | contents of V, |
| Compound | | Nb, Mo, and W | Nb, Mo, and W |
| No. | Molecular formula | (mass %) | (mass %) |
| Compound 1 | C₄₅H₁₀₂Mo₁₂N₃O₅₈P | 41.2 | 41.2 |
| Compound 2 | C₇₂H₆₀O₄₀S₄Si₃W₁₂ | 56.2 | 55.6 |
| Compound 3 | C₃₆H₃₀I₃Mo₁₂O₄₀P | 43.2 | 40.5 |
| Compound 4 | C₅₄H₄₅O₄₀PS₃W₁₂ | 60.2 | 58.1 |
| Compound 5 | C₅₄H₄₅Mo₁₂O₄₀PS₃ | 44.1 | 41.9 |
| Compound 6 | C₃₆H₃₀I₃O₄₀PW₁₂ | 59.3 | 56.8 |
| Compound 7 | C₄₈H₄₀I₄O₄₀SiW₁₂ | 55.2 | 52.1 |
| Compound 8 | C₃₀H₆₉N₂O₅₂PW₁₂ | 62.6 | 60.2 |
| Compound 9 | C₃₀H₆₉N₂Mo₁₂O₅₂P | 46.6 | 44.9 |
| Compound 10 | C₈₀H₁₀₄I₄O₄₀SiW₁₂ | 49.6 | 49.8 |
| Compound 11 | C₄₈H₃₆I₄N₄O₄₈SiW₁₂ | 52.8 | 51.0 |
| Compound 12 | C₆₄H₇₂I₄O₄₀SiW₁₂ | 52.2 | 53.0 |
| Compound 13 | C₅₂H₃₆F₁₂I₄O₄₀SiW₁₂ | 51.7 | 50.5 |
| Compound 14 | C₆₀H₆₄I₄O₅₂SiW₁₂ | 50.6 | 52.0 |
| Compound 15 | C₆₄H₆₀F₁₂I₄O₄₀SiW₁₂ | 49.7 | 49.8 |
| Compound 16 | C₆₃H₁₃₈Mo₁₂N₃O₄₀P | 41.7 | 40.9 |
| Compound 17 | C₁₈H₄₈Mo₁₂N₃O₄₀P | 54.1 | 54.7 |
| Compound 18 | C₁₅H₁₈Mo₁₂N₃O₄₀P | 55.8 | 54.0 |
| Compound 19 | C₁₈H₅₁Mo₁₂N₆O₄₀P | 53.0 | 52.0 |
| Compound 20 | C₁₈H₄₈Mo₁₂N₃O₄₉P | 50.7 | 51.1 |
| Compound 21 | C₂₄H₃₆Mo₁₂N₃O₄₀P | 52.6 | 52.7 |
| Compound 22 | C₃₆H₃₉N₆O₄₀PW₁₂ | 64.3 | 63.8 |
| Compound 23 | C₂₄H₃₆N₃O₄₀PW₁₂ | 68.0 | 68.1 |
| Compound 24 | C₃₂H₄₈N₄O₄₀SiW₁₂ | 65.6 | 64.9 |
| Compound 25 | C₁₈H₂₄Mo₁₂N₃O₄₀P | 54.7 | 52.6 |
| Compound 26 | C₉H₁₅Mo₁₂N₆O₄₀P | 56.7 | 55.0 |
| Compound 27 | C₁₅H₂₇Mo₁₂N₆O₄₀P | 54.5 | 54.5 |
| Compound 28 | C₃₃H₅₄Mo₁₂N₃O₄₀P | 49.7 | 50.3 |
| Compound 29 | C₄₅H₅₄Mo₁₂N₉O₄₀P | 45.3 | 44.9 |
| Compound 30 | C₃₃H₄₈Mo₁₂N₃O₄₀P | 49.9 | 49.8 |
| Compound 31 | C₁₅H₃₉Mo₁₂N₆O₄₀P | 53.3 | 51.0 |
| Compound 32 | C₁₅H₄₂Mo₁₂N₉O₄₀P | 53.0 | 52.2 |
| Compound 33 | C₅₇H₅₄Mo₁₂O₄₀P₄ | 43.4 | 43.0 |
| Compound 34 | C₇₂H₆₀Mo₁₂O₄₀P | 40.5 | 40.0 |
| Compound 35 | C₂₄H₂₀I₂Mo₁₂N₆O₁₉ | 39.9 | 38.9 |
| Compound 36 | C₂₁H₂₁Mo₁₂N₆O₄₃P | 51.7 | 50.5 |
| Compound 37 | C₆₀H₁₃₆N₄O₅₆W₁₀ | 50.4 | 50.2 |
| Compound 38 | C₄₈H₄₀I₄O₃₂W₁₀ | 52.9 | 51.9 |
| Compound 39 | C₉₀H₂O₄Mo₇N₆O₆₀ | 22.4 | 20.8 |
| Compound 40 | C₇₂H₆₀I₆Mo₇O₂₄ | 24.5 | 23.5 |
| Compound 41 | C₅₆H₈₀N₄O₄₈SiW₁₂ | 57.9 | 57.8 |
| Compound 42 | C_{30.8}H_{62.4}N₂O_{20.2}W₆ | 58.5 | 58.8 |
| Compound 43 | C_{30.4}H_{59.2}Mo₆N₂O_{20.6} | 42.3 | 41.9 |
| Compound 44 | C₇₂H₈₄N₁₆O₄₈SiW₁₂ | 52.8 | 52.4 |
| Compound 45 | C_{33.2}H₆₃N_{3.8}O_{20.2}W₆ | 56.8 | 55.9 |
| Compound 46 | C_{33.6}H₆₀Mo₆N_{4.4}O_{20.6} | 40.7 | 40.0 |
| Compound 47 | C₂₁₆H₂₅₂N₄₈O₆₆V₁₈ | 16.7 | 16.9 |
| Compound 48 | C₃₆H₃₀O₄S₂W | 23.7 | 22.9 |
| Compound 49 | H₄SiW₁₂O₄₀ | 65.1 | 65.9 |

### Example 1

0.20 g of compound 1 was dissolved in 4.8 g of PGME to prepare radiation-sensitive resist composition 1.

### Examples 2 to 48 and Comparative Examples 1 to 2

Radiation-sensitive resist compositions 2 to 47 and radiation-sensitive resist comparative compositions 1 to 2 were prepared in the same manner as in Example 1, except that compounds 2 to 49 were used instead of compound 1, and solvents shown in Table 2 below were used instead of PGME.

### [Evaluation]

### (Preparation of Resist Film)

Radiation-sensitive resist compositions 1 to 47 and radiation-sensitive resist comparative compositions 1 to 2 obtained above were each applied onto a 4-inch silicon wafer by using a spin coater. Afterwards, PAB was performed at a temperature of 130° C. for 60 seconds by using a hot plate to obtain a resist film with a dry film thickness of 50 nm.

### (Exposure of Resist Film to Radiation and Sensitivity Evaluation)

The sensitivity of a radiation-sensitive resist composition was evaluated by irradiating EUV rays and EBs with a relatively high correlation to sensitivity. By using an electron beam exposure device (ELS-7500 manufactured by Elionix Co., Ltd., acceleration voltage of 50 kV), EBs were irradiated onto two 50 μm×50 μm areas of a resist film at different doses. The doses of the EBs were 5,000 μC/cm² and 10,000 μC/cm², respectively. After the irradiation, resist films were developed at a temperature of 25° C. for 1 minute by using developers shown in Table 2 below. After the development, sensitivity evaluation was performed by measuring a film thickness in two areas.

In the case of a positive type, when a film did not remain in both of two areas irradiated with doses of 5,000 μC/cm² and 10,000 μC/cm², it was marked as ⊚, when a film remained only in the area irradiated with a dose of 5,000 μC/cm², it was marked as ◯, and when a film remained in both of the two areas, it was marked as x.

In the case of a negative type, when a film with a thickness of 25 nm or more was obtained in both of two areas irradiated with doses of 5,000 μC/cm² and 10,000 μC/cm², it was marked as ⊚, when a film with a thickness of 25 nm or more was obtained only in the area irradiated with a dose of 5,000 μC/cm², it was marked as ◯, and when a film with a thickness of 25 nm or more was not obtained in both of the two areas, it was marked as x.

When all of the positive and negative types are evaluated as ⊚ or ◯, the positive and negative types are usable.

Evaluation results are shown in Table 2 below. In addition, solvents and developers shown in Table 2 below are as follows: PGME: propylene glycol monomethyl ether, H₂O: pure water, NMP: N-Methyl-2-pyrrolidone, DMAc: N,N-dimethylacetamide, CyHex: cyclohexanone, MeOH: methanol, EtOH: ethanol, IPA: 2-Isopropanol, and BuOEtOH: ethylene glycol monobutyl ether (2-butoxyethanol).
Mixed solvent 1: mixed solvent of methanol and pure water in 9:1 mass ratio.
Mixed solvent 2: mixed solvent of N-methyl-2-pyrrolidone and PGME in 2:8 mass ratio.
Mixed solvent 3: mixed solvent of N-methyl-2-pyrrolidone and PGME in 7:3 mass ratio.

TABLE 2

| | Composition | | | | Resist | Sensitivity |
|---|---|---|---|---|---|---|
| | No. | Compound | Solvent | Developer | type | evaluation |
| Example 1 | Composition 1 | Compound 1 | PGME | H₂O | Positive | ⊚ |
| | | | | | type | |
| Example 2 | Composition 2 | Compound 2 | NMP | H₂O | Positive | ∘ |
| | | | | | type | |
| Example 3 | Composition 3 | Compound 3 | NMP | EtOH | Positive | ∘ |
| | | | | | type | |
| Example 4 | Composition 4 | Compound 4 | NMP | MeOH | Positive | ∘ |
| | | | | | type | |
| Example 5 | Composition 5 | Compound 5 | NMP | MeOH | Positive | ∘ |
| | | | | | type | |
| Example 6 | Composition 6 | Compound 6 | NMP | H₂O | Positive | ∘ |
| | | | | | type | |
| Example 7 | Composition 7 | Compound 7 | NMP | MeOH | Positive | ∘ |
| | | | | | type | |
| Example 8 | Composition 8 | Compound 8 | PGME | H₂O | Positive | ⊚ |
| | | | | | type | |
| Example 9 | Composition 9 | Compound 9 | PGME | H₂O | Positive | ⊚ |
| | | | | | type | |
| Example 10 | Composition 10 | Compound 10 | NMP | H₂O | Positive | ∘ |
| | | | | | type | |
| Example 11 | Composition 11 | Compound 11 | NMP | H₂O | Positive | ∘ |
| | | | | | type | |
| Example 12 | Composition 12 | Compound 12 | NMP | H₂O | Positive | ∘ |
| | | | | | type | |
| Example 13 | Composition 13 | Compound 13 | NMP | H₂O | Positive | ∘ |
| | | | | | type | |
| Example 14 | Composition 14 | Compound 14 | NMP | H₂O | Positive | ∘ |
| | | | | | type | |
| Example 15 | Composition 15 | Compound 15 | NMP | H₂O | Positive | ∘ |
| | | | | | type | |
| Example 16 | Composition 16 | Compound 16 | DMAc | Mixed | Positive | ∘ |
| | | | | solvent 1 | type | |
| Example 17 | Composition 17 | Compound 17 | PGME | H₂O | Positive | ⊚ |
| | | | | | type | |
| Example 18 | Composition 18 | Compound 18 | PGME | H₂O | Positive | ⊚ |
| | | | | | type | |
| Example 19 | Composition 19 | Compound 19 | DMAc | H₂O | Positive | ⊚ |
| | | | | | type | |
| Example 20 | Composition 20 | Compound 20 | PGME | H₂O | Positive | ⊚ |
| | | | | | type | |
| Example 21 | Composition 21 | Compound 21 | PGME | H₂O | Positive | ⊚ |
| | | | | | type | |
| Example 22 | Composition 22 | Compound 22 | DMAc | H₂O | Positive | ⊚ |
| | | | | | type | |
| Example 23 | Composition 23 | Compound 23 | DMAc | H₂O | Positive | ⊚ |
| | | | | | type | |
| Example 24 | Composition 24 | Compound 24 | DMAc | H₂O | Positive | ⊚ |
| | | | | | type | |
| Example 25 | Composition 25 | Compound 25 | DMAc | H₂O | Positive | ∘ |
| | | | | | type | |
| Example 26 | Composition 26 | Compound 26 | DMAc | H₂O | Positive | ⊚ |
| | | | | | type | |
| Example 27 | Composition 27 | Compound 27 | DMAc | H₂O | Positive | ∘ |
| | | | | | type | |
| Example 28 | Composition 28 | Compound 28 | CyHex | Mixed | Positive | ⊚ |
| | | | | solvent 1 | type | |
| Example 29 | Composition 29 | Compound 29 | DMAc | IPA | Positive | ⊚ |
| | | | | | type | |
| Example 30 | Composition 30 | Compound 30 | DMAc | H₂O | Positive | ⊚ |
| | | | | | type | |
| Example 31 | Composition 31 | Compound 31 | DMAc | H₂O | Positive | ⊚ |
| | | | | | type | |
| Example 32 | Composition 32 | Compound 32 | CyHex | H₂O | Positive | ⊚ |
| | | | | | type | |
| Example 33 | Composition 33 | Compound 33 | DMAc | H₂O | Positive | ⊚ |
| | | | | | type | |
| Example 34 | Composition 34 | Compound 34 | DMAc | H₂O | Positive | ∘ |
| | | | | | type | |
| Example 35 | Composition 35 | Compound 35 | DMAc | H₂O | Positive | ∘ |
| | | | | | type | |
| Example 36 | Composition 36 | Compound 36 | DMAc | H₂O | Positive | ⊚ |
| | | | | | type | |
| Example 37 | Composition 37 | Compound 37 | PGME | H₂O | Positive | ⊚ |
| | | | | | type | |
| Example 38 | Composition 38 | Compound 38 | DMAc | H₂O | Positive | ∘ |
| | | | | | type | |
| Example 39 | Composition 39 | Compound 39 | PGME | H₂O | Positive | ⊚ |
| | | | | | type | |
| Example 40 | Composition 40 | Compound 40 | DMAc | H₂O | Positive | ∘ |
| | | | | | type | |
| Example 41 | Composition 41 | Compound 41 | NMP | Mixed | Negative | ⊚ |
| | | | | solvent 2 | type | |
| Example 42 | Composition 42 | Compound 42 | NMP | Mixed | Negative | ∘ |
| | | | | solvent 2 | type | |
| Example 43 | Composition 43 | Compound 43 | NMP | Mixed | Negative | ∘ |
| | | | | solvent 2 | type | |
| Example 44 | Composition 44 | Compound 44 | NMP | Mixed | Negative | ⊚ |
| | | | | solvent 2 | type | |
| Example 45 | Composition 45 | Compound 45 | NMP | Mixed | Negative | ∘ |
| | | | | solvent 2 | type | |
| Example 46 | Composition 46 | Compound 46 | NMP | Mixed | Negative | ∘ |
| | | | | solvent 2 | type | |
| Example 47 | Composition 47 | Compound 47 | NMP | Mixed | Negative | ⊚ |
| | | | | solvent 2 | type | |
| Example 48 | Composition 32 | Compound 32 | CyHex | BuOEtOH | Negative | ⊚ |
| | | | | | type | |
| Comparative | Comparative | Compound 48 | NMP | H₂O | Positive | x |
| Example 1 | Composition 1 | | | | type | |
| Comparative | Comparative | Compound 49 | NMP | Mixed | Negative | x |
| Example 2 | Composition 2 | | | solvent 2 | type | |

As clearly shown in Table 2, the radiation-sensitive resist compositions of Examples 1 to 48 including compounds 1 to 47 exhibited good sensitivity to EBs. On the other hand, the radiation-sensitive resist comparative compositions of Comparative Examples 1 and 2 including compounds 48 to 49 did not obtain sufficient sensitivity even at a dose of 10,000 μC/cm².

Embodiments may provide a radiation-sensitive resist composition having improved absorption properties of radiation (particularly, EUV rays) to have improved sensitivity and/or resolution.

According to an aspect of the disclosure, a pattern formation method includes applying one or more of the radiation-sensitive resist compositions onto a substrate to form a resist film, exposing at least a portion of the resist film to radiation, and developing the exposed resist film by using a developer.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A radiation-sensitive resist composition comprising:
an ionic salt (A) comprising an organic cation (b) and an anion (a) which has a metal chalcogenide cluster structure; and
a solvent (B),
wherein the anion (a) comprises at least one of V, Nb, Ta, Mo, or W,
the organic cation (b) is at least one of a secondary ammonium cation having 2 to 30 carbon atoms, a tertiary ammonium cation having 2 to 30 carbon atoms, a quaternary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, or a hydrazinium cation having 1 to 30 carbon atoms, and
a content of the ionic salt (A) in the radiation-sensitive resist composition is in a range of about 20 mass % to about 100 mass % of a total solid content of the radiation-sensitive resist composition.

2. The radiation-sensitive resist composition of claim 1, wherein the anion (a) comprises at least one of V, Mo, or W.

3. The radiation-sensitive resist composition of claim 1, wherein a total number of metal atoms in the metal chalcogenide cluster structure of the anion (a) is in a range of 4 to 50.

4. The radiation-sensitive resist composition of claim 1, wherein a content of the at least one of V, Nb, Ta, Mo, and W is 20 at % or more with respect to 100 at % of a total number of metal atoms in the anion (a).

5. The radiation-sensitive resist composition of claim 1, wherein a molecular weight of the anion (a) is in a range of about 600 to about 9,000.

6. The radiation-sensitive resist composition of claim 1, wherein an average diameter of the anion (a) is in a range of about 0.5 nm to about 10 nm.

7. The radiation-sensitive resist composition of claim 1, wherein the anion (a) is represented by at least one of Formulas a-1 to a-6: 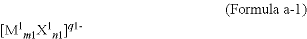
wherein, in Formula a-1,
M¹ is at least one of V, Nb, Ta, Mo, or W,
m1 is an integer from 4 to 60, a plurality of M¹ are identical to or different from each other,
X¹ is at least one of O, OH, S, or Se,
n1 is an integer from 10 to 200, and
q1 is an integer from 2 to 40, 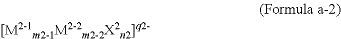
wherein, in Formula a-2,
M²⁻¹ is at least one of V, Nb, Ta, Mo, or W,
m2-1 is an integer from 4 to 60,
M²⁻² is at least one of P, As, Si, Ge, Sn, B, Al, Ga, In, Fe, Zn, Co, Te, Cu, Ag, or Mn,
m2-2 is an integer from 1 to 10,
X² is at least one of O, OH, S, or Se,
n2 is an integer from 10 to 200, and
q2 is an integer from 2 to 40, 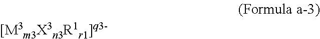
wherein, in Formula a-3,
M³ is at least one of V, Nb, Ta, Mo, or W,
m3 is an integer from 4 to 60,
X³ is at least one of O, OH, S, or Se,
n3 is an integer from 10 to 200,
R¹ is an organic group having 1 to 20 carbon atoms,
r1 is an integer from 1 to 10, and
q3 is an integer from 2 to 40, 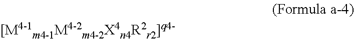
wherein, in Formula a-4,
M⁴⁻¹ is at least one of V, Nb, Ta, Mo, or W,
m4-1 is an integer from 4 to 60,
M⁴⁻² is at least one of P, As, Si, Ge, Sn, B, Al, Ga, In, Fe, Zn, Co, Te, Cu, Ag, or Mn,
m4-2 is an integer from 1 to 10,
X⁴ is at least one of O, OH, S, or Se,
n4 is an integer from 10 to 200,
R² is an organic group having 1 to 20 carbon atoms,
r2 is an integer from 1 to 10, and
q4 is an integer from 2 to 40, 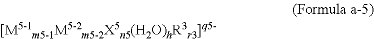
wherein, in Formula a-5,
M⁵⁻¹ is at least one of V, Nb, Ta, Mo, or W,
m5-1 is an integer from 4 to 60,
M⁵⁻² is at least one of P, As, Si, Ge, Sn, B, Al, Ga, In, Fe, Zn, Co, Te, Cu, Ag, or Mn,
m5-2 is an integer from 1 to 10,
X⁵ is at least one of O, OH, S, or Se,
n5 is an integer from 10 to 200,
h is an integer from 1 to 10,
R³ is an organic group having 1 to 20 carbon atoms,
r3 is an integer from 1 to 10, when r3 is greater than or equal to 2, a plurality of R³ are identical to or different from each other, and
q5 is an integer from 2 to 40, and 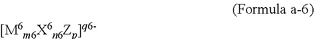
wherein, in Formula a-6,
M⁶ is at least one of V, Nb, Ta, Mo, or W,
m6 is an integer from 4 to 60,
X⁶ is at least one of O, OH, S, or Se,
n6 is an integer from 10 to 200,
Z is an inorganic functional group comprising an oxygen atom and at least one of a nitrogen atom, a phosphorus atom, or a sulfur atom,
p is an integer from 1 to 10, and
q6 is an integer from 2 to 40.

8. The radiation-sensitive resist composition of claim 7, wherein q1 in Formula a-1, q2 in Formula a-2, q3 in Formula a-3, q4 in Formula a-4, q5 in Formula a-5, and q6 in Formula a-6 are each independently an integer from 3 to 15.

9. The radiation-sensitive resist composition of claim 1, wherein the anion (a) is at least one of: [Nb₆O₁₉]⁸⁻, [Nb₇O₂₂]⁹⁻, [Nb₁₀O₂₈]⁶⁻, [Ta₆O₁₉]⁸⁻, [Ta₁₀O₂₈]⁶⁻, [Mo₆O₁₉]²⁻, [W₆O₁₉]²⁻, [W₇O₂₄]⁶⁻, [W₁₀O₃₂]⁴⁻, [W₁₀O₃₄]⁸⁻, [Mo₇O₂₄]⁶⁻, [Mo₈O₂₆]⁴⁻, [Mo₁₀O₃₄]⁸⁻, [W₁₂O₄₀(OH)₂]¹⁰⁻, [W₁₂O₃₈(OH)₂]⁶⁻, [V₄O₁₂]⁴⁻, [V₁₀O₂₈]⁶⁻, [V₁₂O₃₂]⁴⁻, [V₁₃O₃₄]⁴⁻, [V₁₈O₄₂]¹²⁻, [NbW₅O₁₉]³⁻, [Nb₄W₂O₁₉]⁶⁻, [V₂W₄O₁₉]⁴⁻, [NbVW₄O₁₉]⁴⁻, [V₅Mo₈O₄₀]⁷⁻, [W₆O₁₈S]²⁻, [W₃OS₈]²⁻, and [W₄Si₂]²⁻; [TeMoO₂₄]⁶⁻, [CoW₆As₆O₃₀]⁴⁻, [SW₁₂O₄₀]²⁻, [PW₁₂O₄₀]³⁻, [AsW₁₂O₄₀]³⁻, [SiW₁₂O₄₀]⁴⁻, [GeW₁₂O₄₀]⁴⁻, [BW₁₂O₄₀]⁵⁻, [AlW₁₂O₄₀]⁵⁻, [GaW₁₂O₄₀]⁵⁻, [FeW₁₂O₄₀]⁵⁻, [ZnW₁₂O₄₀]⁶⁻, [CoW₁₂O₄₀]⁶⁻, [SMo₁₂O₄₀]²⁻, [PMo₁₂O₄₀]³⁻, [AsMo₁₂O₄₀]³⁻, [SiMo₁₂O₄₀]⁴⁻, [GeMo₁₂O₄₀]⁴⁻, [SiMo₂W₁₀O₄₀]⁴⁻, [SiVW₁₁O₄₀]⁵⁻, [SiMo₂VW₉O₄₀]⁵⁻, [SiW₁₁O₃₉]⁸⁻, [PW₁₀O₃₉]⁸⁻, [B₃W₃₉O₁₃₂]²¹⁻, [AsW₉O₃₃]⁹⁻, [P₂W₁₈O₆₂]⁶⁻, [As₂WiO₆₂]⁶⁻, [S₂W₁₈O₆₂]⁴⁻, [P₂MO₁₈O₆₂]⁶⁻, [As₂Mo₁₈O₆₂]⁶⁻, [S₂Mo₁₈O₆₂]⁴⁻, [AgP₅W₃₀O₁₁₀]¹⁴⁻, [Sn₈W₁₈O₆₆]⁸⁻, [Sn₃W₁₈Si₂O₆₈]¹⁴⁻, [Sn₃W₁₈P₂O₆₈]¹²⁻, [SnW₁₂O₄₂]¹⁰⁻,[Te₁₀W₂₈O₁₁₈]²⁸⁻, [Te₂W₁₈Cu₃O₆₉]¹⁶⁻, [Te₄W₂₀O₈₀]²⁴⁻, [Te₉W₂₈O₁₁₂]²⁴⁻, [Te₂W₅₈O₁₉₈]³⁶⁻, [TeW₁₈O₆₃]⁸⁻, [TeW₁₈O₆₂]¹⁰⁻, [TeW₆O₂₄]⁶⁻, [Te₂W₁₇O₆₁]¹²⁻, [TeW₁₅O₅₄]¹⁴⁻, [InW₁₁PO₄₀]⁸⁻, [InW₁₁SiO₄₀]⁹⁻, [Mo₆O₁₇(NC₆H₅)₂]²⁻, [Mo₈O₂₄{CH₃C(CH₂O)₃}₂]⁶⁻, [InW₃O₄(C₂H₄COO)₈]²²⁻, [MnMo₆O₁₈{CH₃C(CH₂O)₃}₂]³⁻, [ZnMo₆O₁₈{CH₃C(CH₂O)₃}₂]⁴⁻, [PW₉O₃₀(C₂H₅PO₃)₂]⁶⁻, {ZnW₁₂O₄₀[Cu(phen)(H₂O)]₂}²⁻, [Mo₆O₁₈(NO)]³⁻, [MoO₁₅(PO₄)₂]⁶⁻, [W₅O₁₅(PO₄)₂]⁶⁻, [Mo₅O₁₅(HPO₄)₂]⁴⁻, and [Mo₅O₁₅(SO₃)₂]⁴⁻.

10. The radiation-sensitive resist composition of claim 1, wherein the organic cation (b) is at least one of the secondary ammonium cation having 2 to 30 carbon atoms, the tertiary ammonium cation having 2 to 30 carbon atoms, the phosphonium cation having 1 to 30 carbon atoms, the sulfonium cation having 1 to 30 carbon atoms, the iodonium cation having 1 to 30 carbon atoms, the pyridinium cation having 5 to 30 carbon atoms, the imidazolium cation having 3 to 30 carbon atoms, the diazonium cation having 1 to 30 carbon atoms, the guanidinium cation having 1 to 30 carbon atoms, or the hydrazinium cation having 1 to 30 carbon atoms.

11. The radiation-sensitive resist composition of claim 1, wherein the organic cation (b) is at least one of the secondary ammonium cation having 2 to 30 carbon atoms, the tertiary ammonium cation having 2 to 30 carbon atoms, the phosphonium cation having 1 to 30 carbon atoms, the pyridinium cation having 5 to 30 carbon atoms, the imidazolium cation having 3 to 30 carbon atoms, the guanidinium cation having 1 to 30 carbon atoms, or the hydrazinium cation having 1 to 30 carbon atoms.

12. The radiation-sensitive resist composition of claim 1, wherein a molecular weight of the organic cation (b) is in a range of about 50 to about 5,000.

13. The radiation-sensitive resist composition of claim 1, wherein a total molecular weight of the ionic salt (A) is in a range of about 650 to about 30,000.

14. The radiation-sensitive resist composition of claim 1, wherein a ratio of a molecular weight of the anion (a) to a total molecular weight of the organic cation (b) [molecular weight of the anion (a)/total molecular weight of the organic cation (b)] is in a range of about 0.3 to about 30.

15. The radiation-sensitive resist composition of claim 1, wherein the solvent (B) is at least one of an alcohol-based solvent, a ketone-based solvent, an amide-based solvent, an ester-based solvent, or a sulfoxide-based solvent.

16. The radiation-sensitive resist composition of claim 1, wherein the solvent (B) is substantially anhydrous.

17. The radiation-sensitive resist composition of claim 1, wherein the radiation-sensitive resist composition is a positive type radiation-sensitive resist composition.

18. A pattern formation method comprising:
applying a radiation-sensitive resist composition onto a substrate to form a resist film;
exposing at least a portion of the resist film to radiation; and
developing the exposed resist film by using a developer,
wherein the radiation-sensitive resist composition includes
an ionic salt (A) comprising an organic cation (b) and an anion (a) which has a metal chalcogenide cluster structure, and
a solvent (B),
the anion (a) comprises at least one of V, Nb, Ta, Mo, or W,
the organic cation (b) is at least one of a secondary ammonium cation having 2 to 30 carbon atoms, a tertiary ammonium cation having 2 to 30 carbon atoms, a quaternary ammonium cation having 2 to 30 carbon atoms, a phosphonium cation having 1 to 30 carbon atoms, a sulfonium cation having 1 to 30 carbon atoms, an iodonium cation having 1 to 30 carbon atoms, a pyridinium cation having 5 to 30 carbon atoms, an imidazolium cation having 3 to 30 carbon atoms, a diazonium cation having 1 to 30 carbon atoms, a guanidinium cation having 1 to 30 carbon atoms, or a hydrazinium cation having 1 to 30 carbon atoms, and
a content of the ionic salt (A) in the radiation-sensitive resist composition is in a range of about 20 mass % to about 100 mass % of a total solid content of the radiation-sensitive resist composition.

19. The pattern formation method of claim 18, wherein the exposing includes irradiating the portion of the resist film with at least one of visible light, ultraviolet (UV) rays, deep ultraviolet (DUV) rays, extreme ultraviolet (EUV) rays, X-rays, γ-rays, electron beams (EBs), or α-rays.

20. The pattern formation method of claim 18, wherein the exposed resist film comprises an exposed portion and an unexposed portion, and
the developing includes removing the exposed portion.
